(19) United States
(12) Patent Application Publication
(10) Pub. No.: US 2024/0282749 A1
(43) Pub. Date: Aug. 22, 2024

(54) SEMICONDUCTOR DEVICE

(71) Applicant: ROHM CO., LTD., Kyoto-shi (JP)

(72) Inventor: Yuki NAKANO, Kyoto-shi (JP)

(73) Assignee: ROHM CO., LTD., Kyoto-shi (JP)

(21) Appl. No.: 18/652,832

(22) Filed: May 2, 2024

Related U.S. Application Data
(63) Continuation of application No. PCT/JP2022/040498, filed on Oct. 28, 2022.

(30) Foreign Application Priority Data
Nov. 5, 2021 (JP) 2021-181317

(51) Int. Cl. H01L 25/065; H01L 23/00; H01L 23/498

(52) U.S. Cl. CPC H01L 25/0655; H01L 23/49838; H01L 24/16; H01L 24/48; H01L 24/97; H01L 2224/16146; H01L 2224/16225; H01L 2224/48137; H01L 2224/48155; H01L 2224/97; H01L 2924/01029; H01L 2924/13055; H01L 2924/1306; H01L 2924/15311; H01L 2924/182

(57) ABSTRACT

A semiconductor device includes a chip that has a main surface, a main surface electrode that covers the main surface, pillar electrodes that are arranged on the main surface electrode at an interval, a sealing insulator that covers a region between the pillar electrodes on the main surface electrode such as to expose parts of the pillar electrodes, and at least one terminal film that covers at least one of the pillar electrodes on the sealing insulator.

### CROSS-REFERENCE TO RELATED APPLICATIONS

The present application is a bypass continuation of International Patent Application No. PCT/JP2022/040498, filed on Oct. 28, 2022, which claims the benefit of priority to Japanese Patent Application No. 2021-181317, filed on Nov. 5, 2021, the entire contents of each application are hereby incorporated herein by reference.

### BACKGROUND

### 1. Field of the Disclosure

The present disclosure relates to a semiconductor device.

### 2. Description of the Related Art

US20190080976A1 discloses a semiconductor device that includes a semiconductor substrate, an electrode and a protective film. The electrode is formed on the semiconductor substrate. The protective film has a laminated structure that includes an inorganic protective film and an organic protective film and covers the electrode.

### BRIEF DESCRIPTION OF THE DRAWINGS

FIG. 1 is a plan view of a semiconductor device according to a first embodiment.

FIG. 2 is a cross sectional view taken along II-II line shown in FIG. 1.

FIG. 3 is an enlarged plan view showing a principal part of an inner portion of a chip.

FIG. 4 is a cross sectional view taken along IV-IV line shown in FIG. 3.

FIG. 5 is an enlarged cross sectional view showing a peripheral edge portion of the chip.

FIG. 6 is a plan view showing layout examples of a gate electrode and a source electrode.

FIG. 7 is a plan view showing a layout example of an upper insulating film.

FIG. 8A is a partial cross sectional view showing a terminal film according to a first configuration example.

FIG. 8B is a partial cross sectional view showing a terminal film according to a second configuration example.

FIG. 8C is a partial cross sectional view showing a terminal film according to a third configuration example.

FIG. 8D is a partial cross sectional view showing a terminal film according to a fourth configuration example.

FIG. 8E is a partial cross sectional view showing a terminal film according to a fifth configuration example.

FIG. 8F is a partial cross sectional view showing a terminal film according to a sixth configuration example.

FIG. 8G is a partial cross sectional view showing a terminal film according to a seventh configuration example.

FIG. 9 is a plan view showing a wafer structure that is to be used at a time of manufacturing.

FIG. 10 is a cross sectional view showing a device region shown in FIG. 9.

FIGS. 11A to 11J are cross sectional views showing a manufacturing method example for the semiconductor device shown in FIG. 1.

FIGS. 12A to 12C are partial cross sectional views showing a first manufacturing method example of the terminal films.

FIGS. 13A to 13C are partial cross sectional views showing a second manufacturing method example of the terminal films.

FIGS. 14A and 14B are partial cross sectional views showing a third manufacturing method example of the terminal films.

FIG. 15 is a plan view showing a semiconductor device according to a second embodiment.

FIG. 16 is a plan view showing a semiconductor device according to a third embodiment.

FIG. 17 is a plan view showing a semiconductor device according to a fourth embodiment.

FIG. 18 is a circuit diagram showing an electrical configuration of the semiconductor device shown in FIG. 17.

FIG. 19 is a plan view showing a semiconductor device according to a fifth embodiment.

FIG. 20 is a cross sectional view taken along XX-XX line shown in FIG. 19.

FIG. 21 is a plan view showing a semiconductor device according to a sixth embodiment.

FIG. 22 is a plan view showing a semiconductor device according to a seventh embodiment.

FIG. 23 is a plan view showing a semiconductor device according to a eighth embodiment.

FIG. 24 is a plan view showing a semiconductor device according to a ninth embodiment.

FIG. 25 is a plan view showing a semiconductor device according to a tenth embodiment.

FIG. 26 is a cross sectional view taken along XXVI-XXVI line shown in FIG. 25.

FIG. 27 is a plan view showing a semiconductor device according to a eleventh embodiment.

FIG. 28 is a cross sectional view showing a modified example of the chip to be applied to each of the embodiments.

FIG. 29 is a plan view showing a package to which any one of the semiconductor devices according to the first to ninth embodiments is to be incorporated.

FIG. 30 is a plan view showing a package to which any one of the semiconductor devices according to the tenth to eleventh embodiments is to be incorporated.

FIG. 31 is a perspective view showing a package to which any one of the semiconductor devices according to the first to ninth embodiments and any one of the semiconductor devices according to tenth to eleventh embodiments are to be incorporated.

FIG. 32 is an exploded perspective view of the package shown in FIG. 31.

FIG. 33 is a cross sectional view taken along XXXIII-XXXIII line shown in FIG. 31.

### DETAILED DESCRIPTION OF THE PREFERRED EMBODIMENTS

Hereinafter, embodiments shall be described in detail with reference to attached drawings. The attached drawings are schematic views and are not strictly illustrated, and scales and the like thereof do not always match. Also, identical reference symbols are given to corresponding structures among the attached drawings, and duplicate descriptions thereof shall be omitted or simplified. For the structures whose description have been omitted or simplified, the description given before the omission or simplification shall be applies.

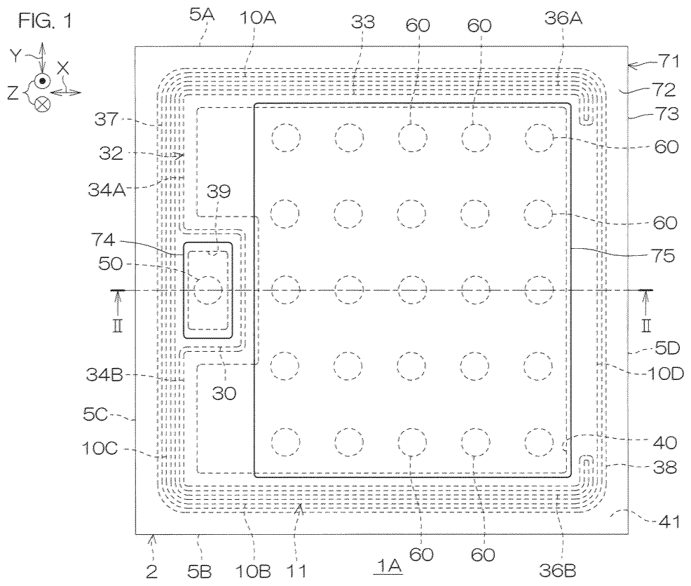

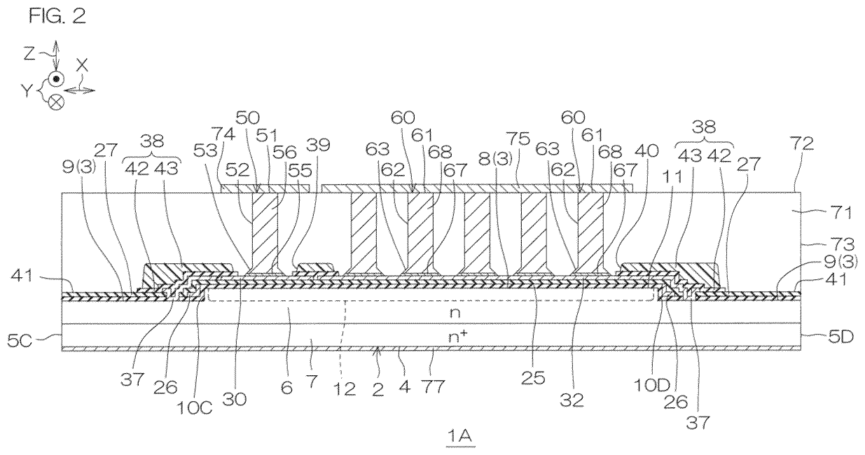

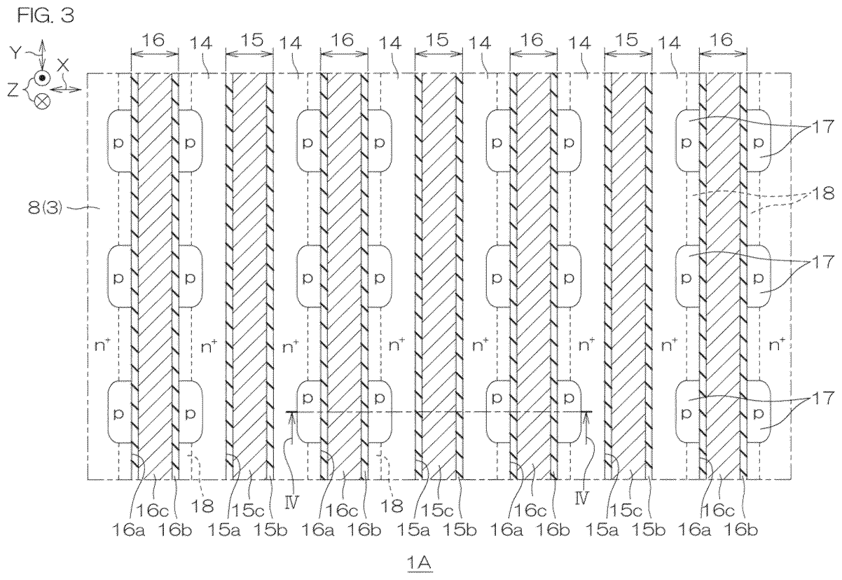

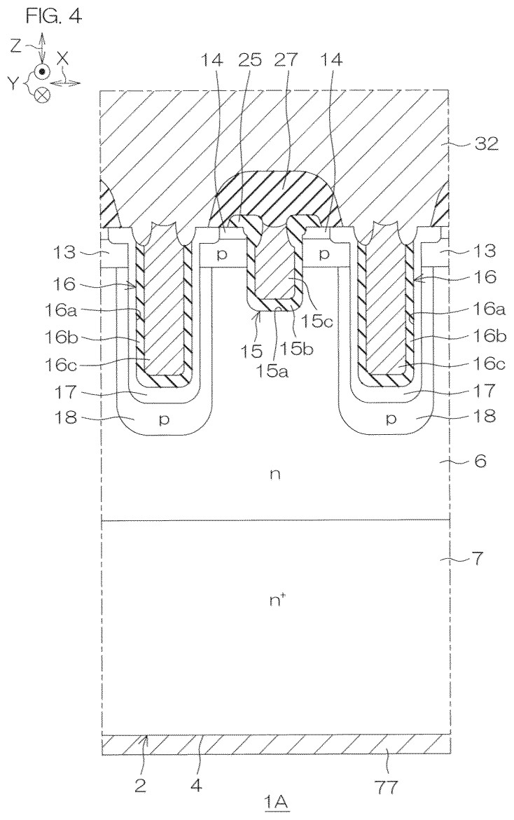

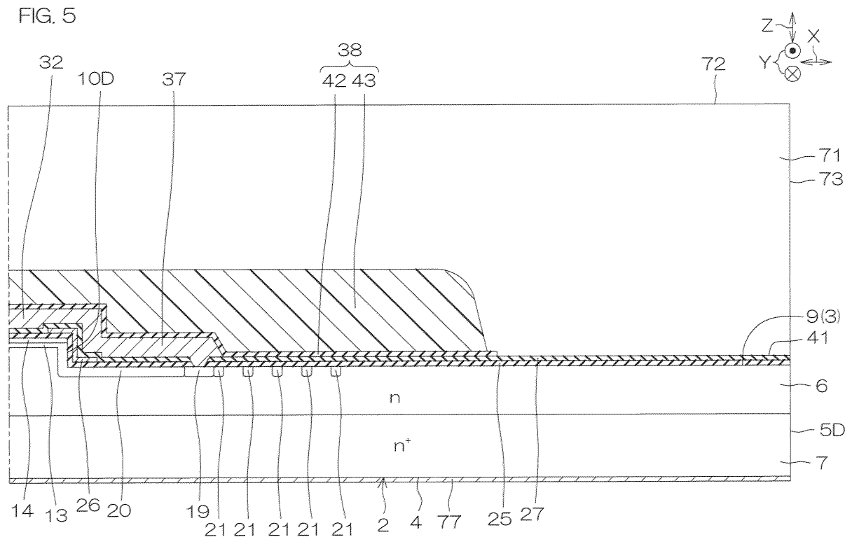

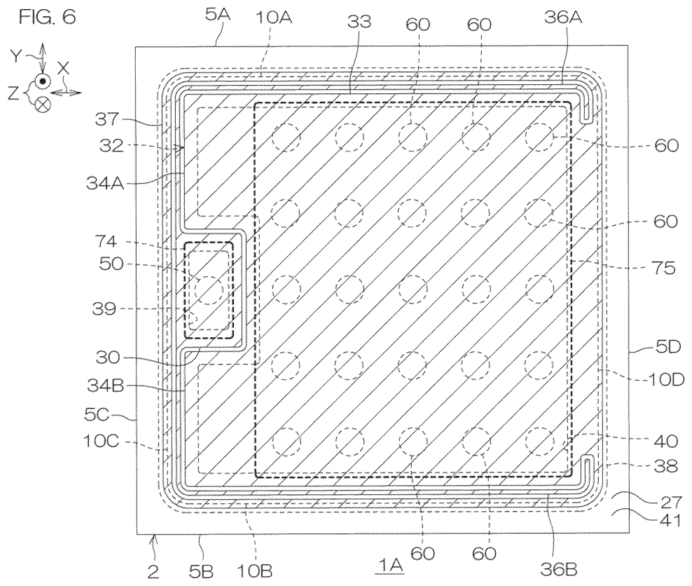

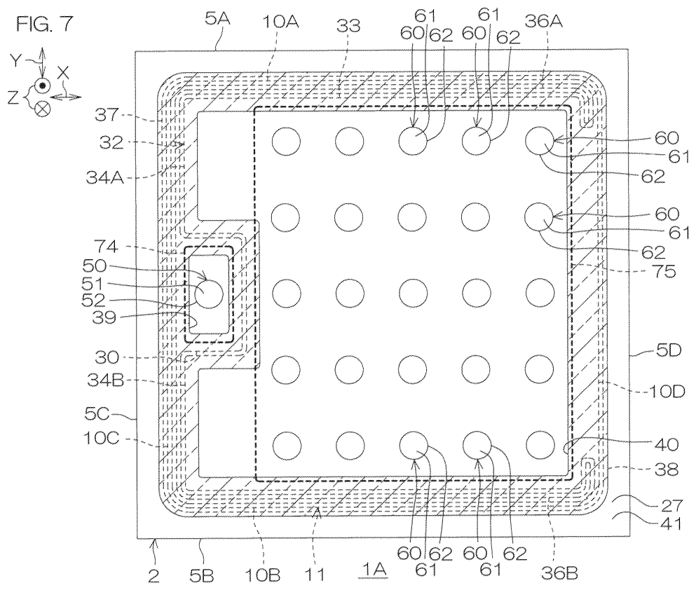

FIG. 1 is a plan view of a semiconductor device 1A according to a first embodiment. FIG. 2 is a cross sectional view taken along II-II line shown in FIG. 1. FIG. 3 is an enlarged plan view showing a principal part of an inner portion of a chip 2. FIG. 4 is a cross sectional view taken along IV-IV line shown in FIG. 3. FIG. 5 is an enlarged cross sectional view showing a peripheral edge portion of the chip 2. FIG. 6 is a plan view showing layout examples of a gate electrode 30 and a source electrode 32. FIG. 7 is a plan view showing a layout example of an upper insulating film 38.

With reference to FIG. 1 to FIG. 7, the semiconductor device 1A includes a chip 2 that includes a monocrystal of a wide bandgap semiconductor and that is formed in a hexahedral shape (specifically, rectangular parallelepiped shape), in this embodiment. That is, the semiconductor device 1A is a “wide bandgap semiconductor device”. The chip 2 may be referred to as a “semiconductor chip” or a “wide bandgap semiconductor chip”. The wide bandgap semiconductor is a semiconductor having a bandgap exceeding a bandgap of an Si (Silicon). GaN (gallium nitride), SiC (silicon carbide) and C (diamond) are exemplified as the wide bandgap semiconductors.

The chip 2 is an “SiC chip” including an SiC monocrystal of a hexagonal crystal as an example of the wide bandgap semiconductor. That is, the semiconductor device 1A is an “SiC semiconductor device”. The SiC monocrystal of the hexagonal crystal has multiple polytypes including 2H (Hexagonal)-SiC monocrystal, 4H-SiC monocrystal, 6H-SiC monocrystal and the like. In this embodiment, an example in which the chip 2 includes the 4H-SiC monocrystal is to be given, but this does not preclude a choice of other polytypes.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are each formed in a quadrangle shape in plan view as viewed from their normal direction Z (hereinafter, simply referred to as “in plan view”). The normal direction Z is also a thickness direction of the chip 2. The first main surface 3 and the second main surface 4 are preferably formed by a c-plane of the SiC monocrystal, respectively.

In this case, the first main surface 3 is preferably formed by a silicon surface of the SiC monocrystal, and the second main surface 4 is preferably formed by a carbon surface of the SiC monocrystal. The first main surface 3 and the second main surface 4 may each have an off angle inclined with a predetermined angle with respect to the c-plane toward a predetermined off direction. The off direction is preferably an a-axis direction ([11-20] direction) of the SiC monocrystal. The off angle may be more than 0° and not more than 10°. The off angle is preferably not more than 5°. The second main surface 4 may consist of a ground surface with grinding marks, or may consist of a smooth surface without a grinding mark.

The first side surface 5A and the second side surface 5B extend in a first direction X along the first main surface 3 and oppose in a second direction Y intersecting to (specifically, orthogonal to) the first direction X. The third side surface 5C and the fourth side surface 5D extend in the second direction Y and oppose in the first direction X. The first direction X may be an m-axis direction ([1-100] direction) of the SiC monocrystal, and the second direction Y may be the a-axis direction of the SiC monocrystal. As a matter of course, the first direction X may be the a-axis direction of the SiC monocrystal, and the second direction Y may be the m-axis direction of the SiC monocrystal. The first to fourth side surfaces 5A to 5D may each consist of a ground surface with grinding marks, or may each consist of a smooth surface without a grinding mark.

The chip 2 has a thickness of not less than 5 μm and not more than 250 μm in regard to the normal direction Z. The thickness of the chip 2 may be not more than 100 μm. The thickness of the chip 2 is preferably not more than 50 μm. The thickness of the chip 2 is particularly preferably not more than 40 μm. The first to fourth side surfaces 5A to 5D may each have a length of not less than 0.5 mm and not more than 10 mm in plan view.

The lengths of the first to fourth side surfaces 5A to 5D are preferably not less than 1 mm. The lengths of the first to fourth side surfaces 5A to 5D are particularly preferably not less than 2 mm. That is, the chip 2 preferably has a planar area of not less than 1 mm square (preferably, not less than 2 mm square) and preferably has a thickness of not more than 100 μm (preferably, not more than 50 μm). The lengths of the first to fourth side surfaces 5A to 5D are set in a range of not less than 4 mm and not more than 6 mm, in this embodiment.

The semiconductor device 1A includes a first semiconductor region 6 of an n-type (first conductivity type) that is formed in a region (surface layer portion) on the first main surface 3 side inside the chip 2. The first semiconductor region 6 is formed in a layered shape extending along the first main surface 3 and is exposed from the first main surface 3 and the first to fourth side surfaces 5A to 5D. The first semiconductor region 6 consists of an epitaxial layer (specifically, an SiC epitaxial layer), in this embodiment. The first semiconductor region 6 may have a thickness of not less than 1 μm and not more than 50 μm in regard to the normal direction Z. The thickness of the first semiconductor region 6 is preferably not less than 3 μm and not more than 30 μm. The thickness of the first semiconductor region 6 is particularly preferably not less than 5 μm and not more than 25 μm.

The semiconductor device 1A includes a second semiconductor region 7 of the n-type that is formed in a region (surface layer portion) on the second main surface 4 side inside the chip 2. The second semiconductor region 7 is formed in a layered shape extending along the second main surface 4 and exposes from the second main surface 4 and the first to fourth side surfaces 5A to 5D. The second semiconductor region 7 has an n-type impurity concentration higher than that of the first semiconductor region 6 and is electrically connected to the first semiconductor region 6. The second semiconductor region 7 consists of a semiconductor substrate (specifically, an SiC semiconductor substrate), in this embodiment. That is, the chip 2 has a laminated structure including the semiconductor substrate and the epitaxial layer.

The second semiconductor region 7 may have a thickness of not less than 1 μm and not more than 200 μm, in regard to the normal direction Z. The thickness of the second semiconductor region 7 is preferably not less than 5 μm and not more than 50 μm. The thickness of the second semiconductor region 7 is particularly preferably not less than 5 μm and not more than 20 μm. Considering an error to be occurred to the first semiconductor region 6, the thickness of the second semiconductor region 7 is preferably not less than 10 μm. The thickness of the second semiconductor region 7 is most preferably less than the thickness of the first semiconductor region 6. According to the second semiconductor region 7 having the relatively small thickness, a resistance value (for example, an on-resistance) due to the second semiconductor region 7 can be reduced. As a matter of course, the thickness of the second semiconductor region 7 may exceed the thickness of first semiconductor region 6.

The semiconductor device 1A includes an active surface 8 (active surface), an outer surface 9 (outer surface) and first to fourth connecting surfaces 10A to 10D (connecting surface) that are formed in the first main surface 3. The active surface 8, the outer surface 9 and the first to fourth connecting surfaces 10A to 10D define a mesa portion 11 (plateau) in the first main surface 3. The active surface 8 may be referred to as a “first surface portion”, the outer surface 9 may be referred to as a “second surface portion”, the first to fourth connecting surfaces 10A to 10D may be referred to as “connecting surface portions”. The active surface 8, the outer surface 9 and the first to fourth connecting surfaces 10A to 10D (that is, the mesa portion 11) may be considered as components of the chip 2 (the first main surface 3).

The active surface 8 is formed at an interval inward from a peripheral edge of the first main surface 3 (the first to fourth side surfaces 5A to 5D). The active surface 8 has a flat surface extending in the first direction X and the second direction Y. The active surface 8 is formed in a quadrangle shape having four sides parallel to the first to fourth side surfaces 5A to 5D in plan view, in this embodiment.

The outer surface 9 is positioned outside the active surface 8 and is recessed toward the thickness direction of the chip 2 (the second main surface 4 side) from the active surface 8. Specifically, the outer surface 9 is recessed with a depth less than the thickness of the first semiconductor region 6 such as to expose the first semiconductor region 6. The outer surface 9 extends along the active surface 8 in a band shape and is formed in an annular shape (specifically, a quadrangle annular shape) surrounding the active surface 8 in plan view. The outer surface 9 has a flat surface extending in the first direction X and the second direction Y and is formed substantially parallel to the active surface 8. The outer surface 9 is continuous to the first to fourth side surfaces 5A to 5D.

The first to fourth connecting surfaces 10A to 10D extend in the normal direction Z and connect the active surface 8 and the outer surface 9. The first connecting surface 10A is positioned on the first side surface 5A side, the second connecting surface 10B is positioned on the second side surface 5B side, the third connecting surface 10C is positioned on the third side surface 5C side, and the fourth connecting surface 10D is positioned on the fourth side surface 5D side. The first connecting surface 10A and the second connecting surface 10B extend in the first direction X and oppose in the second direction Y. The third connecting surface 10C and the fourth connecting surface 10D extend in the second direction Y and oppose in the first direction X.

The first to fourth connecting surfaces 10A to 10D may substantially vertically extend between the active surface 8 and the outer surface 9 such that the mesa portion 11 of a quadrangle columnar is defined. The first to fourth connecting surfaces 10A to 10D may be downwardly inclined from the active surface 8 to the outer surface 9 such that the mesa portion 11 of a quadrangle pyramid shape is defined. Thus, the semiconductor device 1A includes the mesa portion 11 that is formed in the first semiconductor region 6 at the first main surface 3. The mesa portion 11 is formed only in the first semiconductor region 6 and is not formed in the second semiconductor region 7.

The semiconductor device 1A includes a MISFET (Metal Insulator Semiconductor Field Effect Transistor) structure 12 that is formed in the active surface 8 (the first main surface 3). In FIG. 2, the MISFET structure 12 is shown simplified by a dashed line. Hereinafter, with reference to FIG. 3 and FIG. 4, a specific structure of the MISFET structure 12 shall be described.

The MISFET structure 12 includes a body region 13 of a p-type (second conductivity type) that is formed in a surface layer portion of the active surface 8. The body region 13 is formed at an interval to the active surface 8 side from a bottom portion of the first semiconductor region 6. The body region 13 is formed in a layered shape extending along the active surface 8. The body region 13 may be exposed from parts of the first to fourth connecting surfaces 10A to 10D.

The MISFET structure 12 includes a source region 14 of the n-type that is formed in a surface layer portion of the body region 13. The source region 14 has an n-type impurity concentration higher than that of the first semiconductor region 6. The source region 14 is formed at an interval to the active surface 8 side from a bottom portion of the body region 13. The source region 14 is formed in a layered shape extending along the active surface 8. The source region 14 may be exposed from a whole region of the active surface 8. The source region 14 may be exposed from parts of the first to fourth connecting surfaces 10A to 10D. The source region 14 forms a channel inside the body region 13 between the first semiconductor region 6 and the source region 14.

The MISFET structure 12 includes a plurality of gate structures 15 that are formed in the active surface 8. The plurality of gate structures 15 arrayed at intervals in the first direction X and each formed in a band shape extending in the second direction Y in plan view. The plurality of gate structures 15 penetrate the body region 13 and the source region 14 such as to reach the first semiconductor region 6. The plurality of gate structures 15 control a reversal and a non-reversal of the channel in the body region 13.

Each of the gate structures 15 includes a gate trench 15a, a gate insulating film 15b and a gate embedded electrode 15c, in this embodiment. The gate trench 15a is formed in the active surface 8 and defines a wall surface of the gate structure 15. The gate insulating film 15b covers the wall surface of the gate trench 15a. The gate embedded electrode 15c is embedded in the gate trench 15a with the gate insulating film 15b interposed therebetween and faces the channel across the gate insulating film 15b.

The MISFET structure 12 includes a plurality of source structures 16 that are formed in the active surface 8. The plurality of source structures 16 are each arranged at a region between a pair of adjacent gate structures 15 in the active surface 8. The plurality of source structures 16 are each formed in a band shape extending in the second direction Y in plan view. The plurality of source structures 16 penetrate the body region 13 and the source region 14 to reach the first semiconductor region 6. The plurality of source structures 16 have depths exceeding depths of the gate structures 15. Specifically, the plurality of source structures 16 has the depths substantially equal to the depth of the outer surface 9.

Each of the source structures 16 includes a source trench 16a, a source insulating film 16b and a source embedded electrode 16c. The source trench 16a is formed in the active surface 8 and defines a wall surface of the source structure 16. The source insulating film 16b covers the wall surface of the source trench 16a. The source embedded electrode 16c is embedded in the source trench 16a with the source insulating film 16b interposed therebetween.

The MISFET structure 12 includes a plurality of contact regions 17 of the p-type that are each formed in a region along the source structure 16 inside the chip 2. The plurality of contact regions 17 have p-type impurity concentration higher than that of the body region 13. Each of the contact regions 17 covers the side wall and the bottom wall of each of the source structures, and is electrically connected to the body region 13.

The MISFET structure 12 includes a plurality of well regions 18 of the p-type that are each formed in a region along the source structure 16 inside the chip 2. Each of the well regions 18 may have a p-type impurity concentration higher than that of the body region 13 and less than that of the contact regions 17. Each of the well regions 18 covers the corresponding source structure 16 with the corresponding contact region 17 interposed therebetween. Each of the well regions 18 covers the side wall and the bottom wall of the corresponding source structure 16, and is electrically connected to the body region 13 and the contact regions 17.

With reference to FIG. 5, the semiconductor device 1A includes an outer contact region 19 of the p-type that is formed in a surface layer portion of the outer surface 9. The outer contact region 19 has a p-type impurity concentration higher than that of the body region 13. The outer contact region 19 is formed at intervals from a peripheral edge of the active surface 8 and a peripheral edge of the outer surface 9, and is formed in a band shape extending along the active surface 8 in plan view.

The outer contact region 19 is formed in an annular shape (specifically, a quadrangle annular shape) surrounding the active surface 8 in plan view, in this embodiment. The outer contact region 19 is formed at an interval to the outer surface 9 side from the bottom portion of the first semiconductor region 6. The outer contact region 19 is positioned on the bottom portion side of the first semiconductor region 6 with respect to the bottom walls of the plurality of gate structures 15 (the plurality of source structures 16).

The semiconductor device 1A includes an outer well region 20 of the p-type that is formed in the surface layer portion of the outer surface 9. The outer well region 20 has a p-type impurity concentration less than that of the outer contact region 19. The p-type impurity concentration of the outer well region 20 is preferably substantially equal to the p-type impurity concentration of the well regions 18. The outer well region 20 is formed in a region between the peripheral edge of the active surface 8 and the outer contact region 19, and is formed in a band shape extending along the active surface 8 in plan view.

The outer well region 20 is formed in an annular shape (specifically, a quadrangle annular shape) surrounding the active surface 8 in plan view, in this embodiment. The outer well region 20 is formed at an interval to the outer surface 9 side from the bottom portion of the first semiconductor region 6. The outer well region 20 may be formed deeper than the outer contact region 19. The outer well region 20 is positioned on the bottom portion side of the first semiconductor region 6 with respect to the plurality of gate structures 15 (the plurality of source structures 16).

The outer well region 20 is electrically connected to the outer contact region 19. The outer well region 20 extends toward the first to fourth connecting surfaces 10A to 10D side from the outer contact region 19 side, and covers the first to fourth connecting surfaces 10A to 10D, in this embodiment. The outer well region 20 is electrically connected to the body region 13 in the surface layer portion of the active surface 8.

The semiconductor device 1A includes at least one (preferably, not less than 2 and not more than 20) field region 21 of the p-type that is formed in a region between the peripheral edge of the outer surface 9 and the outer contact region 19 in the surface layer portion of the outer surface 9. The semiconductor device 1A includes five field regions 21, in this embodiment. The plurality of field regions 21 relaxes an electric field inside the chip 2 at the outer surface 9. A number, a width, a depth, a p-type impurity concentration, etc., of the field region 21 are arbitrary, and various values can be taken depending on the electric field to be relaxed.

The plurality of field regions 21 are arrayed at intervals from the outer contact region 19 side to the peripheral edge side of the outer surface 9. The plurality of field regions 21 are each formed in a band shape extending along the active surface 8 in plan view. The plurality of field regions 21 are each formed in an annular shape (specifically, a quadrangle annular shape) surrounding the active surface 8 in plan view, in this embodiment. Thus, the plurality of field regions 21 are each formed as an FLR (Field Limiting Ring) region.

The plurality of field regions 21 are formed at intervals to the outer surface 9 side from the bottom portion of the first semiconductor region 6. The plurality of field regions 21 are positioned on the bottom portion side of the first semiconductor region 6 with respect to the bottom walls of the plurality of gate structures 15 (the plurality of source structures 16). The plurality of field regions 21 may be formed deeper than the outer contact region 19. The innermost field region 21 may be connected to the outer contact region 19.

The semiconductor device 1A includes a main surface insulating film 25 that covers the first main surface 3. The main surface insulating film 25 may include at least one of a silicon oxide film, a silicon nitride film and a silicon oxynitride film. The main surface insulating film 25 has a single layered structure consisting of the silicon oxide film, in this embodiment. The main surface insulating film 25 particularly preferably includes the silicon oxide film that consists of an oxide of the chip 2.

The main surface insulating film 25 covers the active surface 8, the outer surface 9 and the first to fourth connecting surfaces 10A to 10D. The main surface insulating film 25 covers the active surface 8 such as to be continuous to the gate insulating film 15b and the source insulating film 16b and to expose the gate embedded electrode 15c and the source embedded electrode 16c. The main surface insulating film 25 covers the outer surface 9 and the first to fourth connecting surfaces 10A to 10D such as to cover the outer contact region 19, the outer well region 20 and the plurality of field regions 21.

The main surface insulating film 25 may be continuous to the first to fourth side surfaces 5A to 5D. In this case, an outer wall of the main surface insulating film 25 may consist of a ground surface with grinding marks. The outer wall of the main surface insulating film 25 may form a single ground surface with the first to fourth side surfaces 5A to 5D. As a matter of course, the outer wall of the main surface insulating film 25 may be formed at an interval inward from the peripheral edge of the outer surface 9 and may expose the first semiconductor region 6 from a peripheral edge portion of the outer surface 9.

The semiconductor device 1A includes a side wall structure 26 that is formed on the main surface insulating film 25 such as to cover at least one of the first to fourth connecting surfaces 10A to 10D at the outer surface 9. The side wall structure 26 is formed in an annular shape (a quadrangle annular shape) surrounding the active surface 8 in plan view, in this embodiment. The side wall structure 26 may have a portion that overlaps onto the active surface 8. The side wall structure 26 may include an inorganic insulator or a polysilicon. The side wall structure 26 may be a side wall wiring that is electrically connected to the plurality of source structures 16.

The semiconductor device 1A includes an interlayer insulating film 27 that is formed on the main surface insulating film 25. The interlayer insulating film 27 may include at least one of a silicon oxide film, a silicon nitride film and a silicon oxynitride film. The interlayer insulating film 27 has a single layered structure consisting of the silicon oxide film, in this embodiment.

The interlayer insulating film 27 covers the active surface 8, the outer surface 9 and the first to fourth connecting surfaces 10A to 10D with the main surface insulating film 25 interposed therebetween. Specifically, the interlayer insulating film 27 covers the active surface 8, the outer surface 9 and the first to fourth connecting surfaces 10A to 10D across the side wall structure 26. The interlayer insulating film 27 covers the MISFET structure 12 on the active surface 8 side and covers the outer contact region 19, the outer well region 20 and the plurality of field regions 21 on the outer surface 9 side.

The interlayer insulating film 27 is continuous to the first to fourth side surfaces 5A to 5D, in this embodiment. An outer wall of the interlayer insulating film 27 may consist of a ground surface with grinding marks. The outer wall of the interlayer insulating film 27 may form a single ground surface with the first to fourth side surfaces 5A to 5D. As a matter of course, the outer wall of the interlayer insulating film 27 may be formed at an interval inward from the peripheral edge portion of the outer surface 9 and may expose the first semiconductor region 6 from the peripheral edge portion of the outer surface 9.

The semiconductor device 1A includes a gate electrode 30 that is arranged on the first main surface 3 (the interlayer insulating film 27). The gate electrode 30 may be referred to as a “gate main surface electrode”. The gate electrode 30 is arranged at an inner portion of the first main surface 3 at an interval from the peripheral edge of the first main surface 3. The gate electrode 30 is arranged on the active surface 8, in this embodiment. Specifically, the gate electrode 30 is arranged on a region adjacent a central portion of the third connecting surface 10C (the third side surface 5C) at the peripheral edge portion of the active surface 8. The gate electrode 30 is formed in a quadrangle shape in plan view, in this embodiment. As a matter of course, the gate electrode 30 may be formed in a polygonal shape other than the quadrangle shape, a circular shape, or an elliptical shape in plan view.

The gate electrode 30 preferably has a planar area of not more than 25% of the first main surface 3. The planar area of the gate electrode 30 may be not more than 10% of the first main surface 3. The gate electrode 30 may have a thickness of not less than 0.5 μm and not more than 15 μm. The gate electrode 30 may include at least one of a Ti film, a TiN film, a W film, an Al film, a Cu film, an Al alloy film, a Cu alloy film and a conductive polysilicon film.

The gate electrode 30 may include at least one of a pure Cu film (Cu film with a purity of not less than 99%), a pure Al film (Al film with a purity of not less than 99%), an AlCu alloy film, an AlSi alloy film and an AlSiCu alloy film. The gate electrode 30 has a laminated structure that includes the Ti film and the Al alloy film (in this embodiment, AlSiCu alloy film) laminated in that order from the chip 2 side, in this embodiment.

The semiconductor device 1A includes a source electrode 32 that is arranged on the first main surface 3 (the interlayer insulating film 27) at an interval from the gate electrode 30. The source electrode 32 may be referred to as a “source main surface electrode”. The source electrode 32 is arranged at an inner portion of the first main surface 3 at an interval from the peripheral edge of the first main surface 3. The source electrode 32 is arranged on the active surface 8, in this embodiment. The source electrode 32 has a body electrode portion 33 and at least one (in this embodiment, a plurality of) drawer electrode portions 34A, 34B, in this embodiment.

The body electrode portion 33 is arrange at a region on the fourth side surface 5D (the fourth connecting surface 10D) side at an interval from the gate electrode 30 and faces the gate electrode 30 in the first direction X, in plan view. The body electrode portion 33 is formed in a polygonal shape (specifically, quadrangle shape) that has four sides parallel to the first to fourth side surfaces 5A to 5D in plan view, in this embodiment.

The plurality of drawer electrode portions 34A, 34B include a first drawer electrode portion 34A on one side (the first side surface 5A side) and a second drawer electrode portion 34B on the other side (the second side surface 5B side). The first drawer electrode portion 34A is drawn out from the body electrode portion 33 onto a region located on one side (the first side surface 5A side) of the second direction Y with respect to the gate electrode 30, and faces the gate electrode 30 in the second direction Y, in plan view.

The second drawer electrode portion 34B is drawn out from the body electrode portion 33 onto a region located on the other side (the second side surface 5B side) of the second direction Y with respect to the gate electrode 30, and faces the gate electrode 30 in the second direction Y, in plan view. That is, the plurality of drawer electrode portions 34A, 34B sandwich the gate electrode 30 from both sides of the second direction Y, in plan view.

The source electrode 32 (the body electrode portion 33 and the drawer electrode portions 34A, 34B) penetrates the interlayer insulating film 27 and the main surface insulating film 25, and is electrically connected to the plurality of source structures 16, the source region 14 and the plurality of well regions 18. As a matter of course, the source electrode 32 does not may have the drawer electrode portions 34A, 34B and may consist only of the body electrode portion 33.

The source electrode 32 has a planar area exceeding the planar are of the gate electrode 30. The planar area of the source electrode 32 is preferably not less than 50% of the first main surface 3. The planar are of the source electrode 32 is particularly preferably not less than 75% of the first main surface 3. The source electrode 32 may have a thickness of not less than 0.5 μm and not more than 15 μm. The source electrode 32 may include at least one of a Ti film, a TiN film, a W film, an Al film, a Cu film, an Al alloy film, a Cu alloy film and a conductive polysilicon film.

The source electrode 32 may include at least one of a pure Cu film (Cu film with a purity of not less than 99%), a pure Al film (Al film with a purity of not less than 99%), an AlCu alloy film, an AlSi alloy film and an AlSiCu alloy film. The source electrode 32 has a laminated structure that includes the Ti film and the Al alloy film (in this embodiment, AlSiCu alloy film) laminated in that order from the chip 2 side, in this embodiment. The source electrode 32 preferably has the same conductive material as that of the gate electrode 30.

The semiconductor device 1A includes at least one (in this embodiment, a plurality of) gate wirings 36A, 36B that are drawn out from the gate electrode 30 onto the first main surface 3 (the interlayer insulating film 27). The plurality of gate wirings 36A, 36B preferably include the same conductive material as that of the gate electrode 30. The plurality of gate wirings 36A, 36B cover the active surface 8 and do not cover the outer surface 9, in this embodiment. The plurality of gate wirings 36A, 36B are drawn out into a region between the peripheral edge of the active surface 8 and the source electrode 32 and each extends in a band shape along the source electrode 32 in plan view.

Specifically, the plurality of gate wirings 36A, 36B include a first gate wiring 36A and a second gate wiring 36B. The first gate wiring 36A is drawn out from the gate electrode 30 into a region on the first side surface 5A side in plan view. The first gate wiring 36A includes a portion extending as a band shape in the second direction Y along the third side surface 5C and a portion extending as a band shape in the first direction X along the first side surface 5A. The second gate wiring 36B is drawn out from the gate electrode 30 into a region on the second side surface 5B side in plan view. The second gate wiring 36B includes a portion extending as a band shape in the second direction Y along the third side surface 5C and a portion extending as a band shape in the first direction X along the second side surface 5B.

The plurality of gate wirings 36A, 36B intersect (specifically, perpendicularly intersect) both end portions of the plurality of gate structures 15 at the peripheral edge portion of the active surface 8 (the first main surface 3). The plurality of gate wirings 36A, 36B penetrate the interlayer insulating film 27 and are electrically connected to the plurality of gate structures 15. The plurality of gate wirings 36A, 36B may be directly connected to the plurality of gate structures 15, or may be electrically connected to the plurality of gate structures 15 via a conductor film.

The semiconductor device 1A includes a source wiring 37 that is drawn out from the source electrode 32 onto the first main surface 3 (the interlayer insulating film 27). The source wiring 37 preferably includes the same conductive material as that of the source electrode 32. The source wiring 37 is formed in a band shape extending along the peripheral edge of the active surface 8 at a region located on the outer surface 9 side than the plurality of gate wirings 36A, 36B. The source wiring 37 is formed in an annular shape (specifically, a quadrangle annular shape) surrounding the gate electrode 30, the source electrode 32 and the plurality of gate wirings 36A, 36B in plan view, in this embodiment.

The source wiring 37 covers the side wall structure 26 with the interlayer insulating film 27 interposed therebetween and is drawn out from the active surface 8 side to the outer surface 9 side. The source wiring 37 preferably covers a whole region of the side wall structure 26 over an entire circumference. The source wiring 37 penetrates the interlayer insulating film 27 and the main surface insulating film 25 on the outer surface 9 side, and has a portion connected to the outer surface 9 (specifically, the outer contact region 19). The source wiring 37 may penetrate the interlayer insulating film 27 and may be electrically connected to the side wall structure 26.

The semiconductor device 1A includes an upper insulating film 38 that selectively covers the gate electrode 30, the source electrode 32, the plurality of gate wirings 36A, 36B and the source wiring 37. The upper insulating film 38 has a gate opening 39 exposing an inner portion of the gate electrode 30 and covers a peripheral edge portion of the gate electrode 30 over an entire circumference. The gate opening 39 is formed in a quadrangle shape in plan view, in this embodiment.

The upper insulating film 38 has a source opening 40 exposing an inner portion of the source electrode 32 and covers a peripheral edge portion of the source electrode 32 over an entire circumference. The source opening 40 is formed in a polygonal shape along the source electrode 32 in plan view, in this embodiment. The upper insulating film 38 covers whole regions of the plurality of gate wirings 36A, 36B and a whole region of the source wiring 37.

The upper insulating film 38 covers the side wall structure 26 with the interlayer insulating film 27 interposed therebetween, and is drawn out from the active surface 8 side to the outer surface 9 side. The upper insulating film 38 is formed at an interval inward from the peripheral edge of the outer surface 9 (the first to fourth side surfaces 5A to 5D) and covers the outer contact region 19, the outer well region 20 and the plurality of field regions 21. The upper insulating film 38 defines a dicing street 41 with the peripheral edge of the outer surface 9.

The dicing street 41 is formed in a band shape extending along the peripheral edge of the outer surface 9 (the first to fourth side surfaces 5A to 5D) in plan view. The dicing street 41 is formed in an annular shape (specifically, a quadrangle annular shape) surrounding the inner portion of the first main surface 3 (the active surface 8) in plan view, in this embodiment. The dicing street 41 exposes the interlayer insulating film 27, in this embodiment.

As a matter of course, in a case in which the main surface insulating film 25 and the interlayer insulating film 27 expose the outer surface 9, the dicing street 41 may expose the outer surface 9. The dicing street 41 may have a width of not less than 1 μm and not more than 200 μm. The width of the dicing street 41 is a width in a direction orthogonal to an extending direction of the dicing street 41. The width of the dicing street 41 is preferably not less than 5 μm and not more than 50 μm.

The upper insulating film 38 preferably has a thickness exceeding the thickness of the gate electrode 30 and the thickness of the source electrode 32. The thickness of the upper insulating film 38 is preferably less than the thickness of the chip 2. The thickness of the upper insulating film 38 may be not less than 3 μm and not more than 35 μm. The thickness of the upper insulating film 38 is preferably not more than 25 μm.

The upper insulating film 38 has a laminated structure that includes an inorganic insulating film 42 and an organic insulating film 43 laminated in that order form the chip 2 side, in this embodiment. The upper insulating film 38 may include at least one of the inorganic insulating film 42 and the organic insulating film 43, and does not necessarily have to include the inorganic insulating film 42 and the organic insulating film 43 at the same time. The inorganic insulating film 42 selectively covers the gate electrode 30, the source electrode 32, the plurality of gate wirings 36A, 36B and the source wiring 37, and defines a part of the gate opening 39, a part of the source opening 40 and a part of the dicing street 41.

The inorganic insulating film 42 may include at least one of a silicon oxide film, a silicon nitride film and a silicon oxynitride film. The inorganic insulating film 42 preferably includes an insulating material different from that of the interlayer insulating film 27. The inorganic insulating film 42 preferably includes the silicon nitride film. The inorganic insulating film 42 preferably has a thickness less than the thickness of the interlayer insulating film 27. The thickness of the inorganic insulating film 42 may be not less than 0.1 μm and not more than 5 μm.

The organic insulating film 43 selectively covers the inorganic insulating film 42, and defines a part of the gate opening 39, a part of the source opening 40 and a part of the dicing street 41. Specifically, the organic insulating film 43 partially exposes the inorganic insulating film 42 in a wall surface of the gate opening 39. Also, the organic insulating film 43 partially exposes the inorganic insulating film 42 in a wall surface of the source opening 40. Also, the organic insulating film 43 partially exposes the inorganic insulating film 42 in a wall surface of the dicing street 41.

As a matter of course, the organic insulating film 43 may cover the inorganic insulating film 42 such that the inorganic insulating film 42 does not expose from the wall surface of the gate opening 39. The organic insulating film 43 may cover the inorganic insulating film 42 such that the inorganic insulating film 42 does not expose from the wall surface of the source opening 40. The organic insulating film 43 may cover the inorganic insulating film 42 such that the inorganic insulating film 42 does not expose from the wall surface of the dicing street 41. In those cases, the organic insulating film 43 may cover a whole region of the inorganic insulating film 42.

The organic insulating film 43 preferably consists of a resin film other than a thermosetting resin. The organic insulating film 43 may consist of a translucent resin or a transparent resin. The organic insulating film 43 may consist of a negative type photosensitive resin film or a positive type photosensitive resin film. The organic insulating film 43 preferably consists of a polyimide film, a polyamide film or a polybenzoxazole film. The organic insulating film 43 includes the polybenzoxazole film, in this embodiment.

The organic insulating film 43 preferably has a thickness exceeding the thickness of the inorganic insulating film 42. The thickness of the organic insulating film 43 preferably exceeds the thickness of the interlayer insulating film 27. The thickness of the organic insulating film 43 particularly preferably exceeds the thickness of the gate electrode 30 and the thickness of the source electrode 32. The thickness of the organic insulating film 43 may be not less than 3 μm and not more than 30 μm. The thickness of the organic insulating film 43 is preferably not more than 20 μm.

The semiconductor device 1A includes at least one (in this embodiment, one) gate pillar electrode 50 that is arranged on the gate electrode 30. The number of the gate pillar electrode 50 is arbitrary and is adjusted in accordance with a planar area of the gate electrode 30 and a planar area of the gate pillar electrode 50 to be formed. The gate pillar electrode 50 is erected in a vertically long columnar shape on the gate electrode 30 at an interval from a peripheral edge of the gate electrode 30 in cross sectional view.

The gate pillar electrode 50 is arranged on an inner the gate electrode 30 at an interval from the upper portion of insulating film 38 (the wall surface of the gate opening 39) in this embodiment. That is, the gate pillar electrode 50 is arranged inside a region surrounded by the gate opening 39 in plan view. The gate pillar electrode 50 is formed in a circular shape in plan view in this embodiment. As a matter of course, the gate pillar electrode 50 may be formed in a quadrilateral shape, a polygonal shape other than the quadrilateral shape, an elliptical shape, or a line shape in plan view.

The gate pillar electrode 50 has a gate electrode surface 51 and a gate electrode side wall 52. The gate electrode surface 51 extends flatly along the first main surface 3. The gate electrode surface 51 may consist of a ground surface with grinding marks. The gate electrode side wall 52 is positioned on the gate electrode 30. The gate electrode side wall 52 extends substantially vertically in the normal direction Z. “Substantially vertically” also includes a mode that extends in a lamination direction while curving (meandering). The gate electrode side wall 52 preferably consists of a smooth surface without grinding marks.

The gate pillar electrode 50 has a first protrusion portion 53 that protrudes outward at a lower end portion of the gate electrode side wall 52 in this embodiment. The first protrusion portion 53 is formed in a region further to the gate electrode 30 side than an intermediate portion of the gate electrode side wall 52. The first protrusion portion 53 is formed in a tapered shape that extends along an outer surface of the gate electrode 30 and gradually decreases in thickness from the gate electrode side wall 52 toward a tip portion in cross sectional view. The first protrusion portion 53 thereby has a tip portion of sharp-pointed shape that forms an acute angle. As a matter of course, the gate pillar electrode 50 without the first protrusion portion 53 may be formed.

Preferably, the gate pillar electrode 50 has a thickness exceeding the thickness of the gate electrode 30. The thickness of the gate pillar electrode 50 is defined by a distance between the gate electrode 30 and the gate electrode surface 51. The thickness of the gate pillar electrode 50 particularly preferably exceeds the thickness of the upper insulating film 38. The thickness of the gate pillar electrode 50 exceeds the thickness of the chip 2 in this embodiment. As a matter of course, the thickness of the gate pillar electrode 50 may be less than the thickness of the chip 2.

The thickness of the gate pillar electrode 50 may be not less than 10 μm and not more than 300 μm. The thickness of the gate pillar electrode 50 is preferably not less than 30 μm. The thickness of the gate pillar electrode 50 is particularly preferably not less than 80 μm and not more than 200 μm. A width (maximum value) of the gate pillar electrode 50 may be not less than 1 μm and not more than 200 μm.

The width (maximum value) of the gate pillar electrode 50 may be of a value belonging to any range among not less than 1 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, and not less than 175 μm and not more than 200 μm. As a matter of course, the width (maximum value) of the gate pillar electrode 50 is not restricted to the above ranges and may be set to a value exceeding 200 μm.

The gate pillar electrode 50 has a planar area less than the planar area of the gate electrode 30. The planar area of the gate pillar electrode 50 is adjusted in accordance with the planar area of the gate electrode 30. The planar area of the gate pillar electrode 50 may be not more than 25% of the first main surface 3. The planar area of the gate pillar electrode 50 is preferably not more than 10% of the first main surface 3.

The gate pillar electrode 50 has a laminated structure that includes a first gate conductor film 55 and a second gate conductor film 56 laminated in that order from the gate electrode 30 side, in this embodiment. The first gate conductor film 55 may include a Ti-based metal film. The first gate conductor film 55 may have a single layered structure consisting of a Ti film or a TiN film. The first gate conductor film 55 may have a laminated structure that includes the Ti film and the TiN film laminated with an arbitrary order.

The first gate conductor film 55 has a thickness less than the thickness of the gate electrode 30. The first gate conductor film 55 covers the gate electrode 30 in a film shape inside the gate opening 39. The first gate conductor film 55 forms a part of the first protrusion portion 53. The first gate conductor film 55 does not necessarily have to be formed and may be omitted.

The second gate conductor film 56 forms a body of the gate pillar electrode 50. The second gate conductor film 56 may include a Cu-based metal film. The Cu-based metal film may be a pure Cu film (Cu film with a purity of not less than 99%) or Cu alloy film. The second gate conductor film 56 includes a pure Cu plating film, in this embodiment. The second gate conductor film 56 preferably has a thickness exceeding the thickness of the gate electrode 30. The thickness of the second gate conductor film 56 particularly preferably exceeds the thickness of the upper insulating film 38. The thickness of the second gate conductor film 56 exceeds the thickness of the chip 2, in this embodiment.

The second gate conductor film 56 covers the gate electrode 30 with the first gate conductor film 55 interposed therebetween inside the gate opening 39. The second gate conductor film 56 forms a part of the first protrusion portion 53. That is, the first protrusion portion 53 has a laminated structure that includes the first gate conductor film 55 and the second gate conductor film 56. The second gate conductor film 56 has a thickness exceeding the thickness of the first gate conductor film 55 in the first protrusion portion 53.

The semiconductor device 1A includes a plurality of source pillar electrodes 60 that are arranged on the source electrode 32. The number of the source pillar electrodes 60 is arbitrary and is adjusted in accordance with a planar area of the source electrode 32 and a planar area of the source pillar electrodes 60 to be formed. The source pillar electrodes 60 are each erected in a vertically long columnar shape on the source electrode 32 at an interval from a peripheral edge of the source electrode 32 in cross sectional view.

The plurality of source pillar electrodes 60 are each arranged on an inner portion of the source electrode 32 at an interval from the upper insulating film 38 (the wall surface of the source opening 40) in this embodiment. That is, the plurality of source pillar electrodes 60 are each arranged inside a region surrounded by the source opening 40 in plan view. The plurality of source pillar electrodes 60 are arranged on the body electrode portion 33 of the source electrode 32 and are not arranged on the drawer electrode portions 34A and 34B of the source electrode 32 in this embodiment.

The plurality of source pillar electrodes 60 are each formed in a circular shape in plan view in this embodiment. As a matter of course, the plurality of source pillar electrodes 60 may each be formed in a quadrilateral shape, a polygonal shape other than the quadrilateral shape, an elliptical shape, or a line shape in plan view. Also, the plurality of source pillar electrodes 60 do not need to have mutually the same planar shape and may have mutually different planar shapes.

The plurality of source pillar electrodes 60 are arrayed in a matrix pattern at intervals in the first direction X and the second direction Y in plan view in this embodiment. A layout of the plurality of source pillar electrodes 60 is arbitrary. The plurality of source pillar electrodes 60 may, for example, be arrayed in a staggered pattern at intervals in the first direction X and the second direction Y in plan view.

That is, in a case in which a plurality of groups, each including the plurality of source pillar electrodes 60 that are arrayed in a single row in the first direction X, are arrayed at intervals in the second direction Y, the plurality of source pillar electrodes 60 included in each group may be arranged to be shifted in the first direction X with respect to the plurality of source pillar electrodes 60 included in a group that is adjacent in the second direction Y. As a matter of course, in this structure, a layout in which the array relationship in the first direction X and the second direction Y is interchanged may be adopted.

Also, in a case in which the plurality of source pillar electrodes 60 are formed in line shapes extending in the first direction X or the second direction Y in plan view, the plurality of source pillar electrodes 60 may be arranged in stripes extending in the first direction X or the second direction Y in plan view. As a matter of course, the plurality of source pillar electrodes 60 may be arranged in an irregular layout.

The plurality of source pillar electrodes 60 each have a source electrode surface 61 and a source electrode side wall 62. The source electrode surface 61 extends flatly along the first main surface 3. The source electrode surface 61 may consist of a ground surface with grinding marks. The source electrode side wall 62 is positioned on the source electrode 32. The source electrode side wall 62 extends substantially vertically in the normal direction Z. “Substantially vertically” also includes a mode that extends in the lamination direction while curving (meandering). The source electrode side wall 62 preferably consists of a smooth surface without grinding marks.

The plurality of source pillar electrodes 60 each have a second protrusion portion 63 that protrudes outward at a lower end portion of the source electrode side wall 62 in this embodiment. The second protrusion portion 63 is formed in a region further to the source electrode 32 side than an intermediate portion of the source electrode side wall 62. The second protrusion portion 63 is formed in a tapered shape that extends along the source electrode 32 and gradually decreases in thickness from the source electrode side wall 62 toward a tip portion in cross sectional view. The second protrusion portion 63 thereby has a tip portion of sharp-pointed shape that forms an acute angle. As a matter of course, the source pillar electrode 60 without the second protrusion portion 63 may be formed.

Preferably, the plurality of source pillar electrodes 60 each have a thickness exceeding the thickness of the source electrode 32. The thickness of each source pillar electrode 60 is defined by a distance between the source electrode 32 and the source electrode surface 61. The thickness of each source pillar electrode 60 particularly preferably exceeds the thickness of the upper insulating film 38. The thickness of each source pillar electrode 60 exceeds the thickness of the chip 2 in this embodiment. As a matter of course, the thickness of the source pillar electrode 60 may be less than the thickness of the chip 2.

The thickness of each source pillar electrode 60 may be not less than 10 μm and not more than 300 μm. The thickness of each source pillar electrode 60 is preferably not less than 30 μm. The thickness of each source pillar electrode 60 is particularly preferably not less than 80 μm and not more than 200 μm. The thickness of each source pillar electrode 60 is substantially equal to the thickness of the gate pillar electrode 50.

A width (maximum value) of each source pillar electrode 60 may be of a value belonging to any range among not less than 1 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, and not less than 175 μm and not more than 200 μm. As a matter of course, the width (maximum value) of each source pillar electrode 60 is not restricted to the above ranges and may be set to a value exceeding 200 μm.

The plurality of source pillar electrodes 60 have a total planar area less than the planar area of the source electrode 32. The total planar area of the plurality of source pillar electrodes 60 is adjusted in accordance with the planar area of the source electrode 32. The total planar area of the plurality of source pillar electrodes 60 preferably exceeds the planar area of the gate pillar electrode 50.

A planar area of each source pillar electrode 60 may be substantially equal to the planar area of the gate pillar electrode 50 or may exceed the planar area of the gate pillar electrode 50 or may be less than the planar area of the gate pillar electrode 50. The total planar area of the plurality of source pillar electrodes 60 is preferably not more than 50% of the first main surface 3. The total planar area of the plurality of source pillar electrodes 60 is particularly preferably not more than 30% of the first main surface 3. The total planar area of the plurality of source pillar electrodes 60 is preferably not less than 10% of the first main surface 3.

The source pillar electrode 60 has a laminated structure that includes a first source conductor film 67 and a second source conductor film 68 laminated in that order from the source electrode 32 side, respectively, in this embodiment. The first source conductor film 67 may include a Ti-based metal film. The first source conductor film 67 may have a single layered structure consisting of a Ti film or a TiN film. The first source conductor film 67 may have a laminated structure that includes the Ti film and the TiN film with an arbitrary order. The first source conductor film 67 preferably consists of the same conductive material of that of the first gate conductor film 55.

The first source conductor film 67 has a thickness less than the thickness of the source electrode 32. The first source conductor film 67 covers the source electrode 32 in a film shape inside the source opening 40. The first source conductor film 67 forms a part of the second protrusion portion 63. The thickness of the first source conductor film 67 is substantially equal to the thickness of the first gate conductor film 55. The first source conductor film 67 does not necessarily have to be formed and may be omitted.

The second source conductor film 68 forms a body of the source pillar electrode 60. The second source conductor film 68 may include a Cu-based metal film. The Cu-based metal film may be a pure Cu film (Cu film with a purity of not less than 99%) or Cu alloy film. The second source conductor film 68 includes a pure Cu plating film, in this embodiment. The second source conductor film 68 preferably consists of the same conductive material of that of the second gate conductor film 56.

The second source conductor film 68 preferably has a thickness exceeding the thickness of the source electrode 32. The thickness of the second source conductor film 68 particularly preferably exceeds the thickness of the upper insulating film 38. The thickness of the second source conductor film 68 exceeds the thickness of the chip 2, in this embodiment. The thickness of the second source conductor film 68 is substantially equal to the thickness of the second gate conductor film 56.

The second source conductor film 68 covers the first source conductor film 67 inside the source opening 40. The second source conductor film 68 forms a part of the second protrusion portion 63. That is, the second protrusion portion 63 has a laminated structure that includes the first source conductor film 67 and the second source conductor film 68. The second source conductor film 68 preferably has a thickness exceeding the thickness of the first source conductor film 67 in the second protrusion portion 63.

The semiconductor device 1A includes a sealing insulator 71 that covers the first main surface 3. The sealing insulator 71 covers a periphery of the gate pillar electrode 50 and peripheries of the source pillar electrodes 60 such as to expose a part of the gate pillar electrode 50 and parts of the source pillar electrodes 60 on the first main surface 3. Specifically, the sealing insulator 71 covers the active surface 8, the outer surface 9 and the first to fourth connecting surfaces 10A to 10D.

The sealing insulator 71 covers the gate pillar electrode 50 on the gate electrode 30. The sealing insulator 71 exposes the gate electrode surface 51 and covers the gate electrode side wall 52. The sealing insulator 71 has a portion that directly covers a portion of the gate electrode 30 that is exposed from the upper insulating film 38 and the gate pillar electrode 50. The sealing insulator 71 covers the first protrusion portion 53 of the gate pillar electrode 50 and opposes the gate electrode 30 with the first protrusion portion 53 interposed therebetween in this embodiment. The sealing insulator 71 suppresses falling-off of the gate pillar electrode 50.

The sealing insulator 71 covers a region between the plurality of source pillar electrodes 60 on the source electrode 32. The sealing insulator 71 exposes the plurality of source electrode surfaces 61 and covers the plurality of source electrode side walls 62. The sealing insulator 71 has a portion that directly covers a portion of the source electrode 32 that is exposed from the upper insulating film 38 and the plurality of source pillar electrodes 60. The sealing insulator 71 covers the second protrusion portions 63 of the plurality of source pillar electrodes 60 and opposes the source electrode 32 with the second protrusion portions 63 interposed therebetween in this embodiment. The sealing insulator 71 suppresses falling-off of the plurality of source pillar electrodes 60.

The sealing insulator 71 has a portion that directly covers the upper insulating film 38. The sealing insulator 71 covers the gate electrode 30 with the upper insulating film 38 interposed therebetween and covers the source electrode 32 with the upper insulating film 38 interposed therebetween. The sealing insulator 71 covers the dicing street 41 at the peripheral edge portion of the outer surface 9. The sealing insulator 71 directly covers the interlayer insulating film 27 at the dicing street 41 in this embodiment. As a matter of course, in a case in which the chip 2 (outer surface 9) and the main surface insulating film 25 are exposed from the dicing street 41, the sealing insulator 71 may directly cover the chip 2 and the main insulating film 25 at the dicing street 41.

The sealing insulator 71 has an insulating main surface 72 and an insulating side wall 73. The insulating main surface 72 flatly extends along the first main surface 3. The insulating main surface 72 forms a single flat surface with the gate electrode surface 51 and the source electrode surfaces 61. The insulating main surface 72 may consist of a ground surface with grinding marks. In this case, the insulating main surface 72 preferably forms a single ground surface with the gate electrode surface 51 and the source electrode surfaces 61.

The insulating side wall 73 extends toward the chip 2 from a peripheral edge of the insulating main surface 72 and forms a single flat surface with the first to fourth side surfaces 5A to 5D. The insulating side wall 73 is formed substantially perpendicular to the insulating main surface 72. The angle formed by the insulating side wall 73 with the insulating main surface 72 may be not less than 88° and not more than 92°. The insulating side wall 73 may consist of a ground surface with grinding marks. The insulating side wall 73 may form a single ground surface with the first to fourth side surfaces 5A to 5D.

The sealing insulator 71 preferably has a thickness exceeding the thickness of the gate electrode 30 and the thickness of the source electrode 32. The thickness of the sealing insulator 71 particularly preferably exceeds the thickness of the upper insulating film 38. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 um and not more than 300 μm. The thickness of the sealing insulator 71 is preferably not less than 30 μm. The thickness of the sealing insulator 71 is particularly preferably not less than 80 μm and not more than 200 μm. The thickness of the sealing insulator 71 is substantially equal to the thickness of the gate pillar electrode 50 and the thickness of the source pillar electrode 60.

The sealing insulator 71 includes a matrix resin, a plurality of fillers and a plurality of flexible particles (flexible agent). The sealing insulator 71 is configured such that a mechanical strength is adjusted by the matrix resin, the plurality of fillers and the plurality of flexible particles. The sealing insulator 71 may include at least the matrix resin, and the presence or the absence of the fillers and the flexible particles is optional.

The sealing insulator 71 may include a coloring material such as carbon black that colors the matrix resin. The matrix resin preferably consists of a thermosetting resin. The matrix resin may include at least one of an epoxy resin, a phenol resin and a polyimide resin as an example of the thermosetting resin. The matrix resin includes the epoxy resin, in this embodiment.

The plurality of fillers are added into the matrix resin and are composed of one of or both of spherical objects each consisting of an insulator and indeterminate objects each consisting of an insulator. The indeterminate object has a random shape other than a sphere shape such as a grain shape, a piece shape and a fragment shape. The indeterminate object may have an edge. The plurality of fillers are each composed of the spherical object from a viewpoint of suppressing a damage to be caused by a filler attack, in this embodiment.

The plurality of fillers may include at least one of ceramics, oxides and nitrides. The plurality of fillers each consist of silicon oxide particles (silicon particles), in this embodiment. The plurality of fillers may each have a particle size of not less than 1 nm and not more than 100 μm. The particle sizes of the plurality of fillers are preferably not more than 50 μm.

The sealing insulator 71 preferably include the plurality of fillers differing in the particle sizes. The plurality of fillers may include a plurality of small size fillers, a plurality of medium size fillers and a plurality of large size fillers. The plurality of fillers are preferably added into the matrix resin with a content (density) being in this order of the small size fillers, the medium size fillers and the large size fillers.

The small size fillers may have a thickness less than the thickness of the source electrode 32 (the gate electrode 30). The particle sizes of the small size fillers may be not less than 1 nm and not more than 1 μm. The medium size fillers may have a thickness exceeding the thickness of the source electrode 32 and not more than the thickness of the upper insulating film 38. The particle sizes of the medium size fillers may be not less than 1 μm and not more than 20 μm.

The large size fillers may have a thickness exceeding the thickness of the upper insulating film 38. The plurality of fillers may include at least one large size filler exceeding any one of the thickness of the first semiconductor region 6 (the epitaxial layer), the thickness of the second semiconductor region 7 (the substrate) and the thickness of the chip 2. The particle sizes of the large size fillers may be not less than 20 μm and not more than 100 μm. The particle sizes of the large size fillers are preferably not more than 50 μm.

An average particle size of the plurality of fillers may be not less than 1 μm and not more than 10 μm. The average particle size of the plurality of fillers is preferably not less than 4 μm and not more than 8 μm. As a matter of course, the plurality of fillers does not necessarily have to include all of the small size fillers, the medium size fillers and the large size fillers at the same time, and may be composed of one of or both of the small size fillers and the medium size fillers. For example, in this case, a maximum particle size of the plurality of fillers (the medium size fillers) may be not more than 10 μm.

The sealing insulator 71 may include a plurality of filler fragments each having a broken particle shape in a surface layer portion of the insulating main surface 72 and in a surface layer portion of the insulating side wall 73. The plurality of filler fragments may each be formed by any one of a part of the small size fillers, a part of the medium size fillers and a part of the large size fillers.

The plurality of filler fragments positioned on the insulating main surface 72 side each has a broken portion that is formed along the insulating main surface 72 such as to be oriented to the insulating main surface 72. The plurality of filler fragments positioned on the insulating side wall 73 side each has a broken portion that is formed along the insulating side wall 73 such as to be oriented to the insulating side wall 73. The broken portions of the plurality of filler fragments may be exposed from the insulating main surface 72 and the insulating side wall 73, or may be partially or wholly covered with the matrix resin. The plurality of filler fragments do not affect the structures on the chip 2 side, since the plurality of filler fragments are located in the surface layer portions of the insulating main surface 72 and the insulating side wall 73.

The plurality of flexible particles are added into the matrix resin. The plurality of flexible particles may include at least one of a silicone-based flexible particles, an acrylic-based flexible particles and a butadiene-based flexible particles. The sealing insulator 71 preferably includes the silicone-based flexible particles. The plurality of flexible particles preferably have an average particle size less than the average particle size of the plurality of fillers. The average particle size of the plurality of flexible particles is preferably not less than 1 nm and not more than 1 μm. A maximum particle size of the plurality of flexible particles is preferably not more than 1 μm.

The plurality of flexible particles are added into the matrix resin such that a ratio of a total cross-sectional area with respect to a unit cross-sectional area is to be not less than 0.1% and not more than 10%. In other words, the plurality of flexible particles are added into the matrix resin with a content of a range of not less than 0.1 wt % and not more than 10 wt %. The average particle size and the content of the plurality of flexible particles are to be adjusted in accordance with an elastic modulus to be imparted to the sealing insulator 71 at a time of manufacturing and/or after manufacturing. For example, according to the plurality of flexible particles having the average particle size of a submicron order (=not more than 1 μm), it makes it possible to contribute to a low elastic modulus and a low curing shrinkage of the sealing insulator 71.

The semiconductor device 1A includes a gate terminal film 74 that covers the gate pillar electrode 50 at an interval from the plurality of source pillar electrodes 60 on the sealing insulator 71. The gate terminal film 74 is electrically connected to the gate pillar electrode 50. The gate terminal film 74 is arranged at an inner portion of the insulating main surface 72 at an interval from the peripheral edge (insulating side wall 73) of the insulating main surface 72 in plan view.

The gate terminal film 74 is arranged at a layer different from the gate electrode 30 and the source electrode 32 and is thus hardly restricted by design rules resulting from a layout of the gate electrode 30 and a layout of the source electrode 32. The gate terminal film 74 can therefore have any planar shape and, at the same time, can be arranged at any location as long as it is electrically connected to the gate pillar electrode 50.

The gate terminal film 74 is arranged on a region adjacent to a central portion of the third side surface 5C in plan view in this embodiment. The gate terminal film 74 is arranged such as to overlap with at least the active surface 8 in plan view. The gate terminal film 74 may be arranged such as to overlap with the active surface 8 and the outer surface 9 in plan view.

The gate terminal film 74 has a thickness less than the thickness of the gate pillar electrode 50. The thickness of the gate terminal film 74 is preferably not more than ¼ that of the gate pillar electrode 50. The thickness of the gate terminal film 74 is particularly preferably not more than 1/10 that of the gate pillar electrode 50. The thickness of the gate terminal film 74 is preferably less than the thickness of the upper insulating film 38. The thickness of the gate terminal film 74 may be less than the thickness of the gate electrode 30. The thickness of the gate terminal film 74 takes various values in accordance with film type. The thickness of the gate terminal film 74 may be not less than 10 nm and not more than 15 μm.

The gate terminal film 74 has a planar area exceeding the planar area of the gate pillar electrode 50. The planar area of the gate terminal film 74 preferably exceeds the planar area of the gate electrode 30. In a case in which the first main surface 3 has a planar area of not less than 1 mm square, the planar area of the gate terminal film 74 may be not less than 0.4 mm square. The gate terminal film 74 may be formed in a polygonal shape (for example, a rectangular shape) having an area of not less than 0.4 mm×0.7 mm. The gate terminal film 74 is formed in a quadrilateral shape having four sides parallel to the first to fourth side surfaces 5A to 5D in plan view in this embodiment. As a matter of course, the gate terminal film 74 may be formed in a polygonal shape other than the quadrilateral shape, a circular shape, or an elliptical shape in plan view.

The semiconductor device 1A includes at least one (in this embodiment, one) source terminal film 75 that covers at least one (in this embodiment, the plurality) of the source pillar electrodes 60 at an interval from the gate pillar electrode 50 (gate terminal film 74) on the sealing insulator 71. The source terminal film 75 is electrically connected to the plurality of source pillar electrodes 60. The source terminal film 75 is arranged at an inner portion of the insulating main surface 72 at an interval from the peripheral edge (insulating side wall 73) of the insulating main surface 72 in plan view.

The source terminal film 75 is arranged at a layer different from the gate electrode 30 and the source electrode 32 and is thus hardly restricted by the design rules resulting from the layout of the gate electrode 30 and the layout of the source electrode 32. The source terminal film 75 can therefore have any planar shape and, at the same time, can be arranged at any location as long as it is electrically connected to the plurality of source pillar electrodes 60.

The source terminal film 75 is arranged such as to overlap with at least the active surface 8 in plan view. The source terminal film 75 may be arranged such as to overlap with the active surface 8 and the outer surface 9 in plan view. The source terminal film 75 is arranged at a position of overlapping with the body electrode portion 33 of the source electrode 32 such as not to overlap with the drawer electrode portions 34A and 34B of the source electrode 32 in plan view in this embodiment.

An opposing area between the gate terminal film 74 and the source terminal film 75 is thereby reduced. Such a structure is effective in reducing a short circuit risk between the gate terminal film 74 and the source terminal film 75 in a case in which solder or a conductive adhesive such as a metal paste, etc., is adhered to the gate terminal film 74 and the source terminal film 75. As a matter of course, a conductive bonding member such as a conductor plate, a conductive wire (for example, a bonding wire), etc., may be connected to the gate terminal film 74 and the source terminal film 75. In this case, a shorting risk between a conductive bonding member on the gate terminal film 74 side and a conductive bonding member on the source terminal film 75 side can be reduced.

The source terminal film 75 has a thickness less than the thickness of the plurality of source pillar electrodes 60. The thickness of the source terminal film 75 is preferably not more than ¼ that of the source pillar electrodes 60. The thickness of the source terminal film 75 is particularly preferably not more than 1/10 that of the source pillar electrodes 60. The thickness of the source terminal film 75 is preferably less than the thickness of the upper insulating film 38. The thickness of the source terminal film 75 may be less than the thickness of the source electrode 32. The thickness of the source terminal film 75 takes various values in accordance with film type. The thickness of the source terminal film 75 may be not less than 10 nm and not more than 15 μm. The thickness of the source terminal film 75 is substantially equal to the thickness of the gate terminal film 74.

The source terminal film 75 has a planar area exceeding the total planar area of the plurality of source pillar electrodes 60. The planar area of the source terminal film 75 exceeds the planar area of the gate terminal film 74. The planar area of the source terminal film 75 preferably exceeds the planar area of the source electrode 32. In a case in which the first main surface 3 has a planar area of not less than 1 mm square, the planar area of the source terminal film 75 may be not less than 0.8 mm square.

In this case, the planar area of the source terminal film 75 is particularly preferably not less than 1 mm square. The source terminal film 75 may be formed in a polygonal shape having an area of not less than 1 mm×1.4 mm. The source terminal film 75 is formed in a quadrilateral shape having four sides parallel to the first to fourth side surfaces 5A to 5D in plan view in this embodiment. As a matter of course, the source terminal film 75 may be formed in a polygonal shape other than the quadrilateral shape, a circular shape, or an elliptical shape in plan view.

The gate terminal film 74 and the source terminal film 75 may each have a single layered structure or a laminated structure that includes at least one among an Ag (silver)-based metal film, an Al (aluminum)-based metal film, a Cu (copper)-based metal film, an Ni (nickel)-based metal film, a Pd (palladium)-based metal film, and an Au (gold)-based metal film.

The Ag-based metal film may be a pure Ag film (an Ag film with a purity of not less than 99%) or an Ag alloy film. The Al-based metal film may be a pure Al film (an Al film with a purity of not less than 99%) or an Al alloy film. The Cu-based metal film may be a pure Cu film (a Cu film with a purity of not less than 99%) or a Cu alloy film. The Ni-based metal film may be a pure Ni film (an Ni film with a purity of not less than 99%) or an Ni alloy film. The Pd-based metal film may be a pure Pd film (a Pd film with a purity of not less than 99%) or a Pd alloy film. The Au-based metal film may be a pure Au film (an Au film with a purity of not less than 99%) or an Au alloy film.

The Ag-based metal film, the Al-based metal film, the Cu-based metal film, and the Ni-based metal film may each have a thickness of not less than 0.1 μm and not more than 15 μm. The Ag-based metal film, the Al-based metal film, the Cu-based metal film, and the Ni-based metal film preferably each have a thickness of not more than 10 μm. The Pd-based metal film and the Au-based metal film may each have a thickness of not less than 1 nm and not more than 1 μm. The Pd-based metal film and the Au-based metal film preferably each have a thickness of not more than 0.5 μm. The Au-based metal film particularly preferably has a thickness of not more than 0.1 μm.

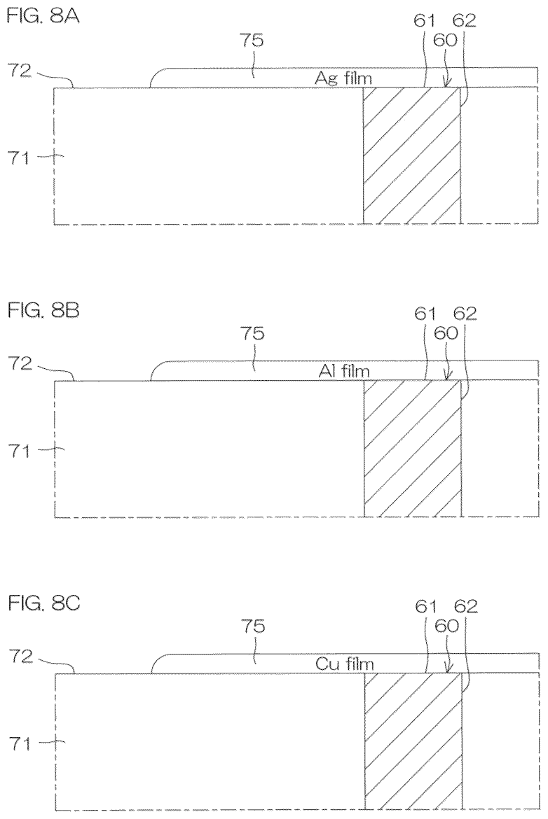

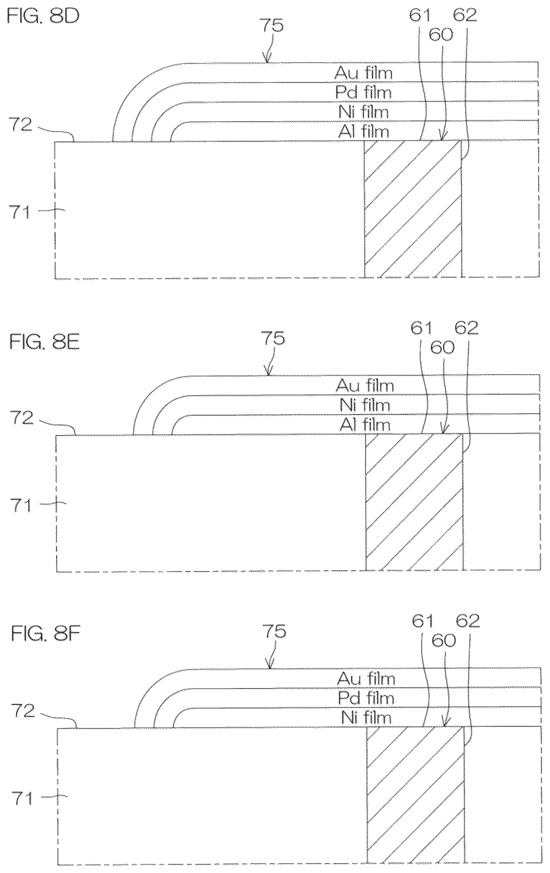

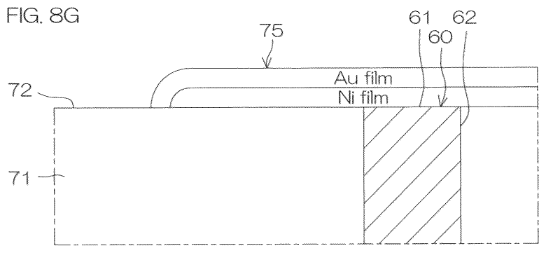

Hereinafter, configuration examples (film type examples) of the gate terminal film 74 and the source terminal film 75 shall be illustrated with reference to FIG. 8A to FIG. 8G. FIG. 8A to FIG. 8G are partial cross sectional views showing the gate terminal film 74 and the source terminal film 75 according to first to seventh configuration examples. The gate terminal film 74 has the same configuration as the source terminal film 75 and therefore, in the following, the expression, source terminal film 75 (gate terminal film 74), shall be used and the configuration of the source terminal film 75 shall be described.

With reference to FIG. 8A, the source terminal film 75 (gate terminal film 74) according to the first configuration example has a single layered structure consisting of an Ag-based metal film. With reference to FIG. 8B, the source terminal film 75 according to the second configuration example has a single layered structure consisting of an Al-based metal film. With reference to FIG. 8C, the source terminal film 75 according to the third configuration example has a single layered structure consisting of a Cu-based metal film. With reference to FIG. 8D, the source terminal film 75

(gate terminal film 74) according to the fourth configuration example has a laminated structure that includes an Al-based metal film, an Ni-based metal film, a Pd-based metal film, and an Au-based metal film that are laminated in that order from the sealing insulator 71 side. The Al-based metal film covers the insulating main surface 72 in a film shape. The Ni-based metal film covers the Al-based metal film in a film shape. The Pd-based metal film covers the Ni-based metal film in a film shape. The Au-based metal film covers the Pd-based metal film in a film shape.

At least one of the Ni-based metal film, the Pd-based metal film, and the Au-based metal film may have a portion in contact with the insulating main surface 72. As a matter of course, at least one of the Ni-based metal film, the Pd-based metal film, and the Au-based metal film may be formed on just the Al-based metal film such as not to contact the insulating main surface 72. The source terminal film 75 (gate terminal film 74) according to the fourth configuration example may include an Ag-based metal film or a Cu-based metal film in place of the Al-based metal film.

With reference to FIG. 8E, the source terminal film 75 (gate terminal film 74) according to the fifth configuration example has a laminated structure that includes an Al-based metal film, an Ni-based metal film, and an Au-based metal film that are laminated in that order from the sealing insulator 71 side. The Al-based metal film covers the insulating main surface 72 in a film shape. The Ni-based metal film covers the Al-based metal film in a film shape. The Au-based metal film covers the Ni-based metal film in a film shape.

At least one of the Ni-based metal film and the Au-based metal film may have a portion in contact with the insulating main surface 72. As a matter of course, at least one of the Ni-based metal film and the Au-based metal film may be formed on just the Al-based metal film such as not to contact the insulating main surface 72. The source terminal film 75 (gate terminal film 74) according to the fifth configuration example may include an Ag-based metal film or a Cu-based metal film in place of the Al-based metal film.

With reference to FIG. 8F, the source terminal film 75 (gate terminal film 74) according to the sixth configuration example has a laminated structure that includes an Ni-based metal film, a Pd-based metal film, and an Au-based metal film that are laminated in that order from the sealing insulator 71 side. The Ni-based metal film covers the insulating main surface 72 in a film shape. The Pd-based metal film covers the Ni-based metal film in a film shape. The Au-based metal film covers the Pd-based metal film in a film shape. At least one of the Pd-based metal film and the Au-based metal film may have a portion in contact with the insulating main surface 72. As a matter of course, at least one of the Ni-based metal film and the Au-based metal film may be formed on just the Ni-based metal film such as not to contact the insulating main surface 72.

With reference to FIG. 8G, the source terminal film 75 (gate terminal film 74) according to the seventh configuration example has a laminated structure that includes an Ni-based metal film and an Au-based metal film that are laminated in that order from the sealing insulator 71 side. The Ni-based metal film covers the insulating main surface 72 in a film shape. The Au-based metal film covers the Ni-based metal film in a film shape. The Au-based metal film may have a portion in contact with the insulating main surface 72. As a matter of course, the Au-based metal film may be formed on just the Ni-based metal film such as not to contact the insulating main surface 72.

The configurations of the source terminal film 75 (gate terminal film 74) shown in FIG. 8A to FIG. 8G are an example and the configuration of the source terminal film 75 (gate terminal film 74) is not restricted to the configurations shown in FIG. 8A to FIG. 8G. The film type of the source terminal film 75 (gate terminal film 74) is to be adjusted in accordance with the material of the solder, metal paste, bonding paste, etc.

For example, in a case in which an Ag sintered paste is bonded to the source terminal film 75 (gate terminal film 74), the source terminal film 75 (gate terminal film 74) preferably includes at least an Ag-based metal film (see FIG. 8A) that has a high affinity to the Ag sintered paste. The Ag sintered paste consists, for example, of a paste in which Ag particles of nano size or micro size are added to an organic solvent.

For example, in a case in which a conducting wire such as a bonding wire, etc., is bonded to the source terminal film 75 (gate terminal film 74), the source terminal film 75 (gate terminal film 74) preferably has a single layered structure or a laminated structure that includes at least one among an Al-based metal film, a Cu-based metal film, an Ni-based metal film, a Pd-based metal film, and an Au-based metal film (see FIG. 8B to FIG. 8G).

For example, in a case in which the bonding wire consists of an Al wire, the source terminal film 75 (gate terminal film 74) preferably includes at least an Al-based metal film. Also, in a case in which the bonding wire consists of a Cu wire, the source terminal film 75 (gate terminal film 74) preferably includes at least a Cu-based metal film. Also, in a case in which the bonding wire consists of an Au wire, the source terminal film 75 (gate terminal film 74) preferably includes at least an Au-based metal film.

The source terminal film 75 (gate terminal film 74) having a laminated structure that includes an Ni-based metal film and an Au-based metal film (see FIG. 8D to 8G) can be applied to bonding wires consisting of various materials. Also, the source terminal film 75 (gate terminal film 74) having a laminated structure that includes an Ni-based metal film and an Au-based metal film (see FIG. 8D to 8G) can be applied to solder and Ag sintered paste. Therefore, from a standpoint of level of versatility, the source terminal film 75 (gate terminal film 74) preferably has a laminated structure that includes an Ni-based metal film and an Au-based metal film (see FIG. 8D to 8G).

With reference to FIG. 2 again, the semiconductor device 1A includes a drain electrode 77 (second main surface electrode) that covers the second main surface 4. The drain electrode 77 is electrically connected to the second main surface 4. The drain electrode 77 forms an ohmic contact with the second semiconductor region 7 that is exposed from the second main surface 4. The drain electrode 77 may cover a whole region of the second main surface 4 such as to be continuous with the peripheral edge of the chip 2 (the first to fourth side surfaces 5A to 5D).

The drain electrode 77 may cover the second main surface 4 at an interval from the peripheral edge of the chip 2. The drain electrode 77 is configured such that a drain source voltage of not less than 500 V and not more than 3000 V is to be applied between the source terminal film 75 and the drain electrode 77. That is, the chip 2 is formed such that the voltage of not less than 500 V and not more than 3000 V is to be applied between the first main surface 3 and the second main surface 4.

As described above, the semiconductor device 1A includes the chip 2, the source electrode 32 (main surface electrode), the plurality of source pillar electrodes 60, the sealing insulator 71, and at least one (in this embodiment, one) source terminal film 75. The chip 2 has the first main surface 3. The source electrode 32 is arranged on the first main surface 3. The plurality of source pillar electrodes 60 are arranged at an interval on the source electrode 32. The sealing insulator 71 covers the region between the plurality of source pillar electrodes 60 on the source electrode 32 such as to expose parts of the plurality of source pillar electrodes 60. The source terminal film 75 covers the plurality of source pillar electrodes 60 on the sealing insulator 71.

According to this structure, a volume of an electrode interposed between the source electrode 32 and the source terminal film 75 can be reduced by the plurality of source pillar electrodes 60. That is, it is made unnecessary to arrange a pillar electrode having a planar area equivalent to the source terminal film 75 on the source electrode 32. Stress due to an electrode interposed between the source electrode 32 and the source terminal film 75 can thereby be reduced. It is therefore possible to suppress shape defects and fluctuations in electrical characteristics due to the stress.

Also, according to this structure, an object to be sealed can be protected from an external force and a humidity) by the sealing insulator 71. That is, the object to be sealed can be protected from a damage due to the external force and deterioration due to the humidity. It is therefore possible to suppress shape defects and fluctuations in electrical characteristics. As a result, it is possible to provide the semiconductor device 1A capable of improving reliability.

The semiconductor device 1A preferably includes the upper insulating film 38 that partially covers the source electrode 32. According to this structure, the source electrode 32 can be protected from the external force and the humidity with the upper insulating film 38. That is, according to this structure, the source electrode 32 can be protected by both of the upper insulating film 38 and the sealing insulator 71.

Also, the sealing insulator 71 preferably has the portion directly covering the upper insulating film 38. The sealing insulator 71 preferably has the portion covering the source electrode 32 across the upper insulating film 38 interposed therebetween. The upper insulating film 38 preferably includes any one of or both of the inorganic insulating film 42 and the organic insulating film 43. The organic insulating film 43 preferably consists of the photosensitive resin film.

The upper insulating film 38 is preferably thicker than the source electrode 32. The upper insulating film 38 is preferably thinner than the chip 2. The sealing insulator 71 is preferably thicker than the source electrode 32. The sealing insulator 71 is preferably thicker than the upper insulating film 38. The sealing insulator 71 is particularly preferably thicker than the chip 2.

Those above structures are effective when the source pillar electrodes 60 having a relatively large total planar area and/or relatively large thicknesses are applied to the chip 2 having a relatively large planar area and/or a relatively small thickness. The source pillar electrodes 60 having the relatively large total planar area and/or the relatively large thicknesses are also effective in absorbing a heat generated on the chip 2 side and dissipating the heat to the outside.

For example, the source pillar electrode 60 is preferably thicker than the source electrode 32. The source pillar electrode 60 is preferably thicker than the upper insulating film 38. The source pillar electrode 60 is particularly preferably thicker than the chip 2. For example, the source pillar electrode 60 may have the total planar area that occupies not less than 10% and not more than 50% of the first main surface 3 in plan view.

In this case, the total planar area of the plurality of source pillar electrodes 60 may be not more than 30%. On one hand, the source electrode 32 may have a planar area amounting to an occupancy ratio of not less than 50% with respect to the planar area of the first main surface 3. On the other hand, the source terminal film 75 may have a planar area amounting to an occupancy ratio of not less than 50% with respect to the planar area of the first main surface 3.

The source terminal film 75 is preferably thinner than the plurality of source pillar electrodes 60. The source terminal film 75 is preferably not more than ¼ the thickness of the plurality of source pillar electrodes 60. The source terminal film 75 is preferably thinner than the upper insulating film 38. The source terminal film 75 is preferably thinner than the source electrode 32. By the comparatively thin source terminal film 75, stress due to the source terminal film 75 can be suppressed.

For example, the chip 2 may have the first main surface 3 having the area of not less than 1 mm square in plan view. The chip 2 may have the thickness of not more than 100 μm in cross sectional view. The chip 2 preferably has the thickness of not more than 50 μm in cross sectional view. The chip 2 may have the laminated structure that includes the semiconductor substrate and the epitaxial layer. In this case, the epitaxial layer is preferably thicker than the semiconductor substrate.

In those above structures, the chip 2 preferably includes the monocrystal of the wide bandgap semiconductor. The monocrystal of the wide bandgap semiconductor is effective in improving electrical characteristics. Also, according to the monocrystal of the wide bandgap semiconductor, it is possible to achieve a thinning of the chip 2 and an increasing of the planar area of the chip 2 while suppressing a deformation of the chip 2 with a relatively high hardness. The thinning of the chip 2 and the increasing of the planar area of the chip 2 are also effective in improving the electrical characteristics.

The structure having the sealing insulator 71 is also effective in a structure that includes the drain electrode 77 covering the second main surface 4 of the chip 2. The drain electrode 77 forms a potential difference (for example, not less than 500 V and not more than 3000 V) with the source electrode 32 via the chip 2. In particular, in a case in which the chip 2 is relatively thin, a risk of a discharge phenomenon between the peripheral edge of the first main surface 3 and the source electrode 32 increases, since a distance between the source electrode 32 and the drain electrode 77 is shortened. In this point, according to the structure having the sealing insulator 71, an insulation property between the peripheral edge of the first main surface 3 and the source electrode 32 can be improved, and therefore the discharge phenomenon can be suppressed.

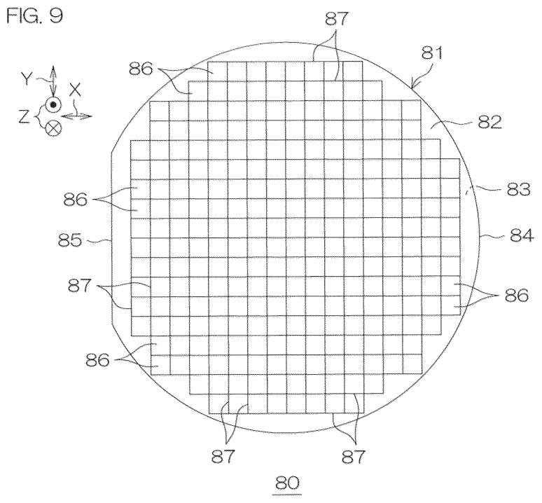

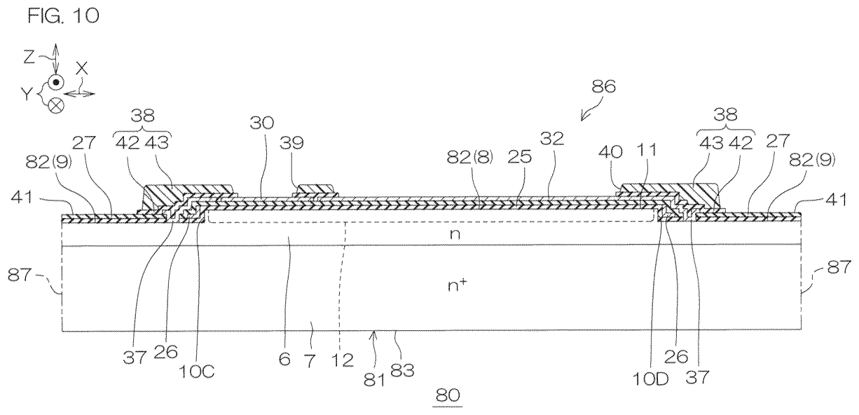

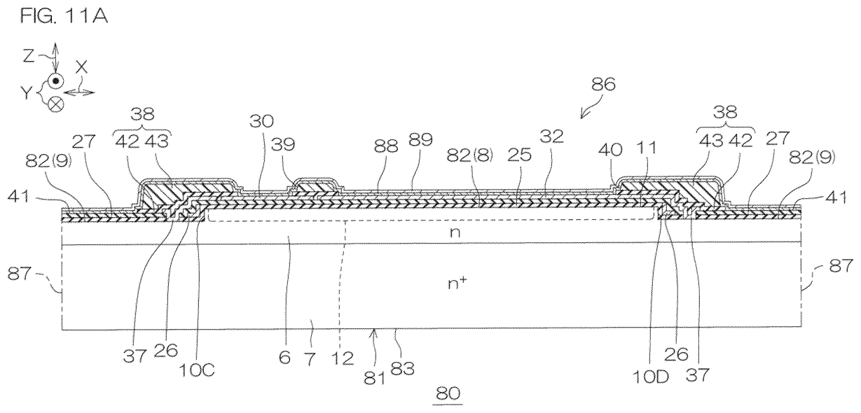

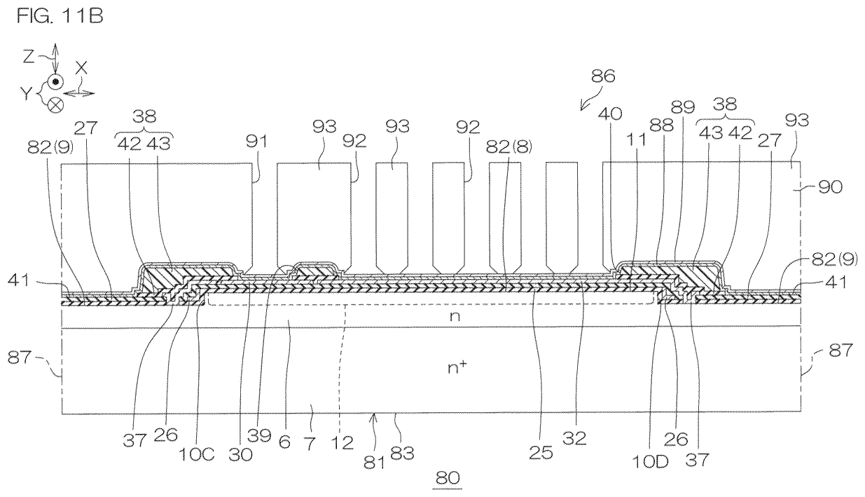

FIG. 9 is a plan view showing a wafer structure 80 that is to be used at a time of manufacturing of the semiconductor device 1A shown in FIG. 1. FIG. 10 is a cross sectional view showing a device region 86 shown in FIG. 9. With reference to FIG. 9 and FIG. 10, the wafer structure 80 includes a wafer 81 formed in a disc shape. The wafer 81 is to be a base of the chip 2. The wafer 81 has a first wafer main surface 82 on one side, a second wafer main surface 83 on the other side, and a wafer side surface 84 connecting the first wafer main surface 82 and the second wafer main surface 83.

The wafer 81 has a mark 85 indicating a crystal orientation of the SiC monocrystal on the wafer side surface 84. The mark 85 includes an orientation flat cut out in a straight line in plan view, in this embodiment. The orientation flat extends in the second direction Y, in this embodiment. The orientation flat does not necessarily have to extend in the second direction Y and may extend in the first direction X.

As a matter of course, the mark 85 may include a first orientation flat extending in the first direction X and a second orientation flat extending in the second direction Y. Also, the mark 85 may have an orientation notch, instead of the orientation flat, cut out toward a central portion of the wafer 81. The orientation notch may be a notched portion cut into a polygonal shape such as a triangle shape and a quadrangle shape in plan view.

The wafer 81 may have a diameter of not less than 50 mm and not more than 300 mm (that is, not less than 2 inch and not more than 12 inch). The diameter of the wafer structure 80 is defined by a length of a chord passing through a center of the wafer structure 80 outside the mark 85. The wafer structure 80 may have a thickness of not less than 100 μm and not more than 1100 μm.

The wafer structure 80 includes the first semiconductor region 6 formed in a region on the first wafer main surface 82 side and the second semiconductor region 7 formed in a region on the second wafer main surface 83 side, inside the wafer 81. The first semiconductor region 6 is formed by an epitaxial layer, and the second semiconductor region 7 formed by a semiconductor substrate. That is, the first semiconductor region 6 is formed by an epitaxial growth of a semiconductor monocrystal from the second semiconductor region 7 by an epitaxial growth method. The second semiconductor region 7 preferably has a thickness exceeding a thickness of the first semiconductor region 6.

The wafer structure 80 includes a plurality of device regions 86 and a plurality of scheduled cutting lines 87 that are provided in the first wafer main surface 82. The plurality of device regions 86 are regions each corresponding to the semiconductor device 1A. The plurality of device regions 86 are each set in a quadrangle shape in plan view. The plurality of device regions 86 are arrayed in a matrix pattern along the first direction X and the second direction Y in plan view, in this embodiment.

The plurality of scheduled cutting lines 87 are lines (regions extending in band shapes) that define positions to be the first to fourth side surfaces 5A to 5D of the chip 2. The plurality of scheduled cutting lines 87 are set in a lattice pattern extending along the first direction X and the second direction Y such as to define the plurality of device regions 86. For example, the plurality of scheduled cutting lines 87 may be demarcated by alignment marks and the like that are provided inside and/or outside the wafer 81.

The wafer structure 80 includes the mesa portion 11, the MISFET structure 12, the outer contact region 19, the outer well region 20, the field regions 21, the main surface insulating film 25, the side wall structure 26, the interlayer insulating film 27, the gate electrode 30, the source electrode 32, the plurality of gate wirings 36A, 36B, the source wiring 37 and the upper insulating film 38 formed in each of the device regions 86, in this embodiment.

The wafer structure 80 includes the dicing street 41 demarcated in regions among the plurality of upper insulating films 38. That is, the dicing street 41 straddles the plurality of device regions 86 across the plurality of scheduled cutting lines 87 such as to expose the plurality of scheduled cutting lines 87. The dicing street 41 is formed in a lattice pattern extending along the plurality of scheduled cutting lines 87. The dicing street 41 exposes the interlayer insulating film 27, in this embodiment. As a matter of course, in a case in which the interlayer insulating film 27 exposing the first wafer main surface 82, the dicing street 41 may expose the first wafer main surface 82.

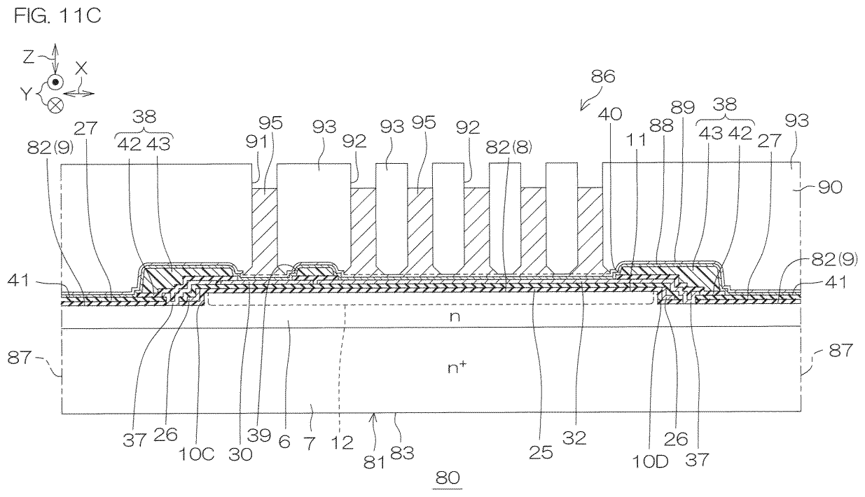

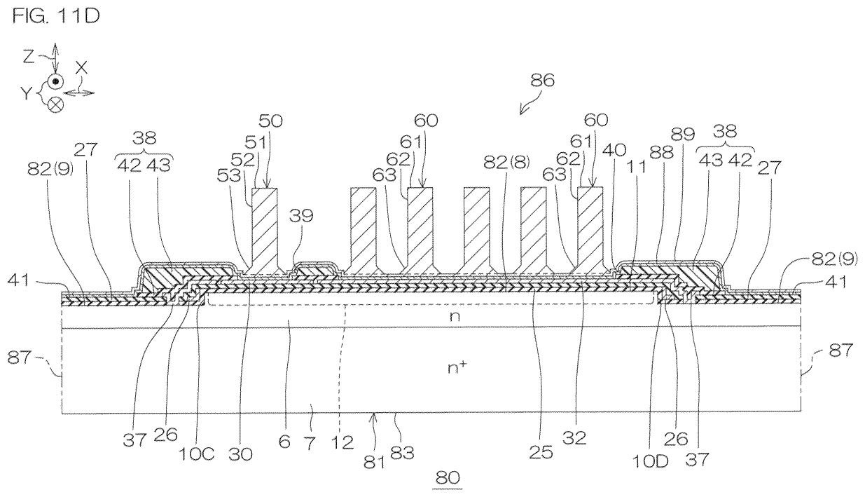

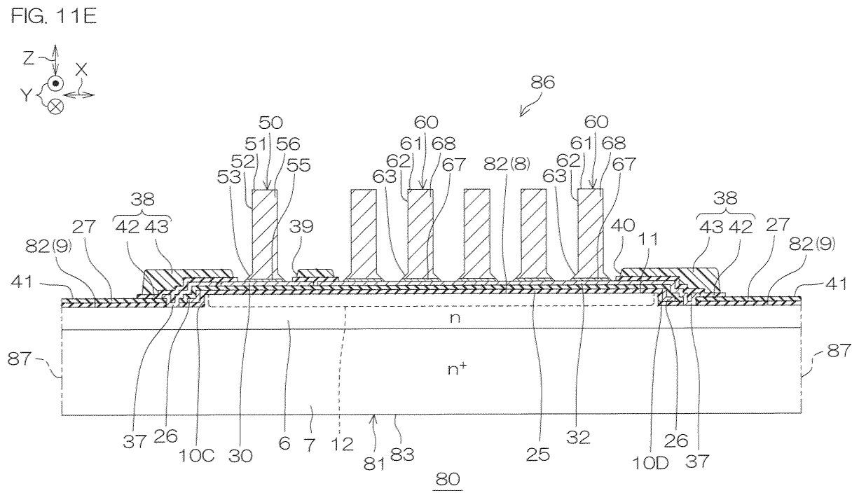

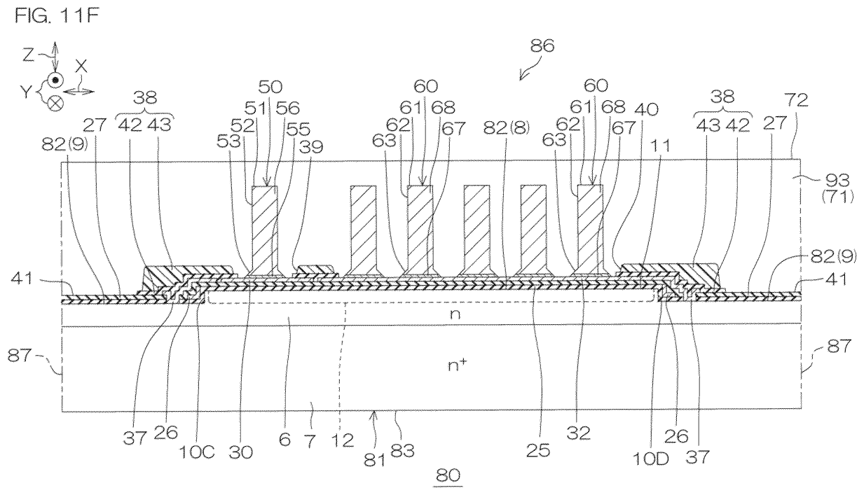

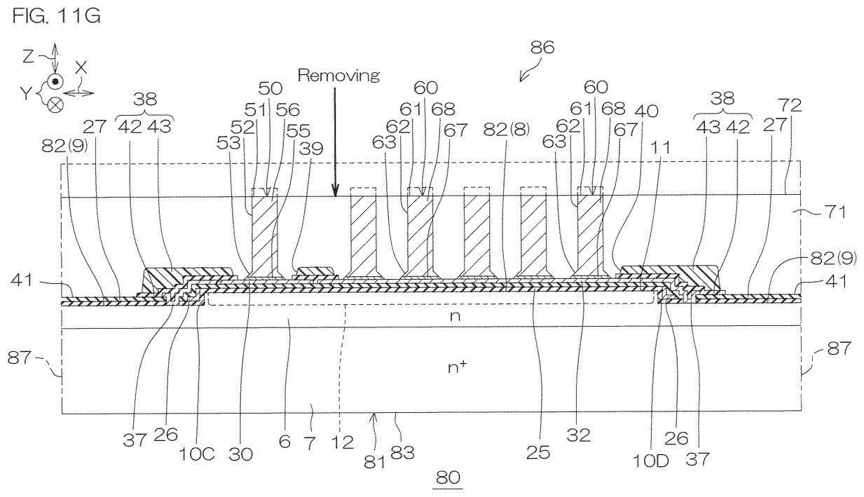

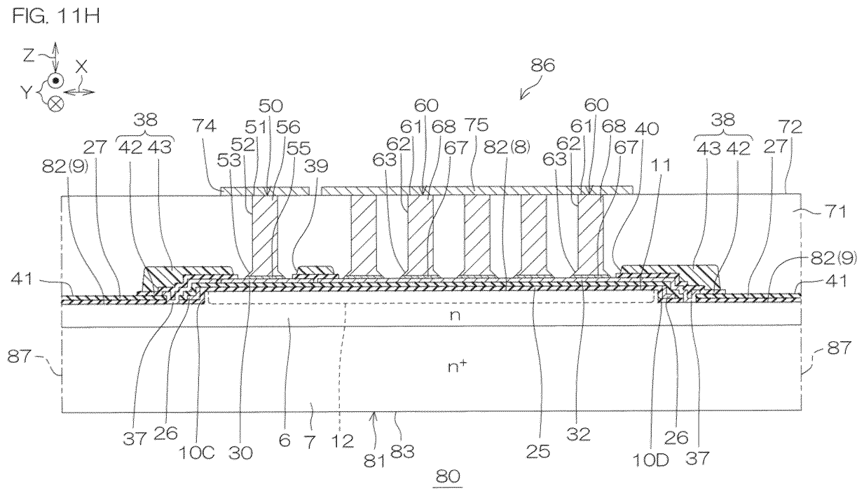

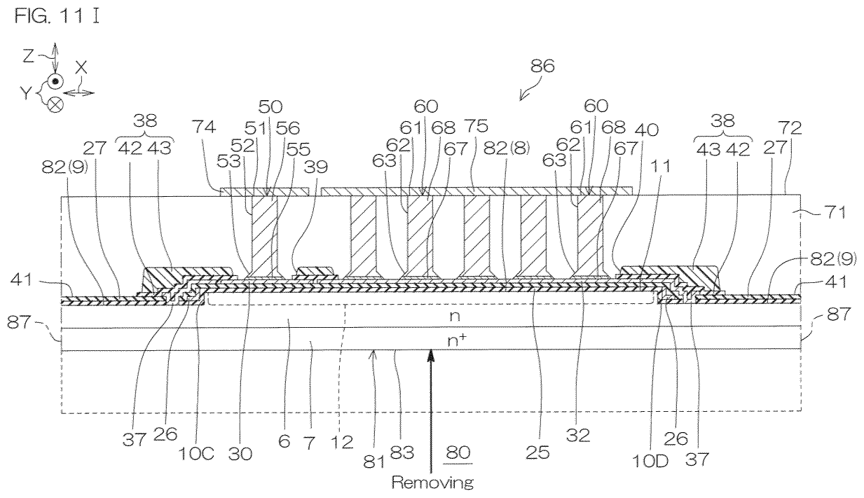

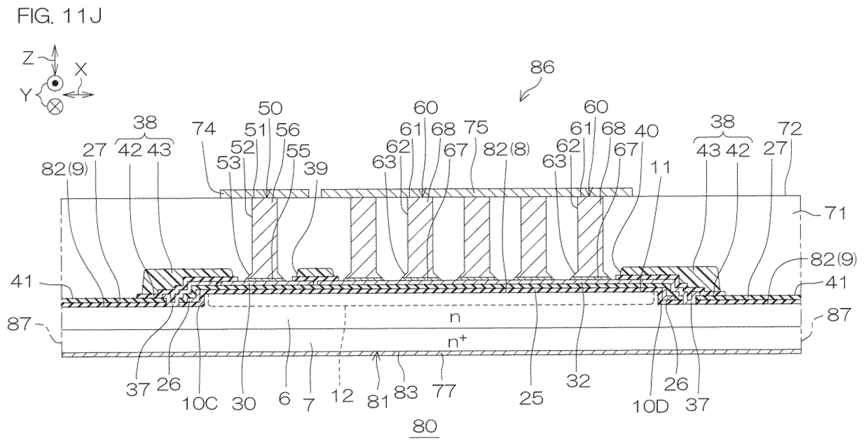

FIG. 11A to FIG. 11J are cross sectional views showing a manufacturing method example for the semiconductor device 1A shown in FIG. 1. Descriptions of the specific features of each structure that are formed in each process shown in FIG. 11A to FIG. 11J shall be omitted or simplified, since those have been as described above.

With reference to FIG. 11A, the wafer structure 80 is prepared (see FIG. 9 and FIG. 10). Next, a first base conductor film 88 to be a base of the first gate conductor film 55 and the first source conductor film 67 is formed on the wafer structure 80. The first base conductor film 88 is formed in a film shape along the interlayer insulating film 27, the gate electrode 30, the source electrode 32, the plurality of gate wirings 36A, 36B, the source wiring 37 and the upper insulating film 38. The first base conductor film 88 includes a Ti-based metal film. The first base conductor film 88 may be formed by a sputtering method and/or a vapor deposition method.

Next, a second base conductor film 89 to be a base of the second gate conductor film 56 and the second source conductor film 68 is formed on the first base conductor film 88. The second base conductor film 89 covers the interlayer insulating film 27, the gate electrode 30, the source electrode 32, the plurality of gate wirings 36A, 36B, the source wiring 37 and the upper insulating film 38 in a film shape with the first base conductor film 88 interposed therebetween. The second base conductor film 89 includes a Cu-based metal film. The second base conductor film 89 may be formed by a sputtering method and/or a vapor deposition method.

Next, with reference to FIG. 11B, a resist mask 90 having a predetermined pattern is formed on the second base conductor film 89. The resist mask 90 includes at least one (in this embodiment, one) first opening 91 exposing the gate electrode 30, a plurality of second openings 92 exposing the source electrode 32. The first opening 91 exposes a region in which the gate pillar electrode 50 is to be formed at a region on the gate electrode 30. The second openings 92 expose regions in which the source pillar electrodes 60 are to be formed at regions on the source electrode 32.

This step includes a step of reducing an adhesion of the resist mask 90 with respect to the second base conductor film 89. The adhesion of the resist mask 90 is to be adjusted by adjusting exposure conditions and/or bake conditions (baking temperature, time, etc.) after exposure for the resist mask 90. Through this step, a growth starting point of the first protrusion portion 53 is formed at a lower end portion of the first opening 91, and growth starting points of the second protrusion portions 63 are formed at lower end portions of the second openings 92.

Next, with reference to FIG. 11C, a third base conductor film 95 to be a base of the second gate conductor film 56 and the second source conductor film 68 is formed on the second base conductor film 89. The third base conductor film 95 is formed by depositing a conductor (in this embodiment, Cu-based metal) in the first opening 91 and the second openings 92 by a plating method (for example, electroplating method), in this embodiment. The third base conductor film 95 integrates with the second base conductor film 89 inside the first opening 91 and the second openings 92.

Through this step, the gate pillar electrode 50 that covers the gate electrode 30 is formed. Also, the source pillar electrodes 60 that cover the source electrode 32 are formed. The volume of the conductor (gate pillar electrode 50) to be deposited on the gate electrode 30 is adjusted by the opening area of the first opening 91, and the volume of the conductor (source pillar electrodes 60) to be deposited on the source electrode 32 is adjusted by the total opening area of the second openings 92. This makes it possible to reduce the conductors to be deposited on gate electrode 30 and source electrode 32.

This step includes a step of entering a plating solution between the second base conductor film 89 and the resist mask 90 at the lower end portion of the first opening 91. Also, this step includes a step of entering the plating solution between the second base conductor film 89 and the resist mask 90 at the lower end portions of the second openings 92. Through this step, a part of the third base conductor film 95 (the gate pillar electrode 50) is grown into a protrusion shape at the lower end portion of the first opening 91 and the first protrusion portion 53 is thereby formed. Also, a part of the third base conductor film 95 (the source pillar electrodes 60) is grown into a protrusion shape at the lower end portion of the second opening 92 and the second protrusion portion 63 is thereby formed.

Next, with reference to FIG. 11D, the resist mask 90 is removed. Through this step, the gate pillar electrode 50 and the source pillar electrodes 60 are exposed outside.

Next, with reference to FIG. 11E, a portion of the second base conductor film 89 that is exposed from the gate pillar electrode 50 and the source pillar electrodes 60 is removed. An unnecessary portion of the second base conductor film 89 may be removed by an etching method. The etching method may be a wet etching method and/or a dry etching method. Next, a portion of the first base conductor film 88 that is exposed from the gate pillar electrode 50 and the source pillar electrodes 60 is removed. An unnecessary portion of the first base conductor film 88 may be removed by an etching method. The etching method may be a wet etching method and/or a dry etching method.

Next, with reference to FIG. 11F, a sealant 93 is supplied on the first wafer main surface 82 such as to cover the gate pillar electrode 50 and the source pillar electrodes 60. The sealant 93 is to be a base of the sealing insulator 71. The sealant 93 fills a periphery of the gate pillar electrode 50 and peripheries of the source pillar electrodes 60, and covers a whole region of the gate pillar electrode 50 and whole regions of the source pillar electrodes 60.

The sealant 93 directly covers a portion of the gate electrode 30 that is exposed from the upper insulating film 38 and the gate pillar electrode 50. The sealant 93 directly covers a portion of the source electrode 32 that is exposed from the upper insulating film 38 and the source pillar electrodes 60. The sealant 93 includes the thermosetting resin, the plurality of fillers and the plurality of flexible particles (flexible agent), in this embodiment, and is hardened by heating. Through this step, the sealing insulator 71 is formed. The sealing insulator 71 has the insulating main surface 72 that covers the gate pillar electrode 50 and the source pillar electrodes 60.

Next, with reference to FIG. 11G, the sealing insulator 71 is partially removed. The sealing insulator 71 is ground from the insulating main surface 72 side by a grinding method, in this embodiment. The grinding method may be a mechanical polishing method or a chemical mechanical polishing method. The insulating main surface 72 is ground until the gate pillar electrode 50 and the source pillar electrodes 60 are exposed. This step includes a grinding step of the gate pillar electrode 50 and the source pillar electrodes 60. Through this step, the insulating main surface 72 that forms the single grinding surface with the gate pillar electrode 50 (the gate electrode surface 51) and the source pillar electrodes 60 (the source electrode surfaces 61) is formed.

The sealing insulator 71 may be formed in a semi-cured state (incompletely cured state) by adjusting the heating conditions in the step of FIG. 11F aforementioned. In this case, the sealing insulator 71 is ground in the step of FIG. 11G and then heated again to form a fully cured state (completely cured state). In this case, it is possible to easily remove the sealing insulator 71.

Next, with reference to FIG. 11H, the gate terminal film 74 that covers the gate pillar electrode 50 is formed on the sealing insulator 71 (insulating main surface 72) and the source terminal film 75 that covers the source pillar electrodes 60 are formed on the sealing insulator 71 (insulating main surface 72). As shall be described below, the gate terminal film 74 and the source terminal film 75 are formed by depositing at least one among an Ag-based metal film, an Al-based metal film, a Cu-based metal film, an Ni-based metal film, a Pd-based metal film, and an Au-based metal film on the sealing insulator 71 (insulating main surface 72) by at least one method among a sputtering method, a vapor deposition method, and a plating method.

Next, with reference to FIG. 11I, the wafer 81 is partially removed from the second wafer main surface 83 side, and the wafer 81 is thinned until a desired thickness is obtained. The thinning step of the wafer 81 is performed by an etching method or a grinding method. The etching method may be a wet etching method or a dry etching method. The grinding method may be a mechanical polishing method or a chemical mechanical polishing method.

This step includes a step of thinning the wafer 81 by using the sealing insulator 71 as a supporting member that supports the wafer 81. This allows for proper handling of the wafer 81. Also, it is possible to suppress a deformation (warpage due to thinning) of the wafer 81 with the sealing insulator 71, and therefore the wafer 81 can be appropriately thinned.

As one example, in a case in which the thickness of the wafer 81 is less than the thickness of the sealing insulator 71, the wafer 81 is further thinned. As the other example, in a case in which the thickness of the wafer 81 is not less than the thickness of the sealing insulator 71, the wafer 81 is thinned until the thickness of the wafer 81 becomes less than the thickness of the sealing insulator 71. In those cases, the wafer 81 is preferably thinned until a thickness of the second semiconductor region 7 (the semiconductor substrate) becomes less than a thickness of the first semiconductor region 6 (the epitaxial layer).

As a matter of course, the thickness of the second semiconductor region 7 (the semiconductor substrate) may be not less than the thickness of the first semiconductor region 6 (the epitaxial layer). Also, the wafer 81 may be thinned until the first semiconductor region 6 is exposed from the second wafer main surface 83. That is, all of the second semiconductor region 7 may be removed.

Next, with reference to FIG. 11J, the drain electrode 77 covering the second wafer main surface 83 is formed. The drain electrode 77 may be formed by a sputtering method and/or a vapor deposition method. The wafer structure 80 and the sealing insulator 71 are cut along the scheduled cutting lines 87. The wafer structure 80 and the sealing insulator 71 may be cut by a dicing blade (not shown). Through the steps including the above, the plurality of semiconductor devices 1A are manufactured from the single wafer structure 80.

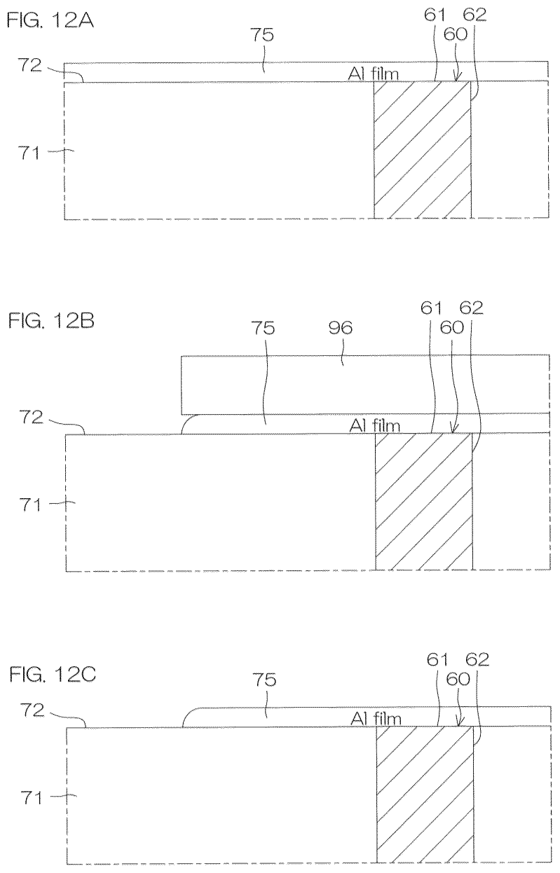

Hereinafter, a manufacturing method example of the gate terminal film 74 and the source terminal film 75 according to FIG. 11H shall be illustrated. FIG. 12A to FIG. 12C are partial cross sectional views showing a first manufacturing method example of the gate terminal film 74 and the source terminal film 75. With the first manufacturing method example, an example in which the gate terminal film 74 and the source terminal film 75 according to the second configuration example (see FIG. 8B) are formed by a sputtering method and/or a vapor deposition method is illustrated.

First, with reference to FIG. 12A, an Al-based metal film that covers a whole region of the insulating main surface 72 of the sealing insulator 71 is formed by a sputtering method and/or a vapor deposition method. The Al-based metal film covers the gate pillar electrode 50 and the plurality of source pillar electrodes 60 collectively.

Next, with reference to FIG. 12B, a resist mask 96 having a predetermined pattern is formed on the Al-based metal film. On the Al-based metal film, the resist mask 96 covers a region on which the gate terminal film 74 is to be formed and a region on which the source terminal film 75 is to be formed and exposes regions besides these.

Next, with reference to FIG. 12C, unnecessary portions of the Al-based metal film are removed by an etching method via the resist mask 96. The etching method may be a wet etching method and/or a dry etching method. The gate terminal film 74 and the source terminal film 75 are thereby formed on the insulating main surface 72.

An Ag-based metal film, a Cu-based metal film, an Ni-based metal film, a Pd-based metal film, and an Au-based metal film can all be formed by a sputtering method and/or a vapor deposition method. The gate terminal film 74 and the source terminal film 75 according to any of the first to seventh configuration examples (FIG. 8A to FIG. 8G) can thus be formed using the steps of FIG. 12A to FIG. 12C. That is, the source terminal film 75 according to any of the first to seventh configuration examples (FIG. 8A to FIG. 8G) is formed by depositing an arbitrary metal film among an Al-based metal film, an Ag-based metal film, a Cu-based metal film, an Ni-based metal film, a Pd-based metal film, and an Au-based metal film on an object to be covered by a sputtering method and/or a vapor deposition method.

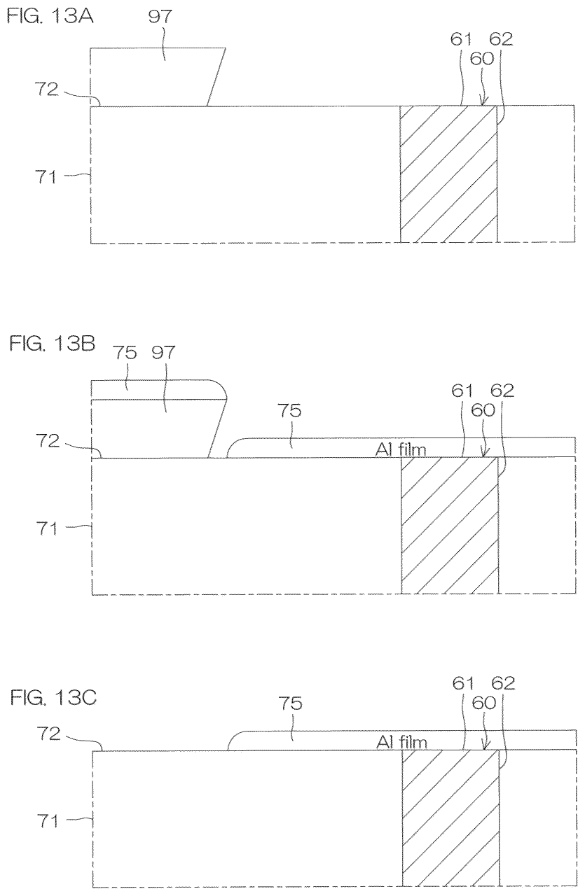

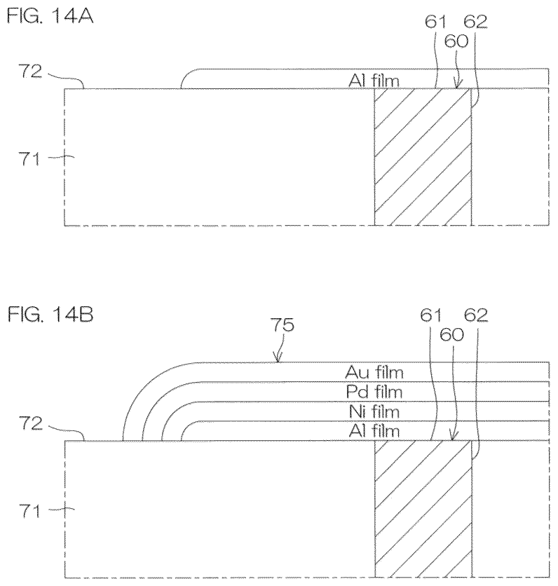

FIG. 13A to FIG. 13C are partial cross sectional views showing a second manufacturing method example of the gate terminal film 74 and the source terminal film 75. With the second manufacturing method example, an example in which the gate terminal film 74 and the source terminal film 75 according to the second configuration example (see FIG. 8B) are formed by a lift-off method is illustrated.

First, with reference to FIG. 13A, a resist mask 97 having a predetermined pattern is formed on the insulating main surface 72. On the insulating main surface 72, the resist mask 97 exposes a region on which the gate terminal film 74 is to be formed and a region on which the source terminal film 75 is to be formed and covers regions besides these.

Next, with reference to FIG. 13B, an Al-based metal film that covers the insulating main surface 72 and the resist mask 97 is formed by a sputtering method and/or a vapor deposition method. The Al-based metal film covers the gate pillar electrode 50 and the plurality of source pillar electrodes 60 collectively.

Next, with reference to FIG. 13C, the resist mask 97 is removed. In this step, a portion of the Al-based metal film that covers the resist mask 97 is also removed at the same time. The gate terminal film 74 and the source terminal film 75 are thereby formed on the insulating main surface 72.

An Ag-based metal film, a Cu-based metal film, an Ni-based metal film, a Pd-based metal film, and an Au-based metal film can all be formed by a sputtering method and/or a vapor deposition method. The gate terminal film 74 and the source terminal film 75 according to any of the first to seventh configuration examples (FIG. 8A to FIG. 8G) can thus be formed using the steps of FIG. 13A to FIG. 13C. That is, the gate terminal film 74 and the source terminal film 75 according to any of the first to seventh configuration examples (FIG. 8A to FIG. 8G) are formed by depositing an arbitrary metal film among an Al-based metal film, an Ag-based metal film, a Cu-based metal film, an Ni-based metal film, a Pd-based metal film, and an Au-based metal film on an object to be covered by a sputtering method and/or a vapor deposition method.

FIG. 14A and FIG. 14B are partial cross sectional views showing a third manufacturing method example of the gate terminal film 74 and the source terminal film 75. With the third manufacturing method example, an example in which the gate terminal film 74 and the source terminal film 75 according to the fourth configuration example (see FIG. 8D) are formed is shown. First, with reference to FIG. 14A, an Al-based metal film is formed through the steps of FIG. 12A to FIG. 12C or the steps of FIG. 13A to FIG. 13C.

Next, with reference to FIG. 14B, an Ni-based metal film, a Pd-based metal film, and an Au-based metal film are laminated in that order on the Al-based metal film by a plating method. In this step, an electroplating method or an electroless plating method is selected in accordance with properties of an object to be laminated. The Ni-based metal film, the Pd-based metal film, and the Au-based metal film are all formed by the electroless plating method in this embodiment. The gate terminal film 74 and the source terminal film 75 are thereby formed on the insulating main surface 72.

The metal film formed in the step of FIG. 14A (sputtering method and/or vapor deposition method) may have either a single layered structure or a laminated structure that includes at least one among an Al-based metal film, an Ag-based metal film, a Cu-based metal film, an Ni-based metal film, a Pd-based metal film, and an Au-based metal film. Also, the metal film formed in the step of FIG. 14B (plating method) may have either a single layered structure or a laminated structure that includes at least one among an Al-based metal film, an Ag-based metal film, a Cu-based metal film, an Ni-based metal film, a Pd-based metal film, and an Au-based metal film.

As described above, the manufacturing method for the semiconductor device 1A includes the preparing step of the wafer structure 80, the forming step of the source pillar electrodes 60, the forming step of the sealing insulator 71, and the forming step of the source terminal film 75. In the preparing step of the wafer structure 80, the water structure 80 that includes the wafer 81 having the first wafer main surface 82 (main surface) and the source electrode 32 (main surface electrode) arranged on the first wafer main surface 82 is prepared.

In the forming step of the source pillar electrodes 60, the plurality of source pillar electrodes 60 are formed at intervals on the source electrode 32. In the forming step of the sealing insulator 71, the sealing insulator 71 that covers the region between the plurality of source pillar electrodes 60 on the source electrode 32 is formed such as to expose parts of the plurality of source pillar electrodes 60. In the forming step of the source terminal film 75, the source terminal film 75 that covers the plurality of source pillar electrodes 60 is formed on the sealing insulator 71.

According to this manufacturing method, a volume of an electrode interposed between the source electrode 32 and the source terminal film 75 can be reduced by the plurality of source pillar electrodes 60. That is, it is made unnecessary to arrange a pillar electrode having a planar area equivalent to the source terminal film 75 on the source electrode 32. Stress due to an electrode interposed between the source electrode 32 and the source terminal film 75 can thereby be reduced. It is therefore possible to suppress shape defects and fluctuations in electrical characteristics due to the stress.

Also, according to this manufacturing method, an object to be sealed can be protected from an external force and humidity by the sealing insulator 71. That is, the object to be sealed can be protected from damage due to the external force and deterioration due to the humidity. Shape defects and fluctuations in electrical characteristics can thereby be suppressed. The semiconductor device 1A that is capable of improving reliability can thus be manufactured.

The manufacturing method for the semiconductor device 1A preferably further includes the step of thinning the wafer 81 after the forming step of the sealing insulator 71. The thinning step of the wafer 81 preferably includes the step of thinning the wafer 81 until it becomes less in thickness than the plurality of source pillar electrodes 60.

The preparing step of the wafer structure 80 preferably includes the step of preparing the wafer structure 80 that includes the wafer 81 having the laminated structure that includes the substrate and the epitaxial layer. In this case, the thinning step of the wafer 81 preferably includes the step of thinning the substrate until it becomes less in thickness than the epitaxial layer. The preparing step of the wafer structure 80 preferably includes the step of preparing the wafer structure 80 including the wafer 81 that includes a monocrystal of a wide bandgap semiconductor.

The forming step of the source pillar electrodes 60 preferably includes the step of forming the plurality of source pillar electrodes 60 in vertically long columnar shapes in cross sectional view. The forming step of the source pillar electrodes 60 preferably includes the step of forming the plurality of source pillar electrodes 60 that are thicker than the source electrode 32.

The forming step of the source terminal film 75 preferably includes the step of forming the source terminal film 75 that is thinner than the plurality of source pillar electrodes 60. The forming step of the source terminal film 75 preferably includes the step of forming the source terminal film 75 that has a thickness of not more than 1/4 the thickness of the plurality of source pillar electrodes 60. The forming step of the sealing insulator 71 preferably includes the step of forming the sealing insulator 71 that is thicker than the source electrode 32.

The forming step of the source pillar electrodes 60 preferably includes the step of forming the second base conductor film 89 that covers the source electrode 32, the step of forming, on the second base conductor film 89, the resist mask 90 that has the plurality of second openings 92 exposing portions of the second base conductor film 89 that cover the source electrode 32, and the step of depositing the third base conductor film 95 (conductor) on portions of the second base conductor film 89 that are exposed from the plurality of second openings 92.

The manufacturing method for the semiconductor device 1A preferably further includes the step of removing the resist mask 90 after the depositing step of the third base conductor film 95. In this case, the forming step of the sealing insulator 71 is preferably performed after the removing step of the resist mask 90.

The forming step of the sealing insulator 71 preferably includes the step of forming the sealing insulator 71 that covers the whole region of the plurality of source pillar electrodes 60 and the step of partially removing the sealing insulator 71 until the plurality of source pillar electrodes 60 are exposed. In this case, the removing step of the sealing insulator 71 may include the step of partially removing the sealing insulator 71 by a grinding method.

The manufacturing method for the semiconductor device 1A preferably includes the step of preparing the wafer structure 80 that includes the wafer 81 having the first wafer main surface 82 on which the device regions 86 and the scheduled cutting lines 87 that demarcate the device regions 86 are set and the source electrode 32 arranged on the first wafer main surface 82 in each device region 86. In this case, the manufacturing method for the semiconductor device 1A preferably includes the step of cutting the wafer 81 and the sealing insulator 71 along the scheduled cutting lines 87 after the forming step of the sealing insulator 71.

The forming step of the source pillar electrodes 60 preferably includes the step of forming the plurality of source pillar electrodes 60 having the total planar area amounting to an occupancy ratio of not more than 30% with respect to a planar area of the device region 86. The forming step of the source terminal film 75 preferably includes the step of forming the source terminal film 75 having the total planar area amounting to an occupancy ratio of not less than 50% with respect to the planar area of the device region 86.

The manufacturing method for the semiconductor device 1A preferably includes the step of forming, before the forming step of the source pillar electrodes 60, the upper insulating film 38 that partially covers the source electrode 32. In this case, the forming step of the source pillar electrodes 60 preferably includes the step of forming the plurality of source pillar electrodes 60 on the source electrode 32 at intervals from the upper insulating film 38. The forming step of the sealing insulator 71 preferably includes the step of forming the sealing insulator 71 that has a portion that covers the source electrode 32 with the upper insulating film 38 interposed therebetween.

The forming step of the upper insulating film 38 preferably includes the step of forming the upper insulating film 38 that includes either one or both of the inorganic insulating film 42 and the organic insulating film 43. The forming step of the sealing insulator 71 preferably includes the step of forming the sealing insulator 71 that includes a thermosetting resin and a plurality of fillers.

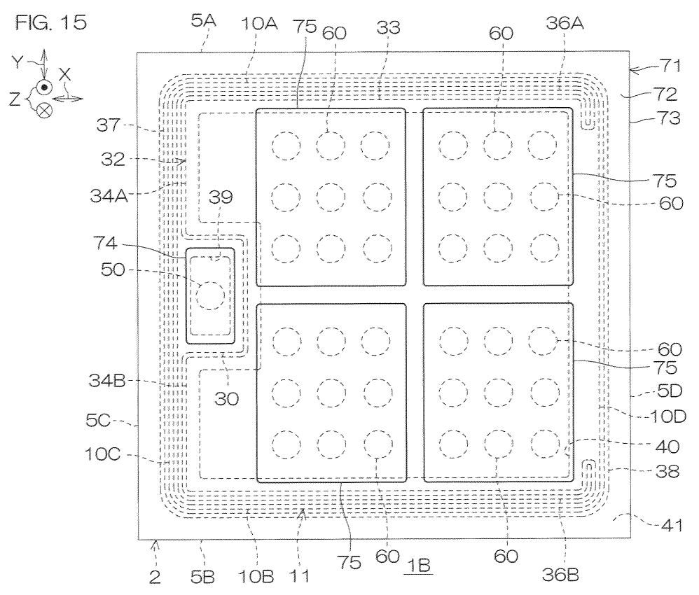

FIG. 15 is a plan view showing a semiconductor device 1B according to a second embodiment. With reference to FIG. 15, the semiconductor device 1B has a modified mode of the semiconductor device 1A. Specifically, the semiconductor device 1B includes a plurality of the source terminal films 75. The plurality of source terminal films 75 are arranged at intervals on the insulating main surface 72 such as to each cover a corresponding at least one (in this embodiment, a plurality) of the source pillar electrodes 60.

The plurality of source terminal films 75 are each electrically connected to the corresponding source pillar electrodes 60. The plurality of source terminal films 75 are arrayed in a matrix pattern at intervals in the first direction X and the second direction Y in plan view in this embodiment. The arrangement and planar shapes of the plurality of source terminal films 75 are arbitrary. For example, the plurality of source terminal films 75 may have mutually different planar areas. Also, the plurality of source terminal films 75 may have mutually different planar shapes.

In a case in which the first main surface 3 has a planar area of not less than 1 mm square, the planar area of each source terminal film 75 is preferably not less than 0.8 mm square. In this case, the planar area of each source terminal film 75 is particularly preferably not less than 1 mm square. Each source terminal film 75 may be formed in a polygonal shape having an area of not less than 1 mm×1.4 mm. Each source terminal film 75 is formed in a quadrilateral shape having four sides parallel to the first to fourth side surfaces 5A to 5D in plan view in this embodiment. As a matter of course, each source terminal film 75 may be formed in a polygonal shape other than the quadrilateral shape, a circular shape, or an elliptical shape in plan view.

As described above, the same effects as those of the semiconductor device 1A are also achieved with the semiconductor device 1B. The semiconductor device 1B is manufactured by changing a layout of the source terminal film 75 in the manufacturing method for the semiconductor device 1A. Therefore, the same effects as those of the manufacturing method for the semiconductor device 1A are also achieved with a manufacturing method for the semiconductor device 1B.

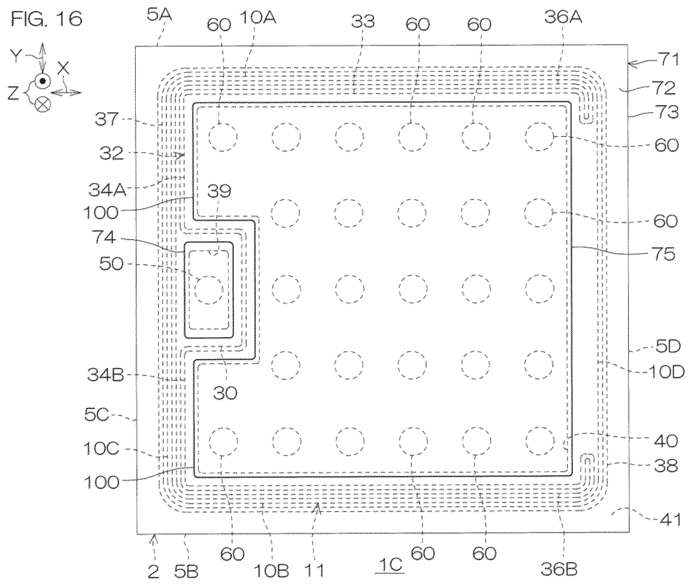

FIG. 16 is a plan view showing a semiconductor device 1C according to a third embodiment. With reference to FIG. 16, the semiconductor device 1C has a modified mode of the semiconductor device 1A. Specifically, the semiconductor device 1C includes the source pillar electrodes 60 that are arranged on at least one or both (in this embodiment, both) of the plurality of drawer electrode portions 34A and 34B in addition to the body electrode portion 33 of the source electrode 32. The number of source pillar electrodes 60 that are arranged on the drawer electrode portions 34A and 34B is arbitrary and one or a plurality of the source pillar electrodes 60 may be arranged on the drawer electrode portions 34A and 34B, respectively.

The source terminal film 75 described above has at least one (in this embodiment, a plurality of) drawer terminal portion 100 in this embodiment. Specifically, the plurality of drawer terminal portions 100 are respectively drawn out to regions overlapping with the plurality of drawer electrode portions 34A and 34B such as to oppose the gate terminal film 74 in the second direction Y in plan view. That is, the plurality of drawer terminal portions 100 sandwich the gate pillar electrode 50 from both sides of the second direction Y in plan view. The plurality of drawer terminal portions 100 each cover at least one (in this embodiment, one) source pillar electrode 60.

As described above, the same effects as those of the semiconductor device 1A are also achieved with the semiconductor device 1C. Also, the semiconductor device 1C is manufactured through the same manufacturing method as the manufacturing method for the semiconductor device 1A. Therefore, the same effects as those of the manufacturing method for the semiconductor device 1A are also achieved with the manufacturing method for the semiconductor device 1C. An example in which the drawer terminal portions 100 are applied to the semiconductor device 1A was illustrated with this embodiment. As a matter of course, the drawer terminal portions 100 may also be applied to the second embodiment.

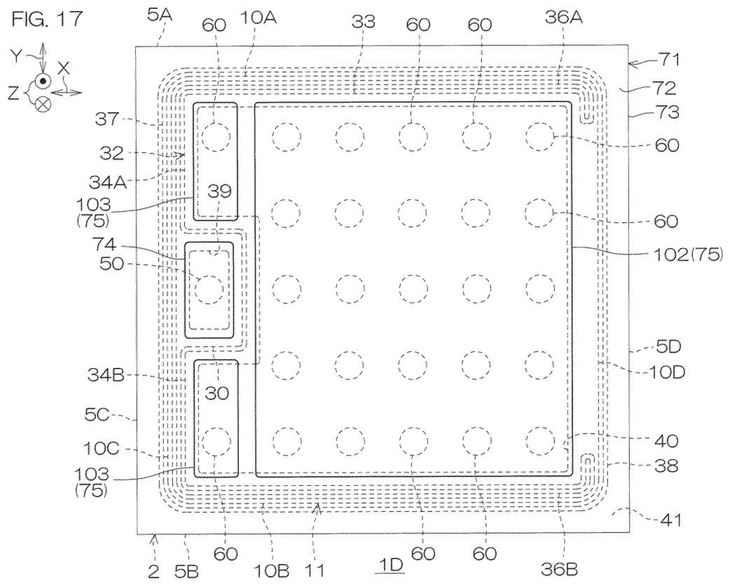

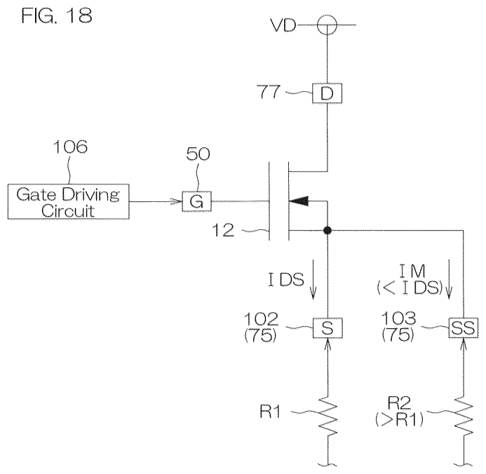

FIG. 17 is a plan view showing a semiconductor device 1D according to a fourth embodiment. FIG. 18 is a circuit diagram showing an electrical configuration of the semiconductor device 1D shown in FIG. 16. With reference to FIG. 17 and FIG. 18, the semiconductor device 1D has a modified mode of the semiconductor device 1A. Specifically, the semiconductor device 1D includes the source pillar electrodes 60 that are arranged on at least one or both (in this embodiment, both) of the plurality of drawer electrode portions 34A and 34B in addition to the body electrode portion 33 of the source electrode 32. The number of source pillar electrodes 60 that are arranged on the drawer electrode portions 34A and 34B is arbitrary and one or a plurality of the source pillar electrodes 60 may be arranged on the drawer electrode portions 34A and 34B, respectively.

The semiconductor device 1D includes a plurality of the source terminal films 75 that are arranged at intervals on the source electrode 32 in this embodiment. Specifically, the semiconductor device 1D includes at least one (in this embodiment, one) source terminal film 75 arranged at a position overlapping with the body electrode portion 33 of the source electrode 32 and at least one (in this embodiment, a plurality) of source terminal films 75 arranged at positions overlapping with the drawer electrode portions 34A and 34B of the source electrode 32 in plan view.

The source terminal film 75 on the body electrode portion 33 side is formed as a main terminal film 102 that conducts a drain source current IDS in this embodiment. The main terminal film 102 covers the source pillar electrodes 60 such as to be electrically connected to the plurality of source pillar electrodes 60.

The plurality of source terminal films 75 on the plurality of drawer electrode portions 34A and 34B sides are formed as sense terminal films 103 that conduct a monitor current IM for monitoring the drain source current IDS in this embodiment. Each sense terminal film 103 has an area less than an area of the main terminal film 102 in plan view. Each sense terminal film 103 covers at least one (in this embodiment, one) source pillar electrode 60.

One sense terminal film 103 is arranged on the first drawer electrode portion 34A and opposes the gate pillar electrode 50 in the second direction Y in plan view. The other sense terminal film 103 is arranged on the second drawer electrode portion 34B and opposes the gate pillar electrode 50 in the second direction Y in plan view. The plurality of sense terminal films 103 thereby sandwich the gate pillar electrode 50 from both sides in the second direction Y in plan view.

With reference to FIG. 18, in the semiconductor device 1D, a gate driving circuit 106 is to be electrically connected to the gate terminal film 74, at least one first resistance R1 is to be electrically connected to the main terminal film 102, and at least one second resistance R2 is to be electrically connected to the plurality of sense terminal film 103. The first resistance R1 is configured such as to conduct the drain source current IDS that is generated in the semiconductor device 1D. The second resistance R2 is configured such as to conduct the monitor current IM having a value less than that of the drain source current IDS.

The first resistance R1 may be a resistor or a conductive bonding member with a first resistance value. The second resistance R2 may be a resistor or a conductive bonding member with a second resistance value more than the first resistance value. The conductive bonding member may be a conductor plate or a conducting wire (for example, bonding wire). That is, at least one first bonding wire with the first resistance value may be connected to the main terminal film 102.

Also, at least one second bonding wire with the second resistance value exceeding the first resistance value may be connected to at least one of the sense terminal films 103. The second bonding wire may have a line thickness less than a line thickness of the first bonding wire. In this case, a bonding area of the second bonding wire with respect to the sense terminal film 103 may be less than a bonding area of the first bonding wire with respect to the main terminal film 102.

As described above, the same effects as those of the semiconductor device 1A are also achieved with the semiconductor device 1D. The semiconductor device 1D can be manufactured by changing the layout of the source terminal film 75 in the manufacturing method of the semiconductor device 1A. Therefore, the same effects as those of the manufacturing method for the semiconductor device 1A are also achieved with the manufacturing method for the semiconductor device 1D.

In this embodiment, an example in which sense terminal film 103 are formed on the drawer electrode portions 34A, 34B, but the arrangement locations of the sense terminal film 103 are arbitrary. Therefore, the sense terminal film 103 may be arranged on the body electrode portion 33. In this embodiment, an example in which the sense terminal film 103 is applied to the semiconductor device 1A has been shown. As a matter of course, the sense terminal film 103 may be applied to the second to third embodiments.

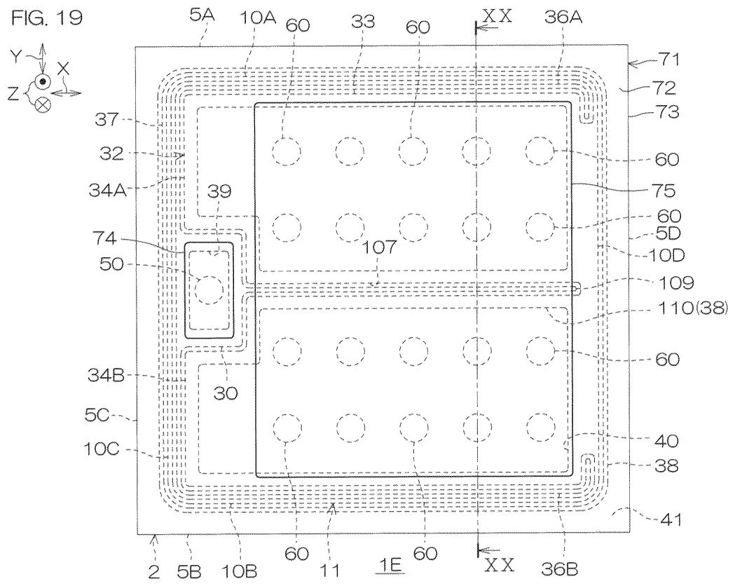

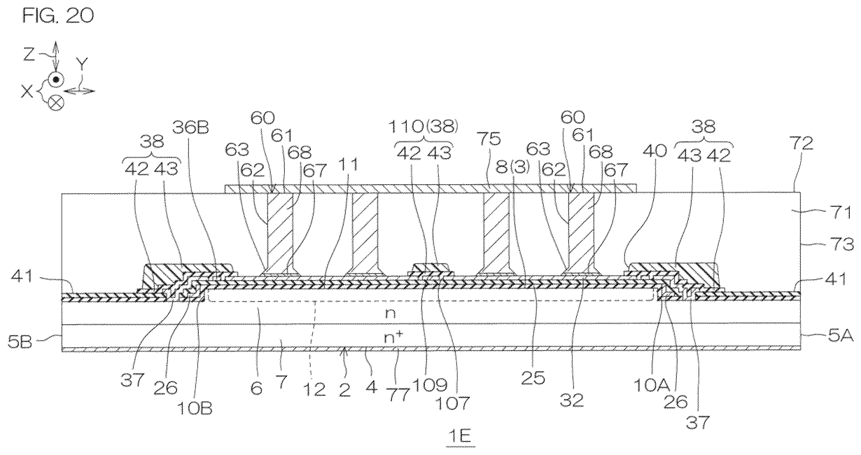

FIG. 19 is a plan view showing a semiconductor device 1E according to a fifth embodiment. FIG. 20 is a cross sectional view taken along XX-XX line shown in FIG. 19. With reference to FIG. 19 and FIG. 20, the semiconductor device 1E has a modified mode of the semiconductor device 1A. Specifically, the semiconductor device 1E includes a gap portion 107 that formed in the source electrode 32.

The gap portion 107 is formed in the body electrode portion 33 of the source electrode 32. The gap portion 107 penetrates the source electrode 32 to expose a part of the interlayer insulating film 27 in cross sectional view. The gap portion 107 extends in a band shape toward an inner portion of the source electrode 32 from a portion of a wall portion of the source electrode 32 that opposes the gate electrode 30 in the first direction X, in this embodiment.

The gap portion 107 is formed in a band shape extending in the first direction X, in this embodiment. The gap portion 107 crosses a central portion of the source electrode 32 in the first direction X in plan view, in this embodiment. The gap portion 107 has an end portion at a position at an interval inward (to the gate electrode 30 side) from a wall portion of the source electrode 32 on the fourth side surface 5D side in plan view. As a matter of course, the gap portion 107 may divide the source electrode 32 into the second direction Y.

The semiconductor device 1E includes a gate intermediate wiring 109 that is drawn out into the gap portion 107 from the gate electrode 30. The gate intermediate wiring 109 has a laminated structure that includes the first gate conductor film 55 and the second gate conductor film 56 as with the gate electrode 30 (the plurality of gate wiring 36A, 36B). The gate intermediate wiring 109 is formed at an interval from the source electrode 32 and extends in a band shape along the gap portion 107 in plan view.

The gate intermediate wiring 109 penetrates the interlayer insulating film 27 at an inner portion of the active surface 8 (the first main surface 3) and is electrically connected to the plurality of gate structures 15. The gate intermediate wiring 109 may be directly connected to the plurality of gate structures 15, or may be electrically connected to the plurality of gate structures 15 via a conductor film.

The upper insulating film 38 aforementioned includes a gap covering portion 110 that covers the gap portion 107 of the source electrode 32, in this embodiment. The gap covering portion 110 covers a whole region of the gate intermediate wiring 109 inside the gap portion 107. The gap covering portion 110 may be drawn out onto the source electrode 32 from inside the gap portion 107 such as to cover the peripheral edge portion of the source electrode 32.

The plurality of source pillar electrodes 60 are each arranged on the source electrode 32 at an interval from the gap covering portion 110 in plan view in this embodiment. The sealing insulator 71 covers the gap portion 107 in a region between the plurality of source pillar electrodes 60 in this embodiment. Specifically, the sealing insulator 71 covers the gap covering portion 110 of the upper insulating film 38 in the region between the plurality of source pillar electrodes 60. That is, the sealing insulator 71 covers the gate intermediate wiring 109 with the upper insulating film 38 interposed therebetween.

The source terminal film 75 has the same mode as in the case of the first embodiment. The source terminal film 75 is arranged on the insulating main surface 72 such as to overlap with the source electrode 32, the gap portion 107, the gate intermediate wiring 109, and the gap covering portion 110 in plan view in this embodiment. The planar shape of the source terminal film 75 is arbitrary and not restricted to a specific mode.

An example in which the upper insulating film 38 has the gap covering portion 110 has been shown, in this embodiment. However, the presence or the absence of the gap covering portion 110 is arbitrary, and the upper insulating film 38 without the gap covering portion 110 may be formed. In this case, the plurality of source pillar electrodes 60 are formed on the source electrode 32 such as to expose the gate intermediate wiring 109. The sealing insulator 71 directly covers the gate intermediate wiring 109, and electrically isolates the gate intermediate wiring 109 from the source electrode 32. The sealing insulator 71 directly covers a part of the interlayer insulating film 27 that exposes at a region between the source electrode 32 and the gate intermediate wiring 109 inside the gap portion 107.

As described above, the same effects as those of the semiconductor device 1A are also achieved with the semiconductor device 1E. In the manufacturing method for the semiconductor device 1E, the wafer structure 80 in which structures corresponding to the semiconductor device 1E are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1E.

An example in which the gap portion 107, the gate intermediate wiring 109, the gap covering portion 110, etc., are applied to the semiconductor device 1A has been shown, in this embodiment. As a matter of course, the gap portion 107, the gate intermediate wiring 109, the gap covering portion 110, etc., may be applied to the second to fourth embodiments.

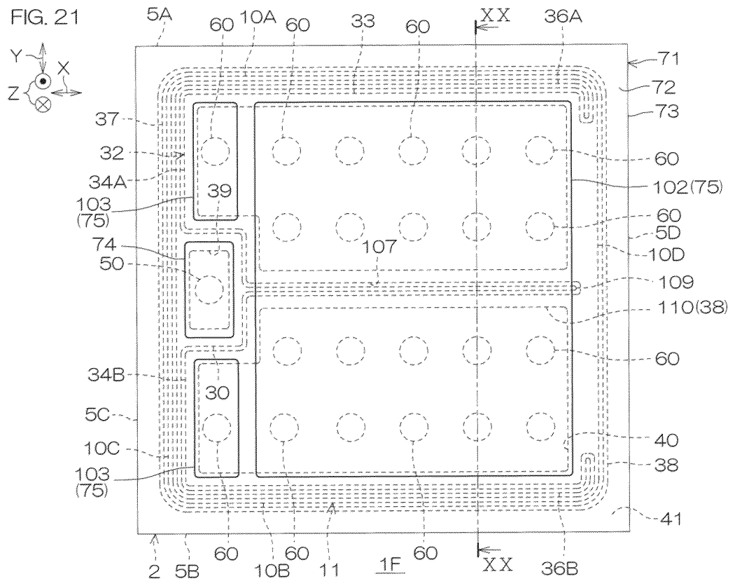

FIG. 21 is a plan view showing a semiconductor device 1F according to a sixth embodiment. With reference to FIG. 21, the semiconductor device 1F has a mode in which the features (structures having the gate intermediate wiring 109) of the semiconductor device 1E according to the fifth embodiment are combined to the features (structures having the sense terminal electrode 103) of the semiconductor device 1D according to the fourth embodiment. The same effects as those of the semiconductor device 1A are also achieved with the semiconductor device 1F having such a mode.

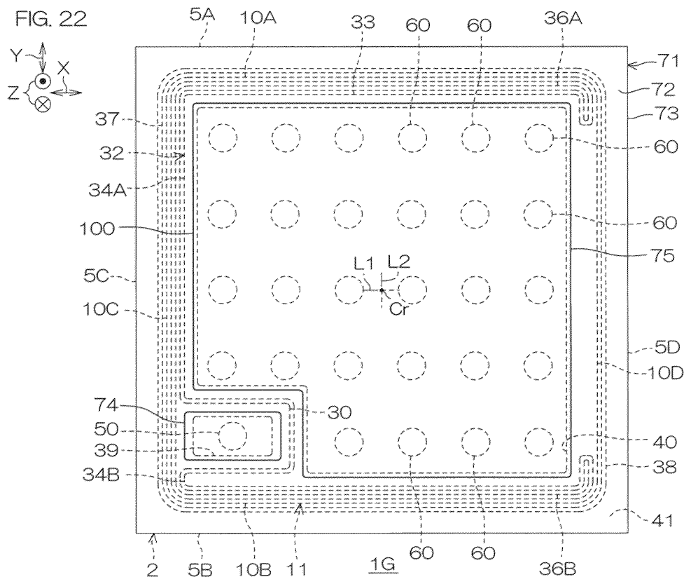

FIG. 22 is a plan view showing a semiconductor device 1G according to a seventh embodiment. With reference to FIG. 22, the semiconductor device 1G has a modified mode of the semiconductor device 1A. Specifically, the semiconductor device 1G has the gate electrode 30 arranged on a region along an arbitrary corner portion of the chip 2.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged at a position offset from both of the first straight line L1 and the second straight line L2. The gate electrode 30 is arranged at a region along a corner portion that connects the second side surface 5B and the third side surface 5C in plan view, in this embodiment.

The plurality of drawer electrode portions 34A, 34B of the source electrode 32 aforementioned sandwich the gate electrode 30 from both sides of the second direction Y in plan view as with the case of the first embodiment. The first drawer electrode portion 34A is drawn out from the body electrode portion 33 with a first planar area. The second drawer electrode portion 34B is drawn out from the body electrode portion 33 with a second planar area less than the first planar area. As a matter of course, the source electrode 32 does not may have the second drawer electrode portion 34B and may only include the body electrode portion 33 and the first drawer electrode portion 34A.

The gate pillar electrode 50 aforementioned is arranged on the gate electrode 30 as with the case of the first embodiment. The gate pillar electrode 50 is arranged at a region along an arbitrary corner portion of the chip 2, in this embodiment. That is, the gate pillar electrode 50 is arranged at a position offset from both of the first straight line L1 and the second straight line L2 in plan view. The gate pillar electrode 50 is arranged at the region along the corner portion that connects the second side surface 5B and the third side surface 5C in plan view, in this embodiment.

The source pillar electrodes 60 aforementioned are arranged on the body electrode portion 33 and the first electrode portion 34A of the source electrode 32, and are not arranged on the second portion 34B, in this embodiment.

The gate terminal film 74 aforementioned covers the gate pillar electrode 50 as with the case of the first embodiment. The gate terminal film 74 is arranged at a region along an arbitrary corner portion of the chip 2 in this embodiment. That is, the gate terminal film 74 is arranged at a position offset from both of the first straight line L1 and the second straight line L2 in plan view. The gate terminal film 74 is arranged at the region along the corner portion that connects the second side surface 5B and the third side surface 5C in plan view in this embodiment.

The source terminal film 75 aforementioned covers the plurality of source pillar electrodes 60 as with the case of the first embodiment. The source terminal film 75 has the drawer terminal portion 100 that is drawn out to the region overlapping with the first drawer electrode portion 34A such as to oppose the gate terminal film 74 in the second direction Y in plan view in this embodiment. The source terminal film 75 is not drawn out onto the second drawer electrode portion 34B in this embodiment.

The drawer terminal portion 100 thus opposes the gate terminal film 74 from one side in the second direction Y. The drawer terminal portion 100 covers at least one (in this embodiment, a plurality) of the source pillar electrodes 60. Due to having the drawer terminal portion 100, the plurality of source pillar electrodes 60 have portions opposing the gate terminal 74 from the two directions of the first direction X and the second direction Y.

As described above, the same effects as those of the semiconductor device 1A are also achieved with the semiconductor device 1G. In the manufacturing method for the semiconductor device 1G, the wafer structure 80 in which structures corresponding to the semiconductor device 1G are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1G. The structure in which the gate electrode 30 and the gate pillar electrode 50 are arranged on the region along the corner portion of the chip 2 may be applied to the second to sixth embodiments.

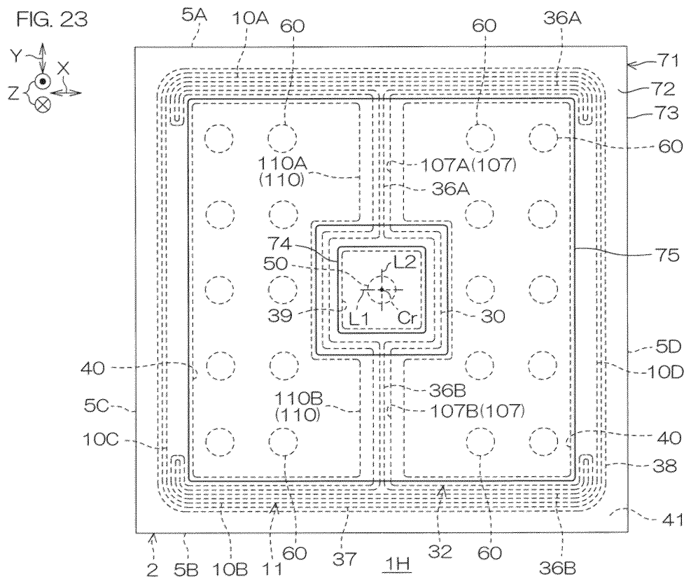

FIG. 23 is a plan view showing a semiconductor device 1H according to a eighth embodiment. With reference to FIG. 23, the semiconductor device 1H has a modified mode of the semiconductor device 1A. Specifically, the semiconductor device 1H has the gate electrode 30 arranged at the central portion of the first main surface 3 (the active surface 8) in plan view.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged such as to overlap an intersecting portion Cr of the first straight line L1 and the second straight line L2. The source electrode 32 aforementioned is formed in an annular shape (specifically, a quadrangle annular shape) surrounding the gate electrode 30 in plan view, in this embodiment.

The semiconductor device 1H includes a plurality of gap portions 107A, 107B that are formed in the source electrode 32. The plurality of gap portions 107A, 107B includes a first gap portions 107A and a second gap portions 107B. The first gap portion 107A crosses a portion of the source electrode 32 that extends in the first direction X in a region on one side (the first side surface 5A side) of the source electrode 32 in the second direction Y. The first gap portion 107A faces the gate electrode 30 in the second direction Y in plan view.

The second gap portion 107B crosses a portion of the source electrode 32 that extends in the first direction X in a region on the other side (the second side surface 5B side) of the source electrode 32 in the second direction Y. The second gap portion 107B faces the gate electrode 30 in the second direction Y in plan view. The second gap portion 107B faces the first gap portion 107A with the gate electrode 30 interposed therebetween in plan view, in this embodiment.

The first gate wiring 36A aforementioned is drawn out into the first gap portion 107A from the gate electrode 30. Specifically, the first gate wiring 36A has a portion extending as a band shape in the second direction Y inside the first gap portion 107A and a portion extending as a band shape in the first direction X along the first side surface 5A (the first connecting surface 10A). The second gate wiring 36B aforementioned is drawn out into the second gap portion 107B from the gate electrode 30. Specifically, the second gate wiring 36B has a portion extending as a band shape in the second direction Y inside the second gap portion 107B and a portion extending as a band shape in the first direction X along the second side surface 5B (the second connecting surface 10B).

The plurality of gate wirings 36A, 36B intersect (specifically, perpendicularly intersect) the both end portions of the plurality of gate structures 15 as with the case of the first embodiment. The plurality of gate wirings 36A, 36B penetrate the interlayer insulating film 27 and are electrically connected to the plurality of gate structures 15. The plurality of gate wirings 36A, 36B may be directly connected the plurality of gate structures 15, or may be electrically connected to the plurality of gate structures 15 via a conductor film.

The source wiring 37 aforementioned is drawn out from a plural portions of the source electrode 32 and surrounds the gate electrode 30, the source electrode 32 and the gate wirings 36A, 36B. As a matter of course, the source wiring 37 may be drawn out from a single portion of the source electrode 32 as with the case of the first embodiment.

The upper insulating film 38 aforementioned includes a plurality of gap covering portions 110A, 110B each cover the plurality of gap portions 107A, 107B, in this embodiment. The plurality of gap covering portions 110A, 110B includes a first gap covering portion 110A and a second gap covering portion 110B. The first gap covering portion 110A covers a whole region of the first gate wiring 36A in the first gap portion 107A. The second gap covering portion 110B covers a whole region of the second gate wiring 36B in the second gap portion 107B. The plurality of gap covering portions 110A, 110B are each drawn out onto the source electrode 32 from inside the plurality of gap portions 107A, 107B such as to cover the peripheral edge portion of the source electrode 32.

The gate pillar electrode 50 aforementioned is arranged on the gate electrode 30 as with the case of the first embodiment. The gate pillar electrode 50 is arranged on the central portion of the first main surface 3 (the active surface 8), in this embodiment. That is, when the first straight line L1 (see two-dot chain line portion) crossing the central portion of the first main surface 3 in the first direction X and the second straight line L2 (see two-dot chain line portion) crossing the central portion of the first main surface 3 in the second direction Y are set, the gate pillar electrode 50 is arranged such as to overlap the intersecting portion Cr of the first straight line L1 and the second straight line L2.

The plurality of source pillar electrodes 60 aforementioned are each arranged on the source electrode 32 at intervals from the plurality of gap covering portions 110A and 110B in plan view in this embodiment. The sealing insulator 71 aforementioned covers the plurality of gap portions 107A and 107B in a region between the plurality of source pillar electrodes 60 in this embodiment. The sealing insulator 71 covers the plurality of gap covering portions 110A and 110B in this embodiment. That is, the sealing insulator 71 covers the plurality of gate wirings 36A and 36B with the plurality of gap covering portions 110A and 110B interposed therebetween.

The gate terminal film 74 aforementioned covers the gate pillar electrode 50 as with the case of the first embodiment. The gate terminal film 74 is arranged at the central portion of the first main surface 3 (the active surface 8) in this embodiment. That is, when the first straight line L1 (see the two-dot chain line portion) crossing the central portion of the first main surface 3 in the first direction X and the second straight line L2 (see the two-dot chain line portion) crossing the central portion of the first main surface 3 in the second direction Y are set, the gate terminal film 74 is arranged such as to cover the intersecting portion Cr of the first straight line L1 and the second straight line L2.

The source terminal film 75 aforementioned is formed in a band shape extending along the gate terminal film 74 in plan view in this embodiment. The source terminal film 75 is formed in an annular shape surrounding the gate terminal film 74 in plan view in this embodiment. The source terminal film 75 overlaps with the source electrode 32, the plurality of gate wirings 36A and 36B, the plurality of gap portions 107A and 107B, and the plurality of gap covering portions 110A and 110B in plan view in this embodiment. The layout (number and planar shape) of the source terminal film 75 is arbitrary and the source terminal film 75 does not necessarily have to be formed in an annular shape in plan view. For example, the plurality of source terminal films 75 that extend in band shapes along the gate terminal film 74 may be arranged.

An example in which the upper insulating film 38 has the gap covering portion 110A, 110B has been shown, in this embodiment. However, the presence or the absence of the plurality of gap covering portion 110A, 110B is arbitrary and the upper insulating film 38 without the plurality of gap covering portion 110A, 110B may be formed. In this case, the plurality of source pillar electrodes 60 are formed on the source electrode 32 such as to expose the gate wirings 36A, 36B.

The sealing insulator 71 directly covers the gate wirings 36A, 36B and electrically isolates the gate wirings 36A, 36B from the source electrode 32. The sealing insulator 71 directly covers a part of the interlayer insulating film 27 exposed from a region between the source electrode 32 and the gate wirings 36A, 36B inside the plurality of gap portions 107A, 107B.

As described above, the same effects as those of the semiconductor device 1A are also achieved with the semiconductor device 1H. In the manufacturing method for the semiconductor device 1H, the wafer structure 80 in which structures corresponding to the semiconductor device 1H are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1H. The structure in which the gate electrode 30 and the gate pillar electrode 50 are arranged on the central portion of the chip 2 may be applied to the second to seventh embodiments.

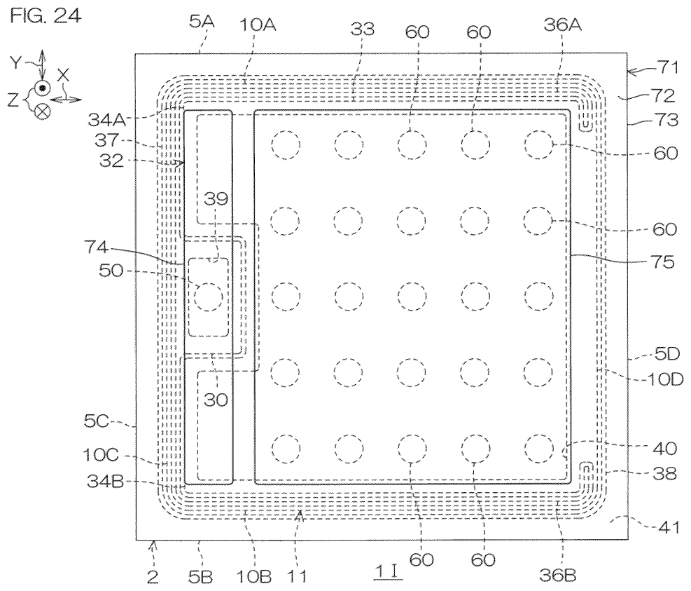

FIG. 24 is a plan view showing a semiconductor device 1I according to a ninth embodiment. The semiconductor device 1I has a modified mode of the semiconductor device 1A. Specifically, the semiconductor device 1I includes the gate terminal film 74 that is arranged at a position overlapping with the gate electrode 30 and the source electrode 32 in plan view.

The gate terminal film 74 is drawn out from a position overlapping with the gate electrode 30 to positions overlapping with the plurality of drawer electrode portions 34A and 34B of the source electrode 32 in plan view in this embodiment. The gate terminal film 74 does not necessarily have to overlap with both of the plurality of drawer electrode portions 34A and 34B in plan view. The gate terminal film 74 may be arranged such as to overlap with just one of either of the plurality of drawer electrode portions 34A and 34B in plan view. As a matter of course, the gate terminal film 74 may be arranged such as to overlap with the body electrode portion 33 of the source electrode 32 in plan view.

As described above, the same effects as those of the semiconductor device 1A are also achieved with the semiconductor device 1I. The semiconductor device 1I is manufactured by changing the layout of the gate terminal film 74 in the manufacturing method for the semiconductor device 1A. Therefore, the same effects as those of the manufacturing method for the semiconductor device 1A are also achieved with a manufacturing method for the semiconductor device 1I. The structure in which the gate terminal film 74 is arranged such as to overlap with a portion of the source electrode 32 in plan view may also be applied to the second to eighth embodiments.

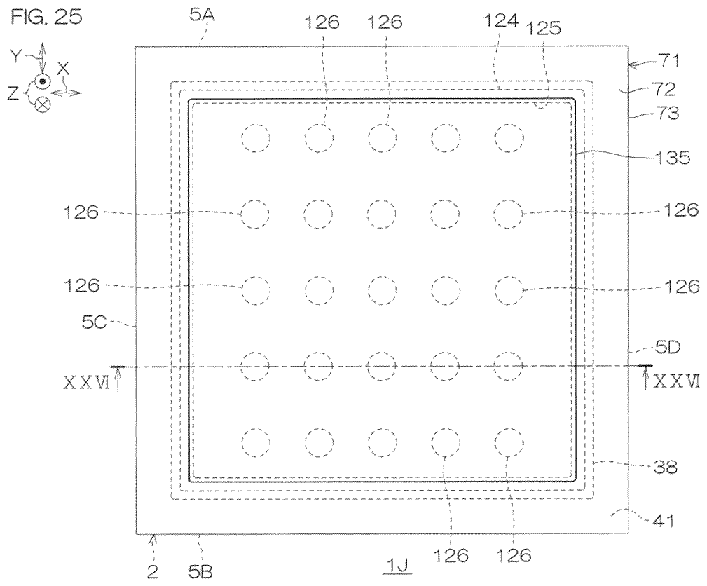

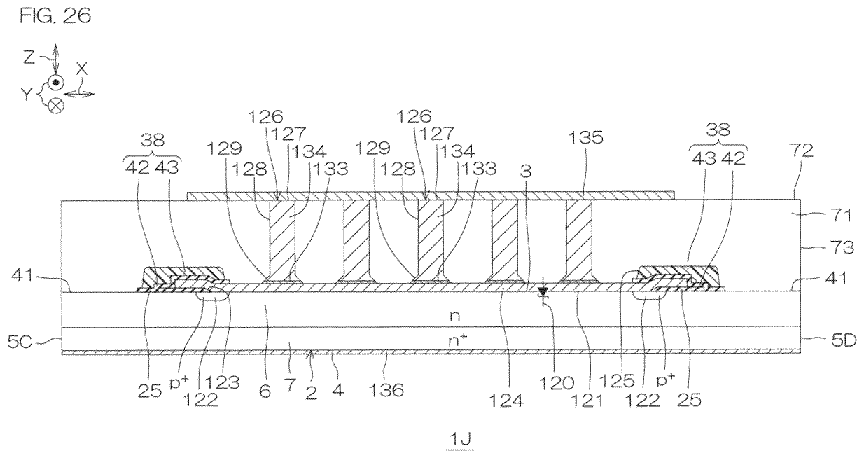

FIG. 25 is a plan view showing a semiconductor device 1J according to a tenth embodiment. FIG. 26 is a cross sectional view taken along XXVI-XXVI line shown in FIG. 25. The semiconductor device 1J includes the chip 2 aforementioned. The chip 2 is free from the mesa portion 11 in this embodiment and has the flat first main surface 3. The semiconductor device 1J has an SBD (Schottky Barrier Diode) structure 120 that is formed in the chip 2 as an example of a diode.

The semiconductor device 1J includes a diode region 121 of the n-type that is formed in an inner portion of the first main surface 3. The diode region 121 is formed by using a part of the first semiconductor region 6, in this embodiment.

The semiconductor device 1J includes a guard region 122 of the p-type that demarcates the diode region 121 from other region at the first main surface 3. The guard region 122 is formed in a surface layer portion of the first semiconductor region 6 at the interval from a peripheral edge of the first main surface 3. The guard region 122 is formed in an annular shape (in this embodiment, a quadrangle annular shape) surrounding the diode region 121 in plan view, in this embodiment. The guard region 122 has an inner end portion on the diode region 121 side and an outer end portion on the peripheral edge side of the first main surface 3.

The semiconductor device 1J includes the main surface insulating film 25 aforementioned that selectively covers the first main surface 3. The main surface insulating film 25 has a diode opening 123 that exposes the diode region 121 and the inner end portion of the guard region 122. The main surface insulating film 25 is formed at an interval inward from the peripheral edge of the first main surface 3 and exposes the first main surface 3 (the first semiconductor region 6) from the peripheral edge portion of the first main surface 3. As a matter of course, the main surface insulating film 25 may cover the peripheral edge portion of the first main surface 3. In this case, the peripheral edge portion of the main surface insulating film 25 may be continuous to the first to fourth side surfaces 5A to 5D.

The semiconductor device 1J includes a first polar electrode 124 (main surface electrode) that is arranged on the first main surface 3. The first polar electrode 124 is an “anode electrode”, in this embodiment. The first polar electrode 124 is arranged at an interval inward from the peripheral edge of the first main surface 3. The first polar electrode 124 is formed in a quadrangle shape along the peripheral edge of the first main surface 3 in plan view, in this embodiment. The first polar electrode 124 enters into the diode opening 123 from on the main surface insulating film 25, and is electrically connected to the first main surface 3 and the inner end portion of guard region 122.

The first polar electrode 124 forms a Schottky junction with the diode region 121 (the first semiconductor region 6). The SBD structure 120 is thereby formed. A planar area of the first polar electrode 124 is preferably not less than 50% of the first main surface 3. The planar area of the first polar electrode 124 is particularly preferably not less than 75% of the first main surface 3. The first polar electrode 124 may have a thickness of not less than 0.5 μm and not more than 15 μm.

The first polar electrode 124 may have a laminated structure that includes a Ti-based metal film and an Al-based metal film. The Ti-based metal film may have a single layered structure consisting of a Ti film or a TiN film. The Ti-based metal film may have a laminated structure that includes the Ti film and the TiN film laminated with an arbitrary order. The Al-based metal film is preferably thicker than the Ti-based metal film. The Al-based metal film may include at least one of a pure Al film (Al film with a purity of not less than 99%), an AlCu alloy film, an AlSi alloy film and an AlSiCu alloy film.

The semiconductor device 1J includes the upper insulating film 38 aforementioned that selectively covers the main surface insulating film 25 and the first polar electrode 124. The upper insulating film 38 has the laminated structure that includes the inorganic insulating film 42 and the organic insulating film 43 laminated in that order from the chip 2 side as with the case of the first embodiment. The upper insulating film 38 has a contact opening 125 exposing an inner portion of the first polar electrode 124 and covers a peripheral edge portion of the first polar electrode 124 over an entire circumference in plan view, in this embodiment. The contact opening 125 is formed in a quadrangle shape in plan view, in this embodiment.

The upper insulating film 38 is formed at an interval inward from the peripheral edge of the first main surface 3 (the first to fourth side surfaces 5A to 5D) and defines the dicing street 41 with the peripheral edge of the first main surface 3. The dicing street 41 is formed in a band shape extending along the peripheral edge of the first main surface 3 in plan view. The dicing street 41 is formed in an annular shape (specifically, a quadrangle annular shape) surrounding the inner portion of the first main surface 3 in plan view, in this embodiment.

The dicing street 41 exposes the first main surface 3 (the first semiconductor region 6), in this embodiment. As a matter of course, in a case in which the main surface insulating film 25 covers the peripheral edge portion of the first main surface 3, the dicing street 41 may expose the main surface insulating film 25. The upper insulating film 38 preferably has a thickness exceeding the thickness of the first polar electrode 124. The thickness of the upper insulating film 38 may be less than the thickness of the chip 2.

The semiconductor device 1J includes a plurality of pillar electrodes 126 that are arranged on the first polar electrode 124. The number of the pillar electrodes 126 is arbitrary and is adjusted in accordance with a planar area of the first polar electrode 124 and a planar area of the pillar electrodes 126 to be formed. The pillar electrodes 126 are each erected in a vertically long columnar shape on the first polar electrode 124 at an interval from a peripheral edge of the first polar electrode 124 in cross sectional view.

The plurality of pillar electrodes 126 are each arranged on an inner portion of the first polar electrode 124 at an interval from the upper insulating film 38 (the wall surface of the contact opening 125) in this embodiment. That is, the plurality of pillar electrodes 126 are each arranged inside a region surrounded by the contact opening 125 in plan view.

The plurality of pillar electrodes 126 are each formed in a circular shape in plan view in this embodiment. As a matter of course, the plurality of pillar electrodes 126 may each be formed in a quadrilateral shape, a polygonal shape other than the quadrilateral shape, an elliptical shape, or a line shape in plan view. Also, the plurality of pillar electrodes 126 do not need to have mutually the same planar shape and may have mutually different planar shapes.

The plurality of pillar electrodes 126 are arrayed in a matrix pattern at intervals in the first direction X and the second direction Y in plan view in this embodiment. A layout of the plurality of pillar electrodes 126 is arbitrary. The plurality of pillar electrodes 126 may, for example, be arrayed in a staggered pattern at intervals in the first direction X and the second direction Y in plan view.

That is, in a case in which a plurality of groups, each including the plurality of pillar electrodes 126 that are arrayed in a single row in the first direction X, are arrayed at intervals in the second direction Y, the plurality of pillar electrodes 126 included in each group may be arranged to be shifted in the first direction X with respect to the plurality of pillar electrodes 126 included in a group that is adjacent in the second direction Y. As a matter of course, in this structure, a layout in which the array relationship in the first direction X and the second direction Y is interchanged may be adopted.

Also, in a case in which the plurality of pillar electrodes 126 are formed in line shapes extending in the first direction X or the second direction Y in plan view, the plurality of pillar electrodes 126 may be arranged in stripes extending in the first direction X or the second direction Y in plan view. As a matter of course, the plurality of pillar electrodes 126 may be arranged in an irregular layout.

The plurality of pillar electrodes 126 each have an electrode surface 127 and an electrode side wall 128. The electrode surface 127 extends flatly along the first main surface 3. The electrode surface 127 may consist of a ground surface with grinding marks. The electrode side wall 128 is positioned on the first polar electrode 124. The electrode side wall 128 extends substantially vertically in the normal direction Z. “Substantially vertically” also includes a mode that extends in the lamination direction while curving (meandering). The electrode side wall 128 preferably consists of a smooth surface without grinding marks.

The plurality of pillar electrodes 126 each have a protrusion portion 129 that protrudes outward at a lower end portion of the electrode side wall 128 in this embodiment. The protrusion portion 129 is formed in a region further to the first polar electrode 124 side than an intermediate portion of the electrode side wall 128. The protrusion portion 129 is formed in a tapered shape that extends along the first polar electrode 124 and gradually decreases in thickness from the electrode side wall 128 toward a tip portion in cross sectional view. The protrusion portion 129 thereby has a tip portion of sharp-pointed shape that forms an acute angle. As a matter of course, the pillar electrode 126 without the protrusion portion 129 may be formed.

Preferably, the plurality of pillar electrodes 126 each have a thickness exceeding the thickness of the first polar electrode 124. The thickness of each pillar electrode 126 is defined by a distance between the first polar electrode 124 and the electrode surface 127. The thickness of each pillar electrode 126 particularly preferably exceeds the thickness of the upper insulating film 38. The thickness of each pillar electrode 126 exceeds the thickness of the chip 2 in this embodiment. As a matter of course, the thickness of each pillar electrode 126 may be less than the thickness of the chip 2.

The thickness of each pillar electrode 126 may be not less than 10 μm and not more than 300 μm. The thickness of each pillar electrode 126 is preferably not less than 30 μm. The thickness of each pillar electrode 126 is particularly preferably not less than 80 μm and not more than 200 μm. A width (maximum value) of each pillar electrode 126 may be of a value belonging to any range among not less than 1 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 Ξm and not more than 150 μm, not less than 150 μm and not more than 175 μm, and not less than 175 μm and not more than 200 μm. As a matter of course, the width (maximum value) of each pillar electrode 126 is not restricted to the above ranges and may be set to a value exceeding 200 μm.

The plurality of pillar electrodes 126 have a total planar area less than the planar area of the first polar electrode 124. The total planar area of the plurality of pillar electrodes 126 is adjusted in accordance with the planar area of the first polar electrode 124. The total planar area of the plurality of pillar electrodes 126 is preferably not more than 50% of the first main surface 3. The total planar area of the plurality of pillar electrodes 126 is particularly preferably not more than 30% of the first main surface 3. The total planar area of the plurality of pillar electrodes 126 is preferably not less than 10% of the first main surface 3.

The pillar electrodes 126 each has a laminated structure that includes a first conductor film 133 and a second conductor film 134 laminated in that order from the first polar electrode 124 side, in this embodiment. The first conductor film 133 may include a Ti-based metal film. The first conductor film 133 may have a single layered structure consisting of a Ti film or a TiN film.

The first conductor film 133 may have a laminated structure that includes the Ti film and the TiN film laminated with an arbitrary order. The first conductor film 133 has a thickness less than the thickness of the first polar electrode 124. The first conductor film 133 covers the first polar electrode 124 in a film shape inside the contact opening 125. The first conductor film 133 forms a part of the protrusion portion 129. The first conductor film 133 does not necessarily have to be formed and may be omitted.

The second conductor film 134 forms a body of the pillar electrode 126. The second conductor film 134 may include a Cu-based metal film. The Cu-based metal film may be a pure Cu film (Cu film with a purity of not less than 99%) or Cu alloy film. The second conductor film 134 includes a pure Cu plating film, in this embodiment. The second conductor film 134 preferably has a thickness exceeding the thickness of the first polar electrode 124. The thickness of the second conductor film 134 particularly preferably exceeds the thickness of the upper insulating film 38. The thickness of the second conductor film 134 exceeds the thickness of the chip 2, in this embodiment.

The second conductor film 134 covers the first polar electrode 124 with the first conductor film 133 interposed therebetween inside the contact opening 125. The second conductor film 134 forms a part of the protrusion portion 129. That is, the protrusion portion 129 has a laminated structure that includes the first conductor film 133 and the second conductor film 134. The second conductor film 134 has a thickness exceeding a thickness of the first conductor film 133 in the protrusion portion 129.

The semiconductor device 1J includes the sealing insulator 71 aforementioned that covers the first main surface 3. The sealing insulator 71 covers peripheries of the plurality of pillar electrodes 126 such as to expose parts of the plurality of pillar electrodes 126 on the first main surface 3. The sealing insulator 71 covers a region between the plurality of pillar electrodes 126 on the first polar electrode 124. The sealing insulator 71 exposes the plurality of electrode surfaces 127 and covers the plurality of electrode side walls 128.

The sealing insulator 71 has a portion that directly covers a portion of the first polar electrode 124 that is exposed from the upper insulating film 38 and the plurality of pillar electrodes 126. The sealing insulator 71 covers the protrusion portions 129 of the plurality of pillar electrodes 126 and opposes the first polar electrode 124 with the protrusion portions 129 interposed therebetween in this embodiment. The sealing insulator 71 suppresses falling-off of the plurality of pillar electrodes 126.

The sealing insulator 71 has a portion that directly covers the upper insulating film 38. The sealing insulator 71 covers the first polar electrode 124 with the upper insulating film 38 interposed therebetween. The sealing insulator 71 covers the dicing street 41 that is demarcated by the upper insulating film 38 at the peripheral edge portion of the first main surface 3. The sealing insulator 71 directly covers the first main surface 3 (the first semiconductor region 6) at the dicing street 41, in this embodiment. As a matter of course, in a case in which the main surface insulating film 25 is exposed from the dicing street 41, the sealing insulator 71 may directly cover the main surface insulating film 25 at the dicing street 41.

The sealing insulator 71 has the insulating main surface 72 and the insulating side wall 73. The insulating main surface 72 flatly extends along the first main surface 3. The insulating main surface 72 forms a single flat surface with the electrode surfaces 127. The insulating main surface 72 may consist of a ground surface with grinding marks. In this case, the insulating main surface 72 preferably forms a single ground surface with the electrode surfaces 127.

The insulating side wall 73 extends toward the chip 2 from the peripheral edge of the insulating main surface 72 and forms a single flat surface with the first to fourth side surfaces 5A to 5D. The insulating side wall 73 is formed substantially perpendicular to the insulating main surface 72. The angle formed by the insulating side wall 73 with the insulating main surface 72 may be not less than 88° and not more than 92°. The insulating side wall 73 may consist of a ground surface with grinding marks. The insulating side wall 73 may form a single ground surface with the first to fourth side surfaces 5A to 5D.

The sealing insulator 71 preferably has a thickness exceeding the thickness of the first polar electrode 124. The thickness of the sealing insulator 71 particularly preferably exceeds the thickness of the upper insulating film 38. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm. The thickness of the sealing insulator 71 is substantially equal to the thickness of the pillar electrodes 126.

The semiconductor device 1J includes at least one (in this embodiment, one) terminal film 135 that covers the plurality of pillar electrodes 126 on the sealing insulator 71. The terminal film 135 is electrically connected to the plurality of pillar electrodes 126. The terminal film 135 is arranged at an inner portion of the insulating main surface 72 at an interval from the peripheral edge (insulating side wall 73) of the insulating main surface 72 in plan view.

The terminal film 135 is arranged at a layer different from the first polar electrode 124 and is thus hardly restricted by design rules resulting from a layout of the first polar electrode 124. The terminal film 135 can therefore have any planar shape and, at the same time, can be arranged at any location as long as it is electrically connected to the plurality of pillar electrodes 126.

The terminal film 135 has a thickness less than the thickness of the plurality of pillar electrodes 126. The thickness of the terminal film 135 is preferably not more than ¼ that of the pillar electrodes 126. The thickness of the terminal film 135 is particularly preferably not more than 1/10 that of the pillar electrodes 126. The thickness of the terminal film 135 is preferably less than the thickness of the upper insulating film 38. The thickness of the terminal film 135 may be less than the thickness of the first polar electrode 124. The thickness of the terminal film 135 takes various values in accordance with film type. The thickness of the terminal film 135 may be not less than 10 nm and not more than 15 μm.

The terminal film 135 has a planar area exceeding the total planar area of the plurality of pillar electrodes 126. The planar area of the terminal film 135 preferably exceeds the planar area of the first polar electrode 124. In this case, the terminal film 135 preferably covers a whole region of the first polar electrode 124. Further, in this case, the terminal film 135 preferably overlaps with the first terminal electrode 124 and the upper insulating film 38 in plan view.

In a case in which the first main surface 3 has a planar area of not less than 1 mm square, the planar area of the terminal film 135 may be not less than 0.8 mm square. In this case, the planar area of the terminal film 135 is particularly preferably not less than 1 mm square. The terminal film 135 may be formed in a polygonal shape having an area of not less than 1 mm×1.4 mm. The terminal film 135 is formed in a quadrilateral shape having four sides parallel to the first to fourth side surfaces 5A to 5D in plan view in this embodiment. As a matter of course, the terminal film 135 may be formed in a polygonal shape other than the quadrilateral shape, a circular shape, or an elliptical shape in plan view.

The terminal film 135 may have each of a single layered structure or a laminated structure that includes at least one among an Ag-based metal film, an Al-based metal film, a Cu-based metal film, an Ni-based metal film, a Pd-based metal film, and an Au-based metal film. The terminal film 135 may have a configuration according to any of the first to seventh configuration examples shown in FIG. 8A to FIG. 8G.

The semiconductor device 1J includes a second polar electrode 136 (second main surface electrode) that covers the second main surface 4. The second polar electrode 136 is a “cathode electrode”, in this embodiment. The second polar electrode 136 is electrically connected to the second main surface 4. The second polar electrode 136 forms an ohmic contact with the second semiconductor region 7 exposed from the second main surface 4. The second polar electrode 136 may cover a whole region of the second main surface 4 such as to be continuous with the peripheral edge of the chip 2 (the first to fourth side surfaces 5A to 5D).

The second polar electrode 136 may cover the second main surface 4 at an interval from the peripheral edge of the chip 2. The second polar electrode 136 is configured such that a voltage of not less than 500 V and not more than 3000 V is to be applied between the terminal film 135 and second polar electrode 136. That is, the chip 2 is formed such that the voltage of not less than 500 V and not more than 3000 V is to be applied between the first main surface 3 and the second main surface 4.

As described above, the semiconductor device 1J includes the chip 2, the first polar electrode 124 (main surface electrode), the plurality of pillar electrodes 126, the sealing insulator 71, and at least one (in this embodiment, one) terminal film 135. The chip 2 has the first main surface 3. The first polar electrode 124 is arranged on the first main surface 3. The plurality of polar electrodes 126 are arranged at intervals on the first polar electrode 124. The sealing insulator 71 covers the region between the plurality of pillar electrodes 126 on the first polar electrode 124 such as to expose parts of the plurality of pillar electrodes 126. The terminal film 135 covers the plurality of pillar electrodes 126 on the sealing insulator 71.

According to this structure, a volume of an electrode interposed between the first polar electrode 124 and the terminal film 135 can be reduced by the plurality of pillar electrodes 126. That is, it is made unnecessary to arrange a pillar electrode having a planar area equivalent to the terminal film 135 on the first polar electrode 124. Stress due to an electrode interposed between the first polar electrode 124 and the terminal film 135 can thereby be reduced. It is therefore possible to suppress shape defects and fluctuations in electrical characteristics due to the stress.

Also, according to this structure, an object to be sealed can be protected from the external force and the humidity by the sealing insulator 71. That is, the object to be sealed can be protected from a damage due to the external force and deterioration due to the humidity. It is therefore possible to suppress shape defects and fluctuations in electrical characteristics. As a result, it is possible to provide the semiconductor device 1J capable of improving reliability.

Thus, the same effects as those of the semiconductor device 1A are also achieved with the semiconductor device 1J. In the manufacturing method for the semiconductor device 1J, the wafer structure 80 in which structures corresponding to the semiconductor device 1J are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1J.

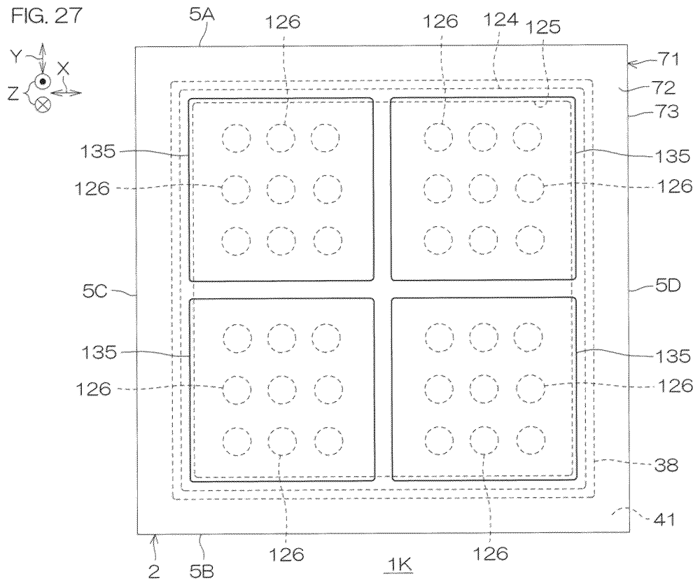

FIG. 27 is a plan view showing a semiconductor device 1K according to a eleventh embodiment. With reference to FIG. 27, the semiconductor device 1K has a mode in which the technical ideas of the semiconductor device 1B according to the second embodiment (see FIG. 15) are combined with the semiconductor device 1J. That is, the semiconductor device 1K includes a plurality of the terminal films 135. The plurality of terminal films 135 are arranged at intervals on the insulating main surface 72 such as to each cover a corresponding at least one (in this embodiment, a plurality) of the pillar electrodes 126.

The plurality of terminal films 135 are each electrically connected to the corresponding pillar electrodes 126. The plurality of terminal films 135 are arrayed in a matrix pattern at intervals in the first direction X and the second direction Y in plan view in this embodiment. The arrangement and planar shapes of the plurality of terminal films 135 are arbitrary.

In a case in which the first main surface 3 has a planar area of not less than 1 mm square, the planar area of each terminal film 135 is preferably not less than 0.8 mm square. In this case, the planar area of each terminal film 135 is particularly preferably not less than 1 mm square. Each terminal film 135 may be formed in a polygonal shape having an area of not less than 1 mm×1.4 mm. Each terminal film 135 is formed in a quadrilateral shape having four sides parallel to the first to fourth side surfaces 5A to 5D in plan view in this embodiment. As a matter of course, each terminal film 135 may be formed in a polygonal shape other than the quadrilateral shape, a circular shape, or an elliptical shape in plan view.

As described above, the same effects as those of the semiconductor device 1J are also achieved with the semiconductor device 1K. The semiconductor device 1K is manufactured by changing a layout of the terminal film 135 in the manufacturing method for the semiconductor device 1J. Therefore, the same effects as those of the manufacturing method for the semiconductor device 1J are also achieved with a manufacturing method for the semiconductor device 1K.

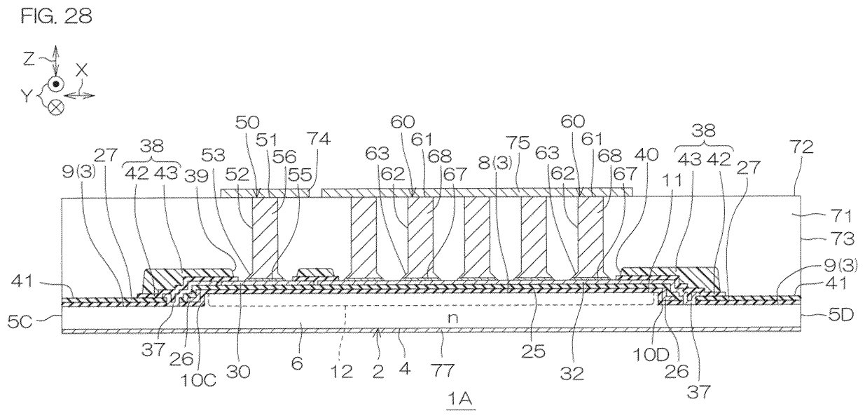

Hereinafter, modified examples to be applied to each embodiment shall be shown. FIG. 28 is a cross sectional view showing a modified example of the chip 2 to be applied to each of the embodiments. In FIG. 28, a mode in which the modified example of the chip 2 is applied to the semiconductor device 1A is shown as an example. However, the modified example of the chip 2 may be applied to any one of the second to eleventh embodiments.

With reference to FIG. 28, the semiconductor device 1A does not have the second semiconductor region 7 inside the chip 2 and may only have the first semiconductor region 6 inside the chip 2. In this case, the first semiconductor region 6 is exposed from the first main surface 3, the second main surface 4 and the first to fourth side surfaces 5A to 5D of the chip 2. That is, the chip 2 has a single layered structure that does not have the semiconductor substrate and that consists of the epitaxial layer, in this embodiment. The chip 2 having such a structure is formed by fully removing the second semiconductor region 7 (the semiconductor substrate) in the step shown in FIG. 11I aforementioned.

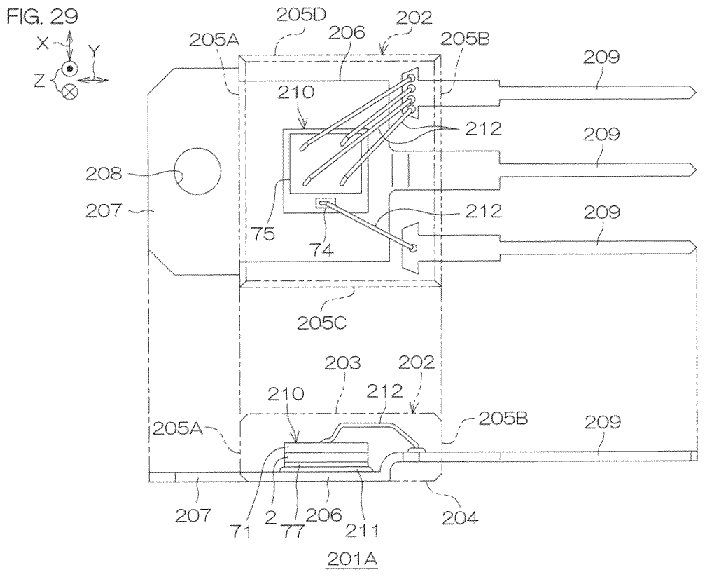

Hereinafter, configuration examples of packages to which any one or plural of the semiconductor devices 1A to 1K according to the first to eleventh embodiments are to be incorporated shall be shown. FIG. 29 is a plan view showing a package 201A to which any one of the semiconductor devices 1A to 1I according to the first to ninth embodiments is to be incorporated. The package 201A may be referred to as a “semiconductor package” or a “semiconductor module”.

With reference to FIG. 29, the package 201A includes a package body 202 of a rectangular parallelepiped shape. The package body 202 consists of a mold resin and includes a matrix resin (for example, epoxy resin), a plurality of fillers and a plurality of flexible particles (flexible agent) as with the sealing insulator 71. The package body 202 has a first surface 203 on one side, a second surface 204 on the other side, and first to fourth side walls 205A to 205D connecting the first surface 203 and the second surface 204.

The first surface 203 and the second surface 204 are each formed in a quadrangle shape in plan view as viewed from their normal direction Z. The first side wall 205A and the second side wall 205B extend in the first direction X and oppose in the second direction Y orthogonal to the first direction X. The third side wall 205C and the fourth side wall 205D extend in the second direction Y and oppose in the first direction X.

The package 201A includes a metal plate 206 (conductor plate) that is arranged inside the package body 202. The metal plate 206 may be referred to as a “die pad”. The metal plate 206 is formed in a quadrangle shape (specifically, rectangular shape) in plan view. The metal plate 206 includes a drawer board part 207 that is drawn out from the first side wall 205A to the outside of the package body 202. The drawer board part 207 has a through hole 208 of a circular shape. The metal plate 206 may be exposed from the second surface 204.

The package 201A includes a plurality of this embodiment, three) lead terminals 209 that are pulled out from an inside of the package body 202 to an outside of the package body 202. The plurality of lead terminals 209 are arranged on the second side wall 205B side. The plurality of lead terminals 209 are each formed in a band shape extending in an orthogonal direction to the second side wall 205B (that is, the second direction Y). The lead terminals 209 on both sides of the plurality of lead terminals 209 are arranged at intervals from the metal plate 206, and the lead terminals 209 on a center is integrally formed with the metal plate 206. A position of the lead terminal 209 that is to be connected to the metal plate 206 is arbitrary.

The package 201A includes a semiconductor device 210 that is arranged on the metal plate 206 inside the package body 202. The semiconductor device 210 consists of any one of the semiconductor devices 1A to 1I according to the first to ninth embodiments. The semiconductor device 210 is arranged on the metal plate 206 in a posture with the drain electrode 77 opposing the metal plate 206, and is electrically connected to the metal plate 206.

The package 201A includes a conductive adhesive 211 that is interposed between the drain electrode 77 and the metal plate 206 and that connects the semiconductor device 210 to the metal plate 206. The conductive adhesive 211 may include a solder or a metal paste. The solder may be a lead-free solder. The metal paste may include at least one of Au, Ag and Cu. The Ag paste may consist of an Ag sintered paste.

The package 201A includes at least one (in this embodiment, a plurality of) conducting wires 212 (conductive connection member) that are electrically connected to the lead terminals 209 and the semiconductor device 210 inside the package body 202. The conducting wires 212 each consists of a metal wire (that is, bonding wire), in this embodiment. The conducting wires 212 may include at least one of an Au wire, a Cu wire and an Al wire. As a matter of course, the conducting wires 212 may each consist of a metal plate such as a metal clip, instead of the metal wire.

At least one (in this embodiment, one) conducting wire 212 is electrically connected to the gate terminal film 74 and the lead terminal 209. At least one (in this embodiment, four) conducting wires 212 are electrically connected to the source terminal film 75 and the lead terminal 209. In a case in which the source terminal film 75 includes the sense terminal film 103 (see FIG. 17), the lead terminal 209 corresponding to the sense terminal film 103, and the conducting wire 212 corresponding to the sense terminal film 103 and the lead terminals 209 may be provided.

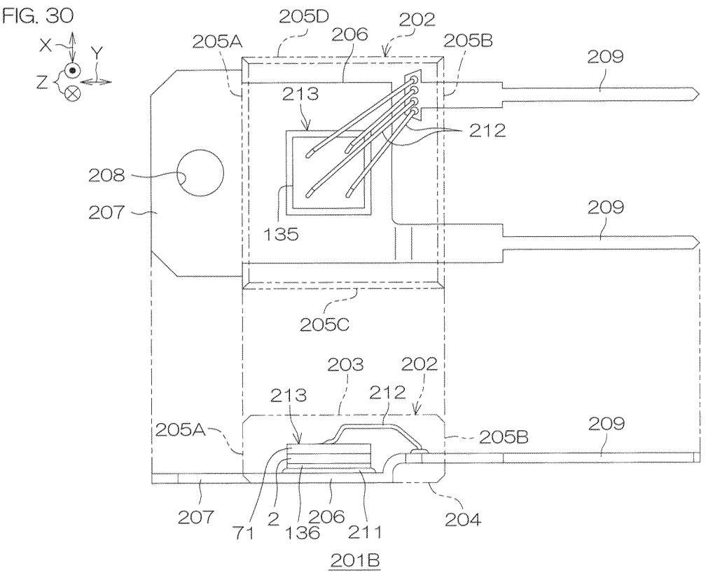

FIG. 30 is a plan view showing a package 201B to which any one of the semiconductor devices 1J to 1K according to the tenth to eleventh embodiments is to be incorporated. The package 201B may be referred to as a “semiconductor package” or a “semiconductor module”. With reference to FIG. 30, the package 201B includes the package body 202, the metal plate 206, the plurality (in this embodiment, two) lead terminals 209, a semiconductor device 213, the conductive adhesive 211, and the plurality conducting wires 212. Hereinafter, points different from those of the package 201A shall be described.

One lead terminal 209 of the plurality of lead terminals 209 is arranged at an interval from the metal plate 206, and the other lead terminals 209 is integrally formed with the metal plate 206. The semiconductor device 213 is arranged on the metal plate 206 inside the package body 202. The semiconductor device 213 consists of any one of the semiconductor devices 1J to 1K according to the tenth to eleventh embodiments. The semiconductor device 213 is arranged on the metal plate 206 in a posture with the second polar electrode 136 opposing to the metal plate 206, and is electrically connected to the metal plate 206.

The conductive adhesive 211 is interposed between the second polar electrode 136 and the metal plate 206 and connects the semiconductor device 213 to the metal plate 206. At least one (in this embodiment, four) conducting wires 212 are electrically connected to the terminal film 135 and the lead terminal 209.

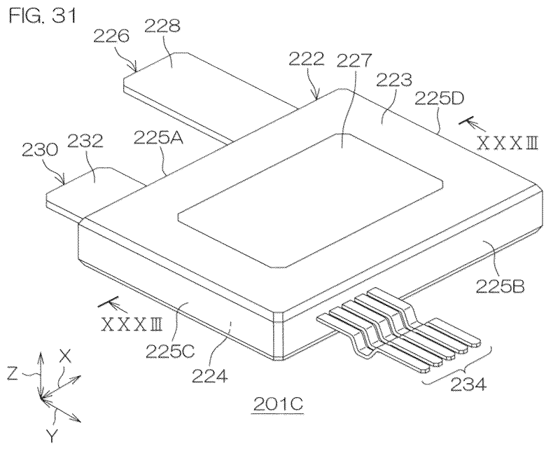

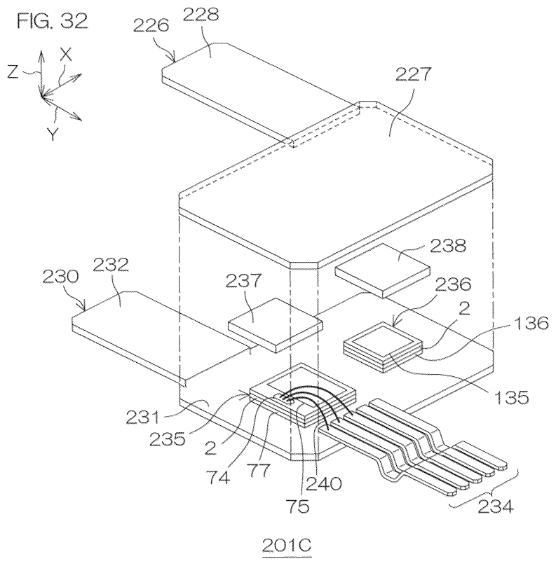

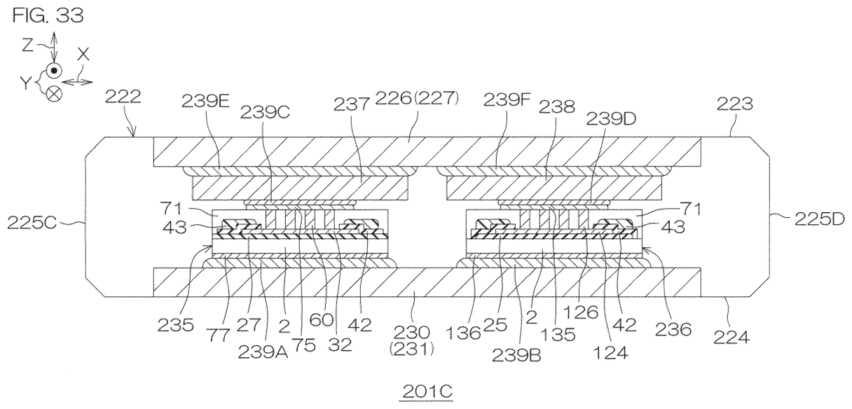

FIG. 31 is a perspective view showing a package 201C to which any one of the semiconductor devices 1A to 1I according to the first to ninth embodiments and the semiconductor device 1J to 1K according to the tenth to eleventh embodiment are to be incorporated. FIG. 32 is an exploded perspective view of the package 201C shown in FIG. 31. FIG. 33 is a cross sectional view taken along XXXIII-XXXIII line shown in FIG. 31. The package 201C may be referred to as a “semiconductor package” or a “semiconductor module”.

With reference to FIG. 31 to FIG. 33, the package 201C includes a package body 222 of a rectangular parallelepiped shape. The package body 222 consists of a mold resin and includes a matrix resin (for example, epoxy resin), a plurality of fillers and a plurality of flexible particles (flexible agent) as with the sealing insulator 71. The package body 222 has a first surface 223 on one side, the second surface 224 on the other side, and first to fourth side walls 225A to 225D connecting the first surface 223 and the second surface 224.

The first surface 223 and the second surface 224 each formed in a quadrangle shape (in this embodiment, rectangular shape) in plan view as viewed from their normal direction Z. The first side wall 225A and the second side wall 225B extend in the first direction X along the first surface 223 and oppose in the second direction Y. The first side wall 225A and the second side wall 225B each forms a long side of the package body 222. The third side wall 225C and the fourth side wall 225D extend in the second direction Y and oppose in the first direction X. The third side wall 225C and the fourth side wall 225D each forms a short side of the package body 222.

The package 201C includes a first metal plate 226 that is arranged inside and outside the package body 222. The first metal plate 226 is arranged on the first surface 223 side of the first surface 223 and includes a first pad portion 227 and a first lead terminal 228. The first pad portion 227 is formed in a rectangular shape extending in the first direction X inside the package body 222 and exposes the first surface 223.

The first lead terminal 228 is pulled out from the first pad portion 227 toward the first side wall 225A in a band shape extending in the second direction Y, and penetrates the first side wall 225A to be exposed from the package body 222. The first lead terminal 228 is arranged on the fourth side wall 225D side in plan view. The first lead terminal 228 is exposed from the first side wall 225A at a position at intervals from the first surface 223 and the second surface 224.

The package 201C includes a second metal plate 230 that is arranged inside and outside the package body 222. The second metal plate 230 is arranged on the second surface 224 side of the package body 222 at an interval from the first metal plate 226 in the normal direction Z and includes a second pad portion 231 and a second lead terminal 232. The second pad portion 231 is formed in a rectangular shape extending in the first direction X inside the package body 222 and exposes from the second surface 224.

The second lead terminal 232 is pulled out from the second pad portion 231 to the first side wall 225A in a band shape extending in the second direction Y, and penetrates the first side wall 225A to be exposed from the package body 222. The second lead terminal 232 arranged on the third side wall 225C side in plan view. The second lead terminal 232 is exposed from the first side wall 225A at a position at intervals from the first surface 223 and the second surface 224.

The second lead terminal 232 is pulled out at a thickness position different from a thickness position of the first lead terminal 228, in regard to the normal direction Z. The second lead terminal 232 is formed at an interval from the first lead terminal 228 to the second surface 224 side, and does not oppose the first lead terminal 228 in the first direction X, in this embodiment. The second lead terminal 232 has a length different from a length of the first lead terminal 228, in regard to the second direction Y.

The package 201C includes a plurality of (in this embodiment, five) third lead terminals 234 that are pulled out from inside of the package body 222 to outside of the package body 222. The plurality of third lead terminals 234 are arranged in a thickness range between the first pad portion 227 and the second pad portion 231, in this embodiment. The plurality of third lead terminals 234 are each pulled out from inside of the package body 222 toward the second side wall 225B in a band shape extending in the second direction Y, and penetrate the second side wall 225B to be exposed from the package body 222.

An arrangement of the plurality of third lead terminals 234 is arbitrary. The plurality of third lead terminals 234 are arranged on the third side wall 225C side such as to locate on the same straight line with the second lead terminal 232, in plan view, in this embodiment. The plurality of third lead terminals 234 may each have a curved section bent toward the first surface 223 and/or the second surface 224 in a portion located outside the package body 222.

The package 201C includes a first semiconductor device 235 that is arranged inside the package body 222. The first semiconductor device 235 consists of any one of the semiconductor devices 1A to 1I according to the first to ninth embodiments. The first semiconductor device 235 is arranged between the first pad portion 227 and the second pad portion 231. The first semiconductor device 235 is arranged on the third side wall 225C side in plan view. The first semiconductor device 235 is arranged on the second metal plate 230 in a posture with the drain electrode 77 opposing to the second metal plate 230 (the second pad portion 231), and is electrically connected to the second metal plate 230.

The package 201C includes a second semiconductor device 236 that is arranged inside the package body 222 at an interval from the first semiconductor device 235. The second semiconductor device 236 consists of any one of the semiconductor devices 1J to 1K according to the tenth to eleventh embodiments. The second semiconductor device 236 is arranged between the first pad portion 227 and the second pad portion 231. The second semiconductor device 236 is arranged on the fourth side wall 225D side in plan view. The second semiconductor device 236 is arranged on the second metal plate 230 in a posture with the second polar electrode 136 opposing to the second metal plate 230 (the second pad portion 231), and is electrically connected to the second metal plate 230.

The package 201C includes a first conductor spacer 237 (first conductive connection member) and a second conductor spacer 238 (second conductive connection member) that are each arranged inside the package body 222. The first conductor spacer 237 is interposed between the first semiconductor device 235 and the first pad portion 227 and is electrically connected to the first semiconductor device 235 and the first pad portion 227. The second conductor spacer 238 is interposed between the second semiconductor device 236 and the first pad portion 227 and is electrically connected to the second semiconductor device 236 and the first pad portion 227.

The first conductor spacer 237 and the second conductor spacer 238 may each include a metal plate (for example, Cu-based metal plate). The second conductor spacer 238 consists of a separated member from the first conductor spacer 237 in this embodiment, but the second conductor spacer 238 may be integrally formed with the first conductor spacer 237.

The package 201C includes first to sixth conductive adhesives 239A to 239F. The first to sixth conductive adhesives 239A to 239F may each include a solder or a metal past. The solder may be a lead-free solder. The metal paste may include at least one of Au, Ag and Cu. The Ag paste may consist of an Ag sintered paste.

The first conductive adhesive 239A is interposed between the drain electrode 77 and the second pad portion 231, and connects the first semiconductor device 235 to the second pad portion 231. The second conductive adhesive 239B is interposed between the second polar electrode 136 and the second pad portion 231, and connects the second semiconductor device 236 to the second pad portion 231.

The third conductive adhesive 239C is interposed between the source terminal film 75 and the first conductor spacer 237, and connects the first conductor spacer 237 to the source terminal film 75. The fourth conductive adhesive 239D is interposed between the terminal film 135 and the second conductor spacer 238, and connects the second conductor spacer 238 to the terminal film 135.

The fifth conductive adhesive 239E is interposed between the first pad portion 227 and the first conductor spacer 237, and connects the first conductor spacer 237 to the first pad portion 227. The sixth conductive adhesive 239F is interposed between the first pad portion 227 and the second conductor spacer 238, and connects the second conductor spacer 238 to the first pad portion 227.

The package 201C includes at least one (in this embodiment, a plurality of) conducting wires 240 (conductive connection member) that are electrically connected to the gate terminal film 74 50 of the first semiconductor device 235 and at least one (in this embodiment, a plurality of) third lead terminals 234 inside the package body 222. The conducting wires 240 each consists of a metal wire (that is, bonding wire), in this embodiment.

The conducting wires 240 may include at least one of a gold wire, a copper wire and an aluminum wire. As a matter of course, the conducting wires 240 may each consist of a metal plate such as a metal clip, instead of the metal wire. In a case in which the source terminal film 75 includes the sense terminal film 103 (see FIG. 17), a conducting wire 240 to be connected to the sense terminal film 103 and the third lead terminal 234 may be further provide.

An example in which the source terminal film 75 is connected to the first pad portion 227 via the first conductor spacers 237 has been shown, in this embodiment. However, the source terminal film 75 may be connected to the first pad portion 227 by the third conductive adhesive 239C without the first conductor spacer 237. Also, an example in which the terminal film 135 is connected to the first pad portion 227 via the second conductor spacers 238 has been shown, in this embodiment. However, the terminal film 135 may be connected to the first pad portion 227 by the fourth conductive adhesive 239D without the second conductor spacers 238.

Each of the embodiments described above can be implemented in yet other modes. With each of the embodiments described above, a mode in which at least one gate pillar electrode 50 is arranged on the gate electrode 30 was illustrated. However, the plurality of the gate pillar electrodes 50 may be arranged on the gate electrode 30. Also, the various modes applied to the plurality of source pillar electrodes 60 and the source terminal film 75 can also be applied to the plurality of gate pillar electrodes 50 and the gate terminal film 74.

With the respective embodiments described above, examples in which various pillar electrodes are arranged at intervals from the upper insulating film 38 were illustrated. However, the gate pillar electrode 50 may have an overlap portion that overlaps onto the upper insulating film 38. Also, at least one source pillar electrode 60 among the plurality of source pillar electrodes 60 may have an overlap portion that overlaps onto the upper insulating film 38. Also, at least one pillar electrode 126 among the plurality of source pillar electrodes 126 may have an overlap portion that overlaps onto the upper insulating film 38.

In each of the above embodiments, the chip 2 having the mesa portion 11 has been shown. However, the chip 2 that does not have the mesa portion 11 and has the first main surface 3 extending in a flat may be adopted. In this case, the side wall structure 26 may be omitted.

In each of the above embodiments, the configurations that has the source wiring 37 have been shown. However, configurations without the source wiring 37 may be adopted. In each of the above embodiments, the gate structure 15 of the trench gate type that controls the channel inside the chip 2 has been shown. However, the gate structure 15 of a planar gate type that controls the channel from on the first main surface 3 may be adopted.

In each of the above embodiments, the configurations in which the MISFET structure 12 and the SBD structure 120 are formed in the different chips 2 have been shown. However, the MISFET structure 12 and the SBD structure 120 may be formed in different regions of the first main surface 3 in the same chip 2. In this case, the SBD structure 120 may be formed as a reflux diode of the MISFET structure 12.

In each of the embodiments, the configuration in which the “first conductive type” is the “n-type” and the “second conductive type” is the “p-type” has been shown. However, in each of the embodiments, a configuration in which the “first conductive type” is the “p-type” and the “second conductive type” is the “n-type” may be adopted. The specific configuration in this case can be obtained by replacing the “n-type” with the “p-type” and at the same time replacing the “p-type” with the “n-type” in the above descriptions and attached drawings.

In each of the embodiments, the second semiconductor region 7 of the “n-type” has been shown. However, the second semiconductor region 7 may be the “p-type”. In this case, an IGBT (Insulated Gate Bipolar Transistor) structure is formed instead of the MISFET structure 12. In this case, in the above descriptions, the “source” of the MISFET structure 12 is replaced with an “emitter” of the IGBT structure, and the “drain” of the MISFET structure 12 is replaced with a “collector” of the IGBT structure. As a matter of course, in a case in which the chip 2 has a single layered structure that consists of the epitaxial layer, the second semiconductor region 7 of the “p-type” may have p-type impurities introduced into a surface layer portion of the second main surface 4 of the chip 2 (the epitaxial layer) by an ion implantation method.

In each of the embodiments, the first direction X and the second direction Y are defined by the extending directions of the first to fourth side surfaces 5A to 5D. However, the first direction X and the second direction Y may be any directions as long as the first direction X and the second direction Y keep a relationship in which the first direction X and the second direction Y intersect (specifically, perpendicularly intersect) each other. For example, the first direction X may be a direction intersecting the first to fourth side surfaces 5A to 5D, and the second direction Y may be a direction intersecting the first to fourth side surfaces 5A to 5D.

Hereinafter, examples of features extracted from the present descriptions and the attached drawings shall be indicated below. Hereinafter, the alphanumeric characters in parentheses represent the corresponding components in the aforementioned embodiments, but are not intended to limit the scope of each clause to the embodiments. The “semiconductor device” in the following clauses may be replaced with a “wide bandgap semiconductor device”, an “SiC semiconductor device”, a “semiconductor switching device” or a “semiconductor rectifier device” as needed.
[A1] A semiconductor device (1A to 1K) comprising: a chip (2) that has a main surface (3); a main surface electrode (30, 32, 124) that covers the main surface (3); pillar electrodes (50, 60, 126) that are arranged on the main surface electrode (30, 32, 124) at an interval; a sealing insulator (71) that covers a region between the pillar electrodes (50, 60, 126) on the main surface electrode (30, 32, 124) such as to expose parts of the pillar electrodes (50, 60, 126); and at least one terminal film (74, 75, 135) that covers at least one of the pillar electrodes (50, 60, 126) on the sealing insulator (71).
[A2] The semiconductor device (1A to 1K) according to A1, wherein the pillar electrodes (50, 60, 126) are each erected in a vertically long columnar shape in cross sectional view.
[A3] The semiconductor device (1A to 1K) according to A1 or A2, wherein the terminal film (74, 75, 135) is thinner than the pillar electrodes (50, 60, 126).
[A4] The semiconductor device (1A to 1K) according to any one of A1 to A3, wherein the terminal film (74, 75, 135) has a thickness of not more than ¼ the thickness of the pillar electrodes (50, 60, 126).
[A5] The semiconductor device (1A to 1K) according to any one of A1 to A4, wherein the pillar electrodes (50, 60, 126) are thicker than the main surface electrode (30, 32, 124), and the sealing insulator (71) is thicker than the main surface electrode (30, 32, 124).
[A6] The semiconductor device (1A to 1K) according to any one of A1 to A5, wherein the pillar electrodes (50, 60, 126) are thicker than the chip (2), and the sealing insulator (71) is thicker than the chip (2).
[A7] The semiconductor device (1A to 1K) according to any one of A1 to A6, wherein the pillar electrodes (50, 60, 126) have a total planar area amounting to an occupancy ratio of not more than 30% with respect to the planar area of the main surface (3), and the terminal film (74, 75, 135) has a total planar area amounting to an occupancy ratio of not less than 50% with respect to the planar area of the main surface (3).
[A8] The semiconductor device (1A to 1K) according to any one of A1 to A7, wherein the pillar electrodes (50, 60, 126) each include a Cu-based metal.
[A9] The semiconductor device (1A to 1K) according to any one of A1 to A8, wherein the terminal film (74, 75, 135) includes at least one among an Ag-based metal film, an Al-based metal film, a Cu-based metal film, an Ni-based metal film, a Pd-based metal film, and an Au-based metal film.
[A10] The semiconductor device (1A to 1K) according to any one of A1 to A9, wherein the pillar electrodes (50, 60, 126) each have an electrode surface (51, 61, 127) and an electrode side wall (52, 62, 128), and the sealing insulator (71) covers the pillar electrodes (50, 60, 126) such as to expose the electrode surfaces (51, 61, 127) and cover the electrode side walls (52, 62, 128).
[A11] The semiconductor device (1A to 1K) according to A10, wherein the sealing insulator (71) has an insulating main surface (72) that forms a single flat surface with the electrode surfaces (51, 61, 127) of the pillar electrodes (50, 60, 126).
[A12] The semiconductor device (1A to 1K) according to any one of A1 to A11, wherein the chip (2) has a side surface (5A to 5D), and the sealing insulator (71) has an insulating side wall (73) that forms a single flat surface with the side surface (5A to 5D).
[A13] The semiconductor device (1A to 1K) according to any one of A1 to A12, further comprising: an insulating film (38) that partially covers the main surface electrode (30, 32, 124); wherein the pillar electrodes (50, 60, 126) are arranged on the main surface electrode (30, 32, 124) at intervals from the insulating film (38).
[A14] The semiconductor device (1A to 1K) according to A13, wherein the sealing insulator (71) has a portion that covers the main surface electrode (30, 32, 124) with the insulating film (38) interposed therebetween.
[A15] The semiconductor device (1A to 1K) according to A13 or A14, wherein the insulating film (38) includes one or both of an inorganic insulating film (42) and an organic insulating film (43).
[A16] The semiconductor device (1A to 1K) according to any one of A1 to A15, wherein the sealing insulator (71) includes a thermosetting resin.
[A17] The semiconductor device (1A to 1K) according to any one of A1 to A16, wherein the chip (2) has a laminated structure including a substrate (7) and an epitaxial layer (6), and includes the main surface (3) that is formed by the epitaxial layer (6).
[A18] The semiconductor device (1A to 1K) according to A17, wherein the epitaxial layer (6) is thicker than the substrate (7).
[A19] The semiconductor device (1A to 1K) according to any one of A1 to A16, wherein the chip (2) has a single layered structure consisting of an epitaxial layer (6).
[A20] The semiconductor device (1A to 1K) according to any one of A1 to A19, wherein the chip (2) includes a monocrystal of a wide bandgap semiconductor.
[B1] A manufacturing method for a semiconductor device (1A to 1K) comprising: a step of preparing a wafer structure (80) that includes a wafer (81) having a main surface (82), and a main surface electrode (30, 32, 124) arranged on the main surface (82); a step of forming pillar electrodes (50, 60, 126) at intervals on the main surface electrode (30, 32, 124); a step of forming a sealing insulator (71) that covers a region between the pillar electrodes (50, 60, 126) on the main surface electrode (30, 32, 124) such as to expose parts of the pillar electrodes (50, 60, 126); and a step of forming at least one terminal film (74, 75, 135) that covers the pillar electrodes (50, 60, 126) on the sealing insulator (71).
[B2] The manufacturing method for semiconductor device (1A to 1K) according to B1, further comprising: a step of thinning the wafer (81) after the step of forming the sealing insulator (71).
[B3] The manufacturing method for semiconductor device (1A to 1K) according to B2, wherein the thinning step of the wafer (81) includes a step of thinning the wafer (81) until the wafer (81) becomes less in thickness than the pillar electrodes (50, 60, 126).
[B4] The manufacturing method for semiconductor device (1A to 1K) according to any one of B1 to B3, wherein the forming step of the pillar electrodes (50, 60, 126) includes a step of forming the pillar electrodes (50, 60, 126) in vertically long columnar shapes in cross sectional view.
[B5] The manufacturing method for semiconductor device (1A to 1K) according to any one of B1 to B4, wherein the forming step of the terminal film (74, 75, 135) includes a step of forming the terminal film (74, 75, 135) that is thinner than the pillar electrodes (50, 60, 126).
[B6] The manufacturing method for semiconductor device (1A to 1K) according to any one of B1 to B5, wherein the forming step of the terminal film (74, 75, 135) includes a step of forming the terminal film (74, 75, 135) having a thickness of not more than ¼ that of the pillar electrodes (50, 60, 126).
[B7] The manufacturing method for semiconductor device (1A to 1K) according to any one of B1 to B6, wherein the forming step of the pillar electrodes (50, 60, 126) includes a step of forming the pillar electrodes (50, 60, 126) that are thicker than the main surface electrode (30, 32, 124), and the forming step of the sealing insulator (71) includes a step of forming the sealing insulator (71) that is thicker than the main surface electrode (30, 32, 124).
[B8] The manufacturing method for semiconductor device (1A to 1K) according to any one of B1 to B7, wherein the forming step of the pillar electrodes (50, 60, 126) includes a step of forming a conductor film (89) that covers the main surface electrode (30, 32, 124), a step of forming, on the conductor film (89), a mask (90) having openings (92) that expose portions of the conductor film (89) covering the main surface electrode (30, 32, 124), and a step of depositing a conductor (95) on the portions of the conductor film (89) exposed from the openings (92).
[B9] The manufacturing method for semiconductor device (1A to 1K) according to B8, further comprising: a step of removing the mask (90) after the depositing step of the conductor (95); wherein the forming step of the sealing insulator (71) is performed after the removing step of the mask (90).
[B10] The manufacturing method for semiconductor device (1A to 1K) according to any one of B1 to B9, wherein the forming step of the terminal film (74, 75, 135) includes a step of forming the terminal film (74, 75, 135) that includes at least one among an Ag-based metal film, an Al-based metal film, a Cu-based metal film, an Ni-based metal film, a Pd-based metal film, and an Au-based metal film.
[B11] The manufacturing method for semiconductor device (1A to 1K) according to any one of B1 to B10, wherein the forming step of the sealing insulator (71) includes a step of forming the sealing insulator (71) that covers a whole region of the pillar electrodes (50, 60, 126), and a step of partially removing the sealing insulator (71) until the pillar electrodes (50, 60, 126) are exposed.
[B12] The manufacturing method for semiconductor device (1A to 1K) according to B11, wherein the removing step of the sealing insulator (71) includes a step of partially removing the sealing insulator (71) by a grinding method.
[B13] The manufacturing method for semiconductor device (1A to 1K) according to any one of B1 to B12, further comprising: a step of preparing the wafer structure (80) that includes the wafer (81) having the main surface (82) in which a device region (86) and a scheduled cutting line (87) that demarcates the device region (86) are set, and the main surface electrode (30, 32, 124) arranged on the main surface (82) in the device region (86); and a step of cutting the wafer (81) and the sealing insulator (71) along the scheduled cutting lines (87) after the forming step of the sealing insulator (71).
[B14] The manufacturing method for semiconductor device (1A to 1K) according to B13, wherein the forming step of the pillar electrodes (50, 60, 126) includes a step of forming the pillar electrodes (50, 60, 126) having a total planar area amounting to an occupancy ratio of not more than 30% with respect to a planar area of the device region (86), and the forming step of the terminal film (74, 75, 135) includes a step of forming the terminal film (74, 75, 135) having a total planar area amounting to an occupancy ratio of not less than 50% with respect to the planar area of the device region (86).
[B15] The manufacturing method for semiconductor device (1A to 1K) according to any one of B1 to B14, further comprising: a step of forming an insulating film (38) that partially covers the main surface electrode (30, 32, 124) before the forming step of the pillar electrodes (50, 60, 126); wherein the forming step of the pillar electrodes (50, 60, 126) includes a step of forming the pillar electrodes (50, 60, 126) on the main surface electrode (30, 32, 124) at intervals from the insulating film (38).
[B16] The manufacturing method for semiconductor device (1A to 1K) according to B15, wherein the forming step of the sealing insulator (71) includes a step of forming the sealing insulator (71) having a portion that covers the main surface electrode (30, 32, 124) with the insulating film (38) interposed therebetween.
[B17] The manufacturing method for semiconductor device (1A to 1K) according to B15 or B16, wherein the forming step of the insulating film (38) includes a step of forming the insulating film (38) that includes one or both of an inorganic insulating film (42) and an organic insulating film (43).
[B18] The manufacturing method for semiconductor device (1A to 1K) according to any one of B1 to B17, wherein the forming step of the sealing insulator (71) includes a step of forming the sealing insulator (71) that includes a thermosetting resin.
[B19] The manufacturing method for semiconductor device (1A to 1K) according to any one of B1 to B18, wherein the wafer (81) has a laminated structure including a substrate (7) and an epitaxial layer (6), and has the main surface (3) that is formed by the epitaxial layer (6).
[B20] The manufacturing method for semiconductor device (1A to 1K) according to any one of B1 to B19, wherein the wafer (81) includes the wafer (81) that includes a monocrystal of a wide bandgap semiconductor.

While embodiments of the present invention have been described in detail above, those are merely specific examples used to clarify the technical contents, and the present invention should not be interpreted as being limited only to those specific examples, and the spirit and scope of the present invention shall be limited only by the appended Claims.

What is claimed is:

1. A semiconductor device comprising:
a chip that has a main surface;
a main surface electrode that covers the main surface;
pillar electrodes that are arranged on the main surface electrode at an interval;
a sealing insulator that covers a region between the pillar electrodes on the main surface electrode such as to expose parts of the pillar electrodes; and
at least one terminal film that covers at least one of the pillar electrodes on the sealing insulator.

2. The semiconductor device according to claim 1,
wherein the pillar electrodes are each erected in a vertically long columnar shape in cross sectional view.

3. The semiconductor device according to claim 1,
wherein the terminal film is thinner than the pillar electrodes.

4. The semiconductor device according to claim 1,
wherein the terminal film has a thickness of not more than ¼ the thickness of the pillar electrodes.

5. The semiconductor device according to claim 1,
wherein the pillar electrodes are thicker than the main surface electrode, and
the sealing insulator is thicker than the main surface electrode.

6. The semiconductor device according to claim 1,
wherein the pillar electrodes are thicker than the chip, and
the sealing insulator is thicker than the chip.

7. The semiconductor device according to claim 1,
wherein the pillar electrodes have a total planar area amounting to an occupancy ratio of not more than 30% with respect to the planar area of the main surface, and
the terminal film has a total planar area amounting to an occupancy ratio of not less than 50% with respect to the planar area of the main surface.

8. The semiconductor device according to claim 1,
wherein the pillar electrodes each include a Cu-based metal.

9. The semiconductor device according to claim 1,
wherein the terminal film includes at least one among an Ag-based metal film, an Al-based metal film, a Cu-based metal film, an Ni-based metal film, a Pd-based metal film, and an Au-based metal film.

10. The semiconductor device according to claim 1,
wherein the pillar electrodes each have an electrode surface and an electrode side wall, and
the sealing insulator covers the pillar electrodes such as to expose the electrode surfaces and cover the electrode side walls.

11. The semiconductor device according to claim 10,
wherein the sealing insulator has an insulating main surface that forms a single flat surface with the electrode surfaces of the pillar electrodes.

12. The semiconductor device according to claim 1,
wherein the chip has a side surface, and
the sealing insulator has an insulating side wall that forms a single flat surface with the side surface.

13. The semiconductor device according to claim 1, further comprising:
an insulating film that partially covers the main surface electrode;
wherein the pillar electrodes are arranged on the main surface electrode at intervals from the insulating film.

14. The semiconductor device according to claim 13,
wherein the sealing insulator has a portion that covers the main surface electrode across the insulating film.

15. The semiconductor device according to claim 13,
wherein the insulating film includes one or both of an inorganic insulating film and an organic insulating film.

16. The semiconductor device according to claim 1,
wherein the sealing insulator includes a thermosetting resin.

17. The semiconductor device according to claim 1,
wherein the chip has a laminated structure including a substrate and an epitaxial layer, and includes the main surface that is formed by the epitaxial layer.

18. The semiconductor device according to claim 17,
wherein the epitaxial layer is thicker than the substrate.

19. The semiconductor device according to claim 1,
wherein the chip has a single layered structure consisting of an epitaxial layer.

20. The semiconductor device according to claim 1,
wherein the chip includes a monocrystal of a wide bandgap semiconductor.
